(19) United States
(12) Patent Application Publication
(10) Pub. No.: US 2023/0342526 A1
(43) Pub. Date: Oct. 26, 2023

(54) SYSTEM AND METHOD FOR WILDFIRE SPREAD BEHAVIOR FORECASTING AND ON-PARCEL WILDFIRE RISK EVALUATION

(71) Applicant: Willow Labs, Inc., San Francisco, CA (US)

(72) Inventor: Scott FARLEY, San Francisco, CA (US)

(21) Appl. No.: 18/127,437

(22) Filed: Mar. 28, 2023

Related U.S. Application Data
(60) Provisional application No. 63/355,594, filed on Jun. 25, 2022.
(60) Provisional application No. 63/324,502, filed on Mar. 28, 2022.

(51) Int. Cl. G06F 30/27

(52) U.S. Cl. CPC G06F 30/27

(57) ABSTRACT

A system and method for wildfire spread behavior forecasting and on-parcel wildfire risk evaluation is disclosed. An example embodiment comprises an autonomous planning agent that learns spatio-temporal distributions of firefighting equipment and personnel that minimize asset losses from wildfires in the wildland urban interface. Drawing on large volumes of earth observation data and official incident status reports, the system utilizes artificial intelligence (AI) methods to develop a control system that produces expressive, spatiotemporally explicit resource assignment policies for use in a decision support system. In particular, the key components of the system are: (1) a neural-network-based fire behavior simulator capable of accurately modeling wildland fire ignition, spread, and control; (2) a learning algorithm that produces coherent firefighting strategies given current and forecast weather and fuel conditions; and (3) a wildfire hazard evaluation algorithm that evaluates the impact of home hardening, defensible space, and other common wildfire hazards found on residential parcels.

### PRIORITY PATENT APPLICATIONS

This non-provisional patent application draws priority from U.S. Provisional Pat. Application Serial No. 63/324,502; filed Mar. 28, 2022. This non-provisional patent application also draws priority from U.S. Provisional Pat. Application Serial No. 63/355,594; filed Jun. 25, 2022. This present non-provisional patent application draws priority from the referenced patent applications. The entire disclosure of the referenced patent applications is considered part of the disclosure of the present application and is hereby incorporated by reference herein in its entirety.

### COPYRIGHT

A portion of the disclosure of this patent document contains material that is subject to copyright protection. The copyright owner has no objection to the facsimile reproduction of the patent document or the patent disclosure, as it appears in the U.S. Patent and Trademark Office patent files or records, but otherwise reserves all copyright rights whatsoever. The following notice applies to the disclosure provided herein and to the drawings that form a part of this document: Copyright 2021 - 2023, Scott Farley, All Rights Reserved.

### TECHNICAL FIELD

An example embodiment of the present invention comprises a software system for (1) forecasting the behavior and growth trajectory of a wildfire given future predictions of wind, weather, vegetation, firefighter actions, and other data sources, (2) optimizing the deployment of fire suppression units (firefighters, aircraft, and engines) to the most beneficial locations using Monte Carlo simulations of future trajectories and a policy-learning algorithm, (3) analyzing, ranking, and prioritizing the wildfire hazards posed vegetation, structure design attributes, and other wildfire hazards found on a parcel and (4) exposing these forecasting tools as application programming interfaces (API’s) to facilitate their use in decision support systems. In particular, a system and method for wildfire spread behavior forecasting and on-parcel wildfire risk evaluation is disclosed.

### BACKGROUND

Wildfires annually bum millions of acres in the Western United States, destroying thousands of homes, releasing millions of tons of CO2 into the atmosphere, and costing billions of dollars to control. Firefighter actions and the vegetation and design of structures in the wildland urban interface (WUI) have significant influence over the number and location of structures burned during a wildfire, yet decision support systems do not account for these critical variables.

After a fire is reported, wildland firefighting resources -- personnel, engines, bulldozers, air tankers, and helicopters -- are committed in two phases: (1) in an initial attack (IA) cadre and (2) after the incident has grown in scope and the incident commander (IC) has determined the need for additional support. Because only a limited supply of firefighting personnel and equipment exists at a given time and ICs are primarily concerned with the control of a single incident, the existing dispatching method can create an inefficient distribution of resources over large spatial and temporal scales. Further, it leaves fire managers to navigate the complex decisions of determining which fires receive resources and at what point in the incident lifecycle without a statistical framework on which to assess these tradeoffs. As fire crews in the western US are increasingly strained due to more frequent fires and more extreme fire behavior, efficient allocation of resources is paramount to their ability to effectively protect lives and property.

The survival of homes and other structures when exposed to wildfire is highly dependent on the structure’s materials of constructure, design attributes, and surrounding vegetation. Collectively, parcel-scale factors, including the quantity and arrangement of fuels adjacent to the structure, its design and materials of construction, and the density and topology of other nearby structures, have a particularly significant influence on a structure’s resilience once exposed. Currently, fire departments and other public agencies in the Western United States do not account for these factors in routine quantitative risk modeling. These agencies enact blanket risk mitigation programs and policies that do not provide prioritization of parcel-scale factors by their relative risk to community safety.

### BRIEF DESCRIPTION OF THE DRAWINGS

Embodiments are illustrated by way of example and not limitation in the figures of the accompanying drawings, in which:

FIG. 1 illustrates an example embodiment of the wildfire risk evaluation module configured to respond to an initial environment and determine the long-term value of three representative assignment action policies (left, center, and right);

FIG. 2 illustrates a wireframe of the system components of an example embodiment, including a data processor, wildfire mechanics module, planning agent, simulated environment generator, and API;

FIG. 3 illustrates an overview of an example embodiment of the wildfire behavior mechanics module architecture;

FIG. 4 illustrates an overview of an example embodiment for joining and enriching structured data describing fire suppression resource locations with satellite-based fire perimeter data ;

FIG. 5 illustrates the example embodiment of a data processing sequence for time varying data sources used as input in the fire mechanics module;

FIG. 6 illustrates an example embodiment of a data processing sequence of time invariant data sources used as input in the fire mechanics module;

FIG. 7 illustrates an example embodiment of the architecture of the fire mechanics module;

FIG. 8 illustrates an overview of the architecture of the fire mechanics module, including data inputs and outputs;

FIG. 9 illustrates an example embodiment of the architecture of the environment generator module, including data inputs, preprocessing steps, model architecture, and data outputs;

FIG. 10 illustrates an overview of an example embodiment for how the planning agent module produces optimal location selections from a pool of available resource types;

FIG. 11 illustrates an overview of an example embodiment of the planning agent architecture, including data inputs, state representation and updates, action selection, reward calculation, and performance evaluation;

FIG. 12 illustrates a mechanism for computing reward function values using a configurable asset type weighting function;

FIG. 13 illustrates an overview of an example embodiment of the process used to train the planning agent;

FIG. 14 illustrates an overview of an example embodiment of the planning agent’s action/value model architecture;

FIG. 15 illustrates an overview of inference-time action selection using a stochastic search tree;

FIG. 16 illustrates an overview of how actions computed at inference time are post-processed and made available to a user requesting information over a data network through an API service;

FIG. 17 illustrates an overview of the genetic selection tournament process and the mechanism for selecting candidates after each episode;

FIG. 18 illustrates an overview of an example embodiment of the information flows used to provide an end user with decision support through an API, including used a trained planning agent to predict optimal actions and returning data to the client’s device through a data network;

FIG. 19 illustrates a spatiotemporally-explicit fire growth prediction produced by the fire mechanics module over an example 3D heterogeneous landscape;

FIG. 20 illustrates an example embodiment of a probability distribution of fire growth predictions produced by the estimator and fire suppression resource locations;

FIG. 21 illustrates examples of findings indicating potential fire hazards encountered during an on-site inspection in an example embodiment;

FIG. 22 illustrates an overview of an example embodiment of the on-parcel risk assessment process using data from an on-site inspection, including a data processor module, component hazard modules, efficiency module, resolution simulation module, and API service to make decision support available over a data network;

FIG. 23 illustrates an overview of an example embodiment for calculating resolution strategy efficiency for a set of findings encountered during pre-fire inspections spread across an administrative unit;

FIG. 24 illustrates two spatially-explicit fire weather/wind scenarios for an example embodiment;

FIG. 25 illustrates an overview of the intensity component architecture in an example embodiment;

FIG. 26 illustrates radiative heating studies and a line of best fit between the measured datapoints;

FIG. 27 illustrates the direction component (left), distance component (middle) and total decay value for combustion at a hypothetical location marked as the center circle;

FIG. 28 illustrates a schematic of the ember lofting, transport, and deposition;

FIG. 29 illustrates a particle radius (left), mass (middle), and surface-area-to-volume (center) distributions of the simulated embers used in an example embodiment;

FIG. 30 illustrates an overview of an example embodiment of the ember hazard score component architecture;

FIG. 31 illustrates an overview of an example embodiment of the ember flight mechanics simulator;

FIG. 32 illustrates an overview of an example embodiment of using a model trained on post-fire damage inspection data to produce hazard scores from pre-fire inspections;

FIG. 33 illustrates an overview of an example embodiment for computing the hazard of findings encountered during a pre-fire inspection by using a rubric informed by external sources and adjusting for structure separation distance;

FIG. 34 illustrates an overview of an example embodiment’s parcel aggregator module architecture for computing a risk evaluation score for a set of tax parcel boundaries using pre-fire inspection findings;

FIG. 35 illustrates an overview of an example embodiment for using cost data from multiple sources to compute risk efficiency for pre-fire site inspection findings;

FIG. 36 illustrates an example of hotspots calculated during an example embodiment of the risk evaluation process;

FIG. 37 illustrates an overview of an example embodiment that enables users to communicate with the risk assessment computation, efficiency metrics, and resolution simulations through the use of an API over a data network;

FIG. 38 illustrates intensity scores and affected buildings for each combustible discovery on a parcel in an example embodiment;

FIGS. 39 and 40 illustrate simulated ember trajectories for the 2020 scenario and the 2017 scenario in an example embodiment;

FIG. 41 illustrates discovery hazard index scores on the example parcel, broken out by component index score;

FIG. 42 illustrates discovery hazard index scores on the example parcel shown spatially;

FIG. 43 illustrates an example embodiment of parcel scores calculated directly from on-site inspection findings; and

FIG. 44 illustrates an example embodiment where parcel risk assessments produced from on-site inspection findings are paired with modeled projections of fire growth produced by the fire mechanics module.

### DETAILED DESCRIPTION

In the following detailed description, reference is made to the accompanying drawings that form a part hereof, and in which are shown, by way of illustration, specific embodiments in which the disclosed subject matter can be practiced. It is understood that other embodiments may be utilized and structural changes may be made without departing from the scope of the disclosed subject matter.

### A. Example Embodiments of an Information Technology System for Forecasting Wildfire Spread

An example embodiment of the present invention leverages artificial intelligence (AI) to produce efficient spatiotemporal assignment strategies for firefighting personnel and equipment (“suppression resources”) across broad spatiotemporal scales and specific wildfire incidents. A cloud-based decision support system (DSS) makes policies that effectively protect values at risk available to emergency dispatchers and fire leadership. The software platform aids decision makers in identifying strategies that effectively utilize a given pool of suppression resources within a spatial region by simulating many possible outcomes, quantifying each simulation in terms of probable asset loss, and proposing strategies that minimize total weighted losses within the region. The strategy search is conducted using a reinforcement learning (RL) agent that evaluates the past, current, and forecast weather and fuel conditions to estimate the long-term value of each candidate strategy. An example embodiment of the present invention is a commercially viable, large-scale planning agent and fire behavior simulator made available over a data network and integrated into dispatching software via an Application Programming Interface (API). The trained planning agent, training platform, and simulator also have powerful applications in other domains, such as in the management and harvest schedule of large-scale silviculture and viticulture, or in the application to other emergency management domains such as search and rescue.

The present invention offers several advantages over existing DSS systems commonly used in wildland fire applications, including (1) it is fully data-driven using aerial imagery, remotely sensed vegetation data, and ground-based records of suppression resource location, allowing expressive representations of on-the-ground fire behavior and control activities, (2) it offers a probabilistic, spatio-temporally explicit framework that can be used to support real-time dispatching decisions in the presence of uncertainty, and (3) it focuses on resource distribution over a range of spatial scales (100 s of meters to 100 s of kilometers), informing the allocation of suppression resources on the scales needed to suppress the multiple concurrent mega-fires observed in recent fire years.

An example embodiment of the present invention may complement, but not replace, the rich expertise of dispatchers, incident commanders, and fire leadership by suggesting potential alternate assignment strategies. This technology may be used primarily by dispatchers and duty officers at large firefighting agencies (state and national agencies, e.g., US Forest Service, CalFIRE, Oregon Department of Forestry), private firefighting companies with large service areas, and inter-agency coordinating groups (e.g., National Interagency Fire Center) responsible for handling resource demands at large spatial scales. The value propositions the current invention offers are (1) reduction in wildland firefighting costs by improving the efficiency of local and regional resources and (2) novel strategies that improve agencies’ ability to keep fires limited in size and protect property and lives in the wildland-urban interface (WUI).

On most wildfires burning in the WUI, the primary objective of an IC is to lead tactical fire suppression activities that control a fire’s spread and prevent it from burning values at risk (e.g., homes in the wildland urban interface, natural or cultural heritage sites, electrical infrastructure, municipal facilities, etc.). Experienced IC’s on large fires make complex decisions about the quantity and type of resources required to achieve this objective using their historical experience and available information about the current and forecast environment in which the fire is burning (e.g., the fire’s current perimeter, dominant fuel types, expected weather conditions, and knowledge of the terrain and values at risk). The suppression resources (personnel, helicopters, and engines) committed to these incidents are drawn from a fixed-size pool of resources charged with the protection of a given spatial region; each resource can operate on at most one incident at any point in time. This structure leads to game theoretical challenges among ICs, as each is charged with the most efficient control of an individual incident. While inter-agency policies exist to facilitate the sharing and prioritization of resources among multiple incidents, these tend to be qualitative in nature. The work described here leverages an algorithm to quantitatively solve the resource allocation problem by formulating it as a discrete time partially observable Markov decision process (POMDP) and using a policy gradient algorithm to approximate its optimal solutions. Under the POMDP framework, the planning agent operates in an environment with incomplete information by taking actions which may affect the future state of the environment. Through experimentation with and observation of its environment, the agent constructs a probabilistic model of how its actions map to future environmental states. Leveraging a configurable, user-specified reward function that quantifies the relative utility of each state, the agent learns an optimal policy such that its actions maximize its long term utility (i.e., minimize assets burned) over a finite time horizon (e.g., a single 24 hour operational period, a complete fire season).

Various example embodiments disclosed herein provide an information technology system comprising: a data processor; and a wildfire risk evaluation module, executable by the data processor, the wildfire risk evaluation module including several submodules as described herein.

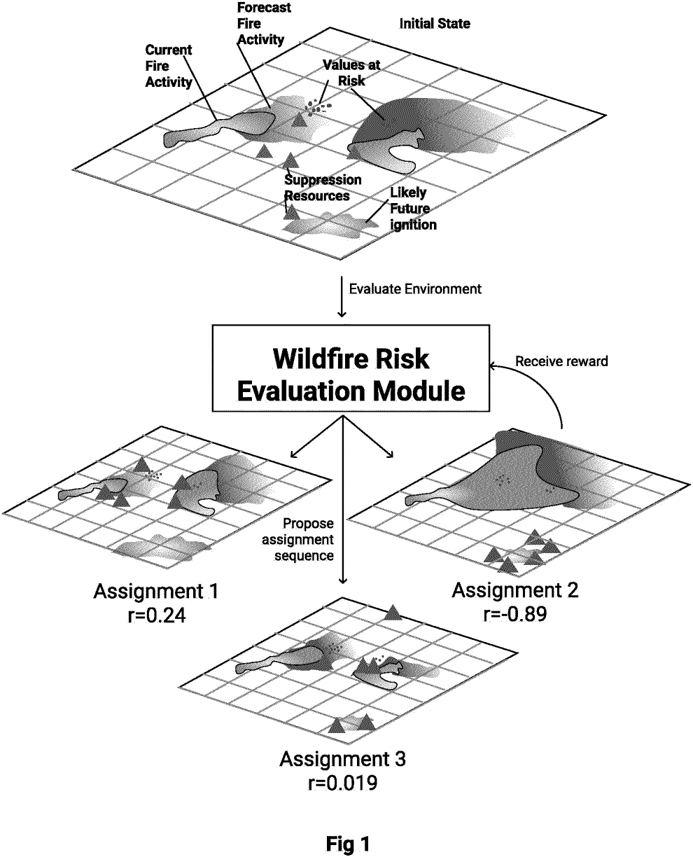

Using the processes and data processing techniques disclosed in more detail below, FIG. 1 illustrates an example embodiment of the wildfire risk evaluation model configured to traverse through an environment and produce and predict the value of three representative policies (left, center, and right). As shown in FIG. 1, (a) the model receives an initial observation of state at time=t, which includes information on current and forecast conditions; (b) the model takes action based on state information in the form of personnel locations at time t+1; (c) the model receives observation of state at the next timestep (t+1); and (d) the model receives a reward based on the performance of the last timestep, the reward corresponding to the loss of assets in the period between t and t+1. The three representative policies shown in FIG. 1 are different realizations of the risk tradeoff among the two burning wildfires and one likely ignition: (1) choosing to fight active fires over the potential ignition, (2) ignoring existing fires to protect the area of potential ignition, (3) a mix between the two.

In the example embodiment, the planning agent operates over an environment represented as a spatial grid, across which zero or more wildfires can spread simultaneously and in which zero or more fire suppression resources can act to inhibit fire growth. The planning agent receives observations of the state of this environment in the form of a pixel matrix that represents time invariant environmental conditions (topography, fuel load, fuel type), time varying environmental conditions (wind, weather), values at risk (structures, transportation infrastructure, electrical infrastructure), vegetation, and a vector describing the location and type of each suppression unit. At each timestep, the agent emits an action indicating the new location assignment for each available resource in the region and the number of resources of each type required at the following timestep. The agent receives rewards inversely proportional to the value of resources burned during the previous period (e.g., acres burned, number of structures destroyed) and cumulative resource travel. The relative importance of each Through experimentation, the agent learns to exploit strategies that efficiently maximize the probability of successfully protecting values at risk (e.g., see FIG. 1).

Like related work, the system is characterized as a POMDP and the agent’s goal is to identify strategies that maximize an objective function related to the loss of values at risk. However, previous studies have employed assumptions, such as linear system dynamics or broad heuristics, are deterministic, or focus on a single aspect of the incident response lifecycle, such as prepositioning, initial attack, or extended attack, that limit their generalized ability for expressively characterizing suppression resource allocation at various spatial scales in response to evolving environmental conditions. An example embodiment of the current invention creates a flexible, large-scale, data-driven autonomous planning agent that provides resource allocation policies in the presence of multiple concurrent wildfires and accounts for uncertainty in fire growth and containment. The planning agent is first trained to produce control policies for a sets of heterogeneous suppression resources that minimize asset loss through experimentation with a fire environment simulator and an environment simulator. At inference time, the planning agent produces a policy for a given set of suppression resources in response to current and forecast environmental conditions. The policy and supporting data (e.g., predicted fire growth trajectory) are made available to client devices (e.g., phones, tablet computers, laptops) through an API service and data network. The client device displays maps and graphics illustrating the policy and expected results to fire managers and other personnel responsible for dispatching resources in the field.

Creating the autonomous planning agent presents several technical challenges:

First, training the agent requires a simulator that can efficiently and accurately estimate the dynamics of the fire environment, including ignition, spread, and control. Previous work in fire behavior modeling (e.g., Farsite, Flammap, Burn-P3) and resource allocation relies heavily on assumptions about a fire’s behavior spread mechanics, and resource productivity in constructing fire line. Further, most current fire simulators model fire mechanics deterministically and do not account for stochasticity or allow probabilistic inference about future behavior. Given the large and extreme fires observed in recent years, these assumptions may not accurately capture the salient features required for large scale planning (e.g., ignition probability or widespread spotting contributing to rapid fire growth). The example embodiment described here includes a new probabilistic fire behavior model trained directly on observations of past fire behavior, remotely sensed environment data, and records of suppression resource location. In an example environment, the fire mechanics module, employs a neural network architecture, accepts as input recent, current, and forecast wind, weather, vegetation, topography, and the quantity, type, and location of resources available for suppression to estimate the probability of fire occurrence at each location (i.e., at each pixel) on the landscape. In the example embodiment, environmental layers may include wind speed, wind direction, temperature, relative humidity, topography, aerial imagery, satellite imagery, fuel model, vegetation density, vegetation height, canopy base height, and others. Suppression resources represented may include helicopters, engines, and hand crews, each of which have different capacity for movement through the landscape and efficiency in inhibiting fire growth. The planning agent may invoke the fire mechanics module many times to produce probabilistic estimates of fire growth locations, thereby producing its policy outputs in the presence of uncertain fire growth characteristics.

Second, to learn generalizable policies, the agent must be provided with a well-specified reward function. Inspired by the carefully curated reward function designs recently successful in eSports competitions, the agent in this work is supplied with a shaped reward function that guides it towards the optimal behavior of jointly maximizing resource efficiency and asset protection. In the example embodiment, the reward function is inversely proportional to the number of assets burned. Further, the user of the decision support system may control some aspects of the reward function via a weighting scheme that adjusts the weights for the loss of particular asset classes (e.g., residential structures burned may be weighted more heavily than electrical infrastructure lost).

Previous studies have shown various techniques for modeling multi-agent environments, either as global optimization problems or as multiple independently-solved local optimization problems. In the example embodiment, the planning agent treats suppression unit (e.g., engine, helicopter, or crew) as an independent actor optimizing its own actions, knowing only the current environment, forecast environment, and the positions and types of other units operating in the environment. From these locally-optimal decisions, the agent demonstrates the ability to learn complex strategies involving teamwork and collaboration from independent decision making.

An example embodiment of the present invention includes five primary components: (1) a data processing module that prepares data for analysis, (2) a wildfire mechanics module that predicts future fire intensity and growth, (3) an environment simulation module that produces statistically-representative simulated weather data for a location, (4) a simulation module that enables the planning agent to interact with synthetic environments and the fire mechanics module, (5) a planning agent module that interacts with the environment to predict high-value locations for suppression resources.

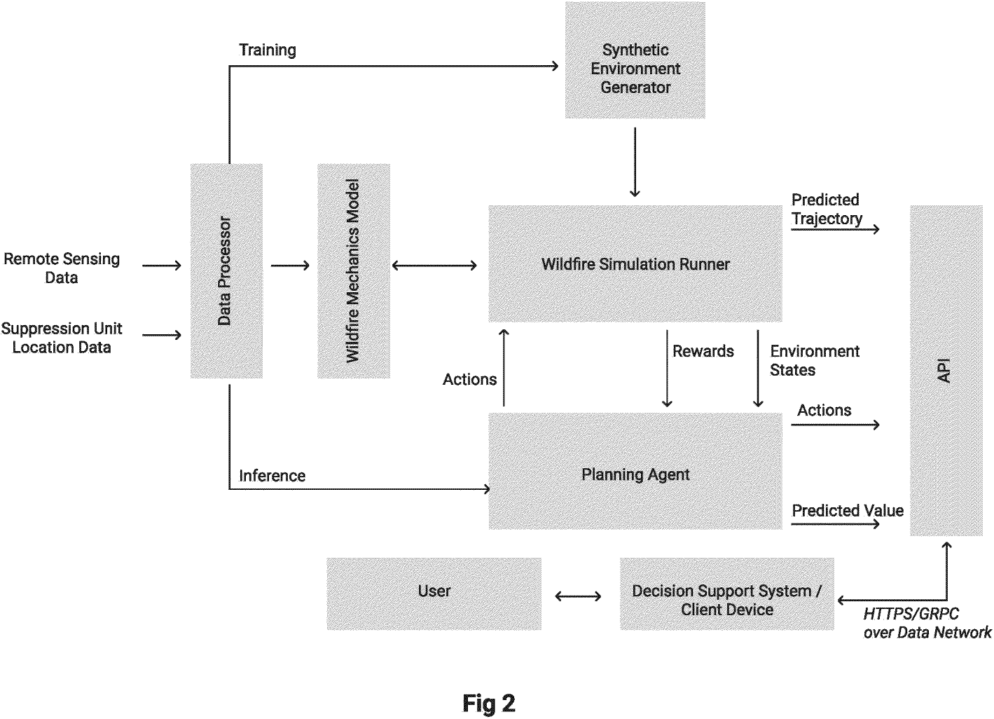

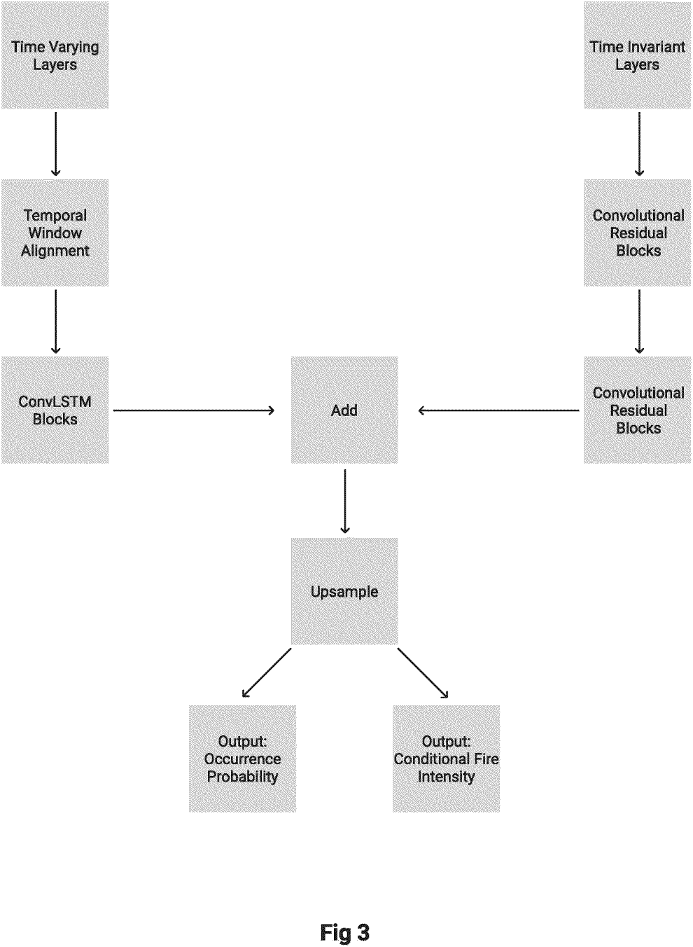

FIG. 2 illustrates a wireframe of the system components of an example embodiment. On the left portion of FIG. 3, various remotely-sensed data sources and suppression resource locations are ingested by the data processing module. In the center portion of FIG. 3, the planning agent interacts with the environment simulator and the fire mechanics module to identify relationships between actions, states, and rewards. In the right portion of FIG. 3, an API is used to facilitate communication between a user’s client device and the trained planning agent through a data network.

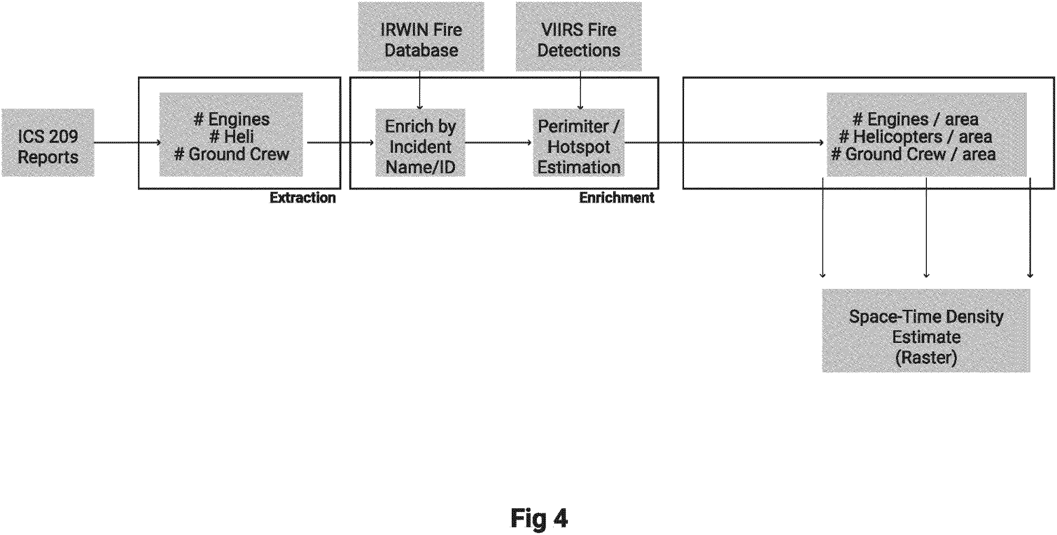

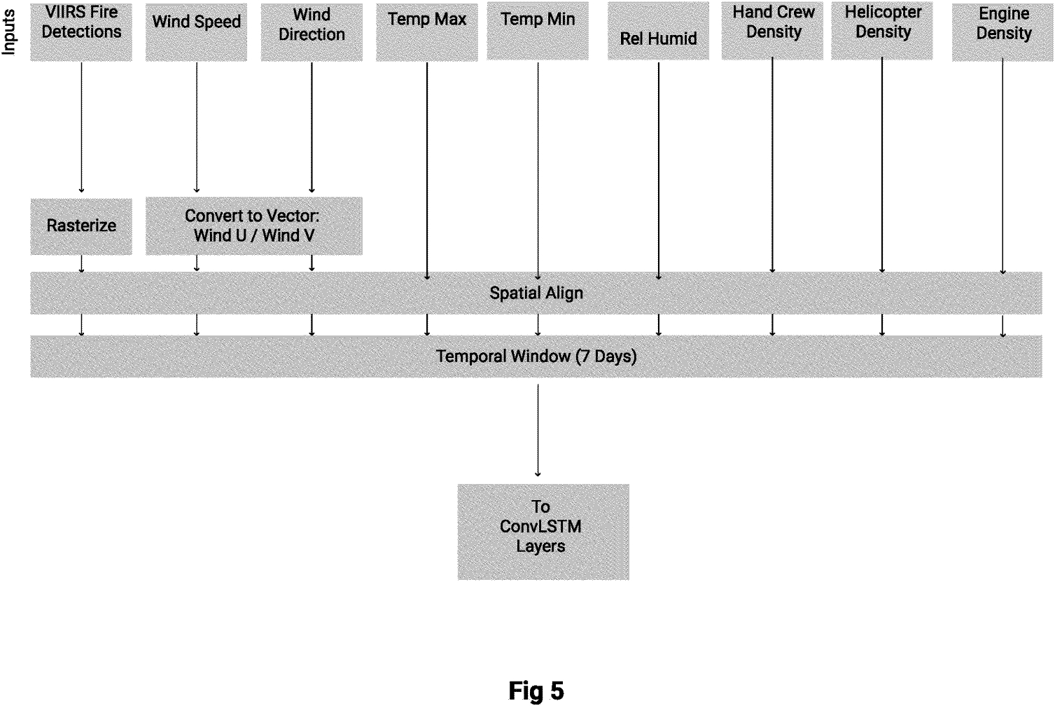

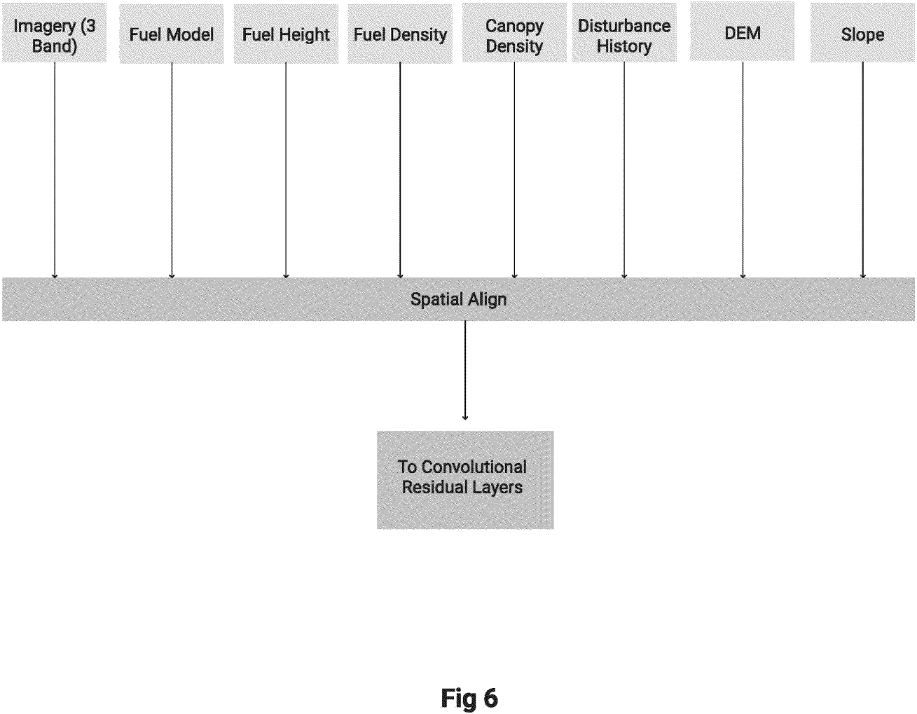

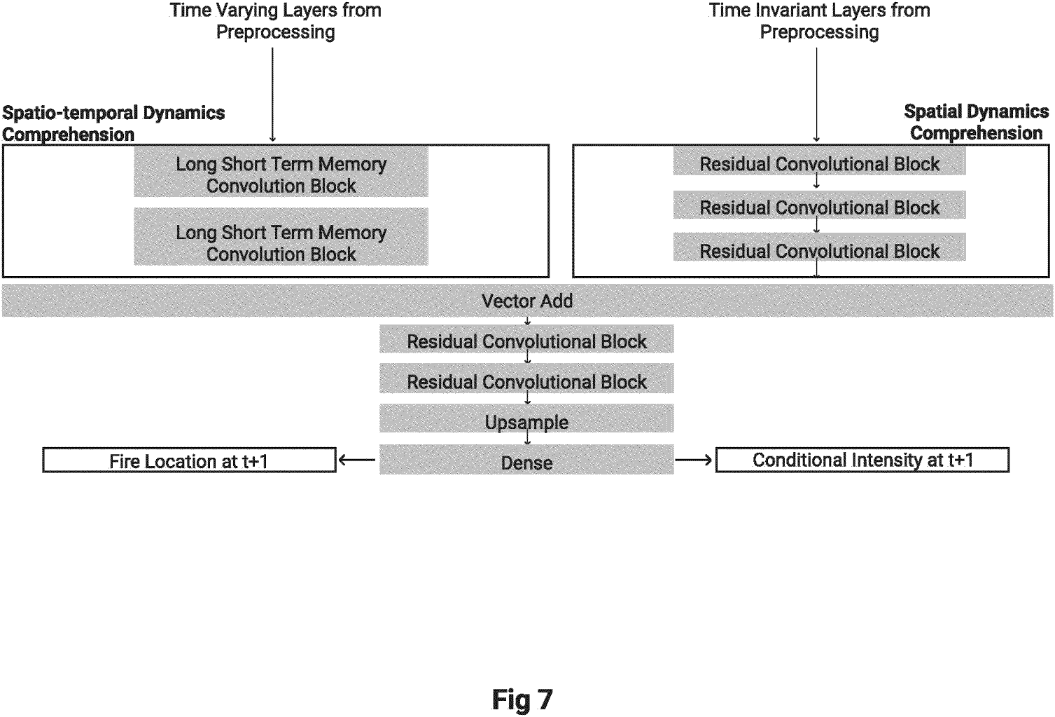

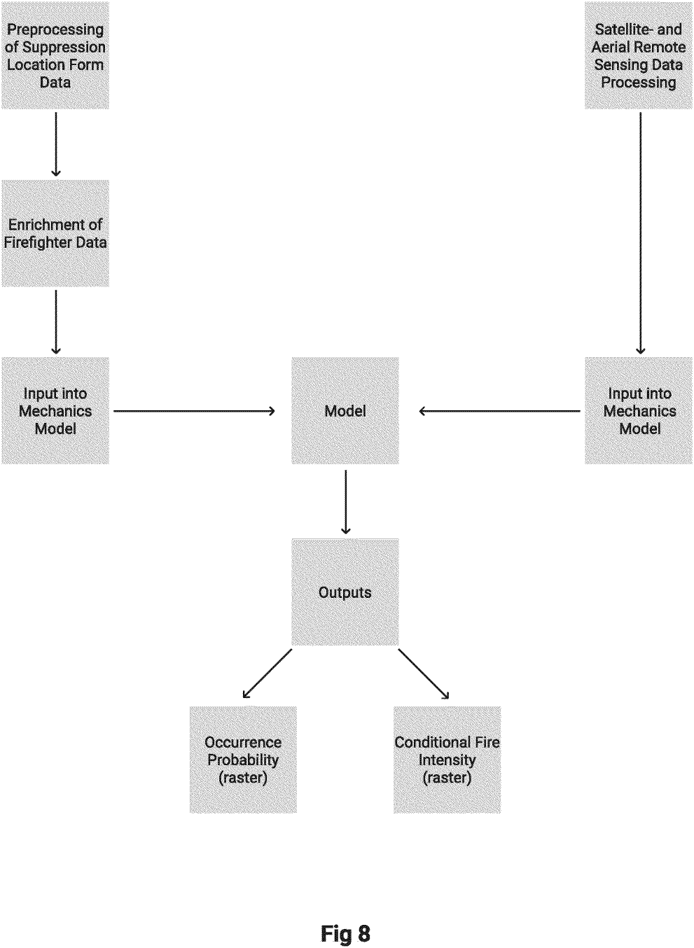

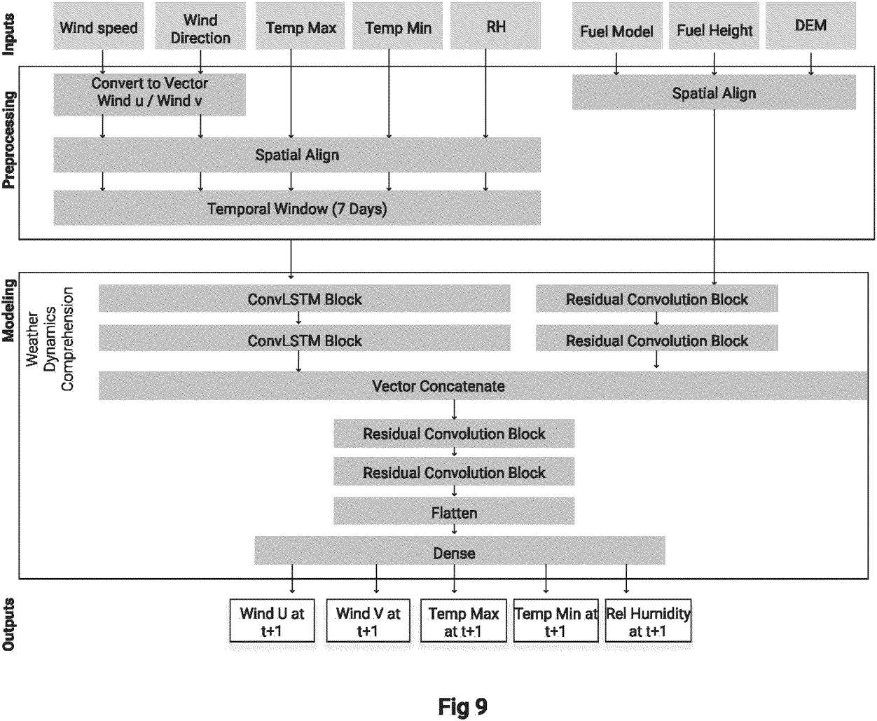

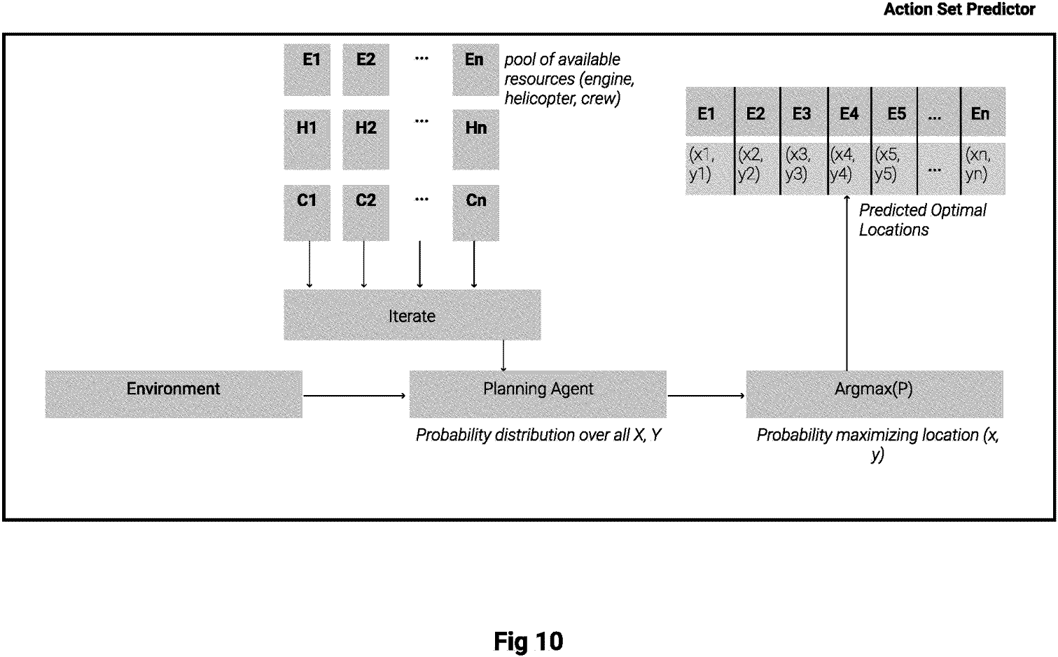

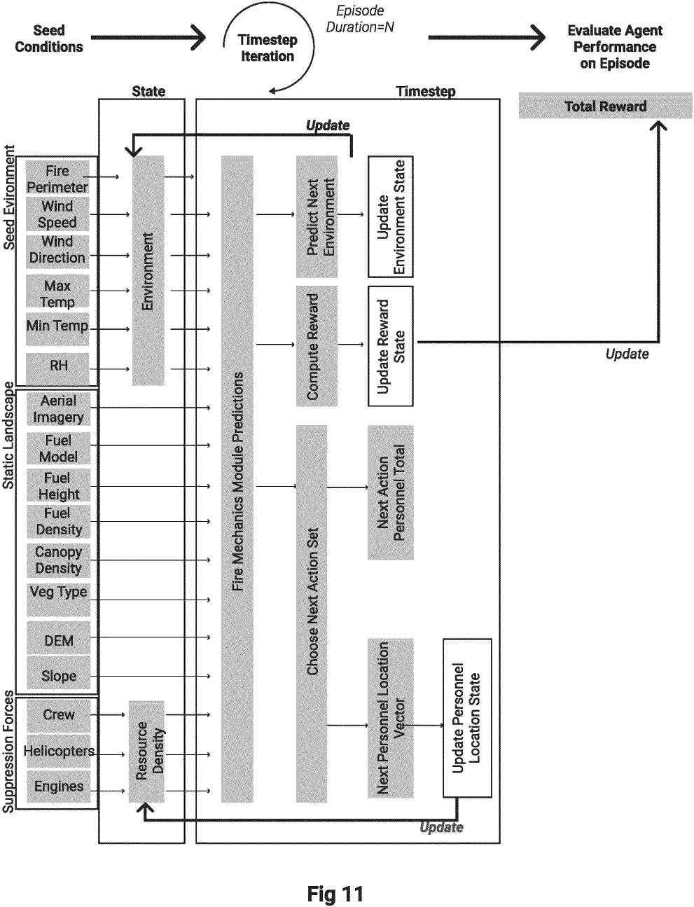

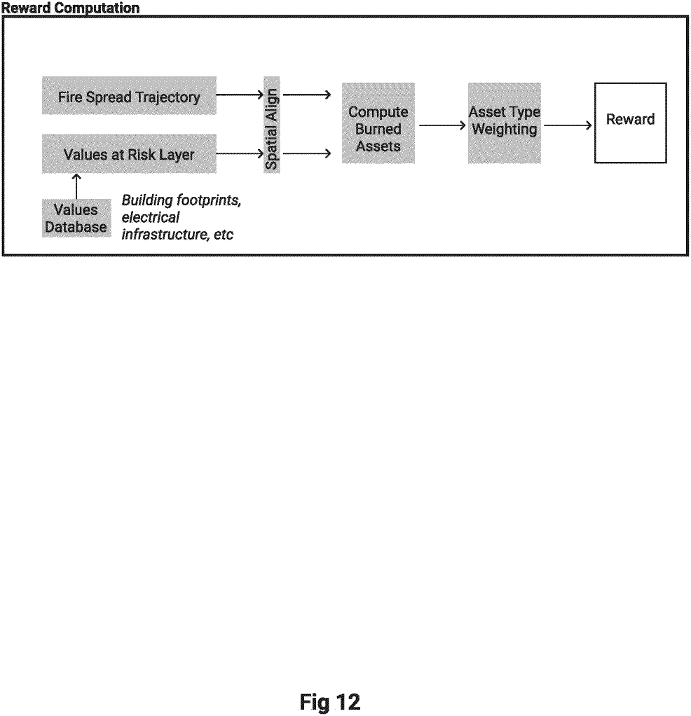

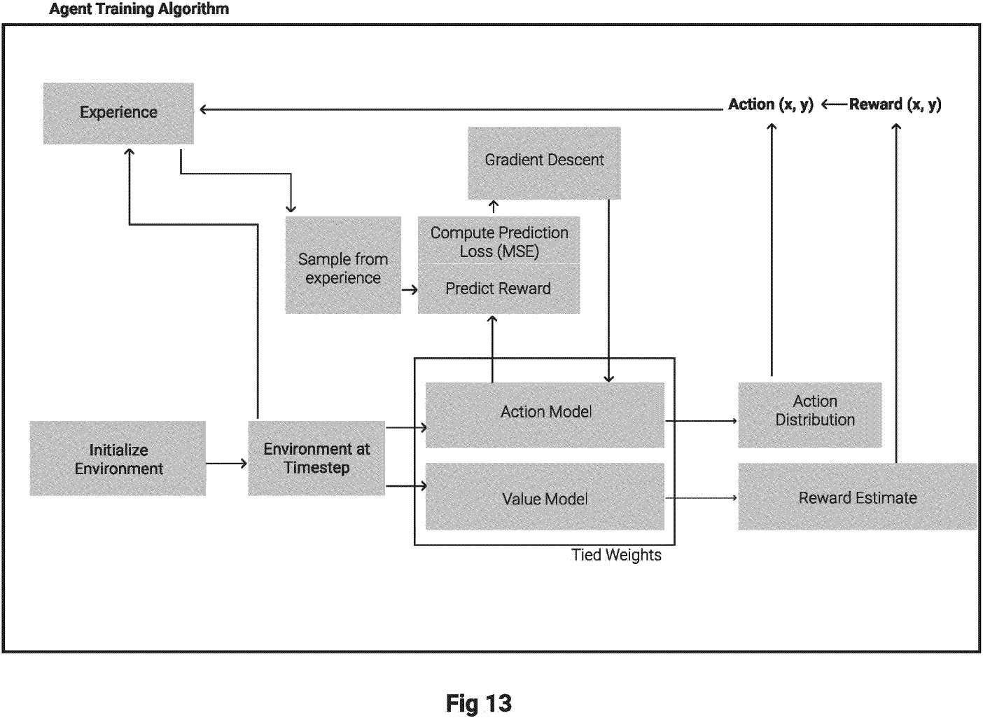

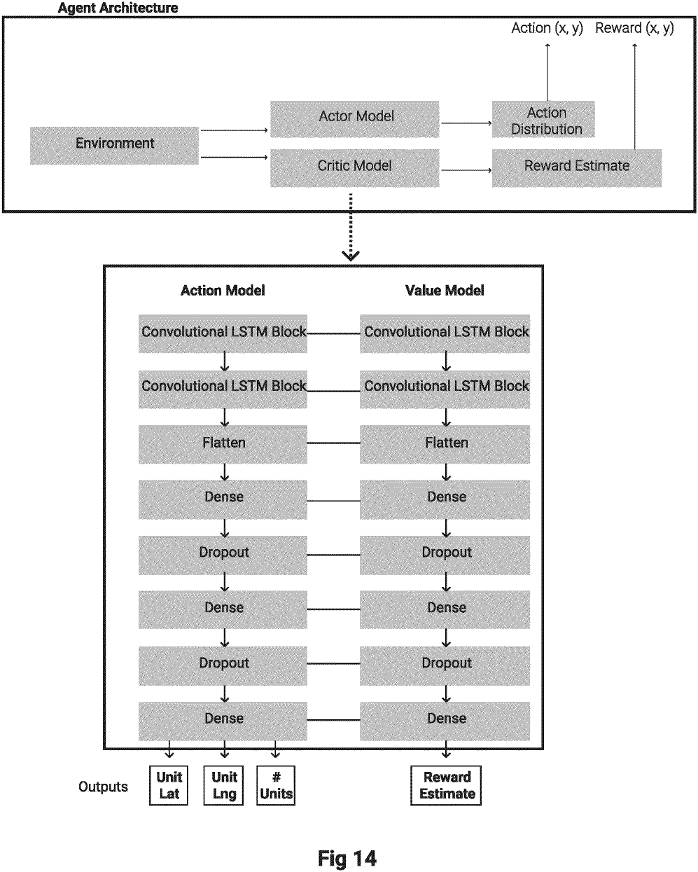

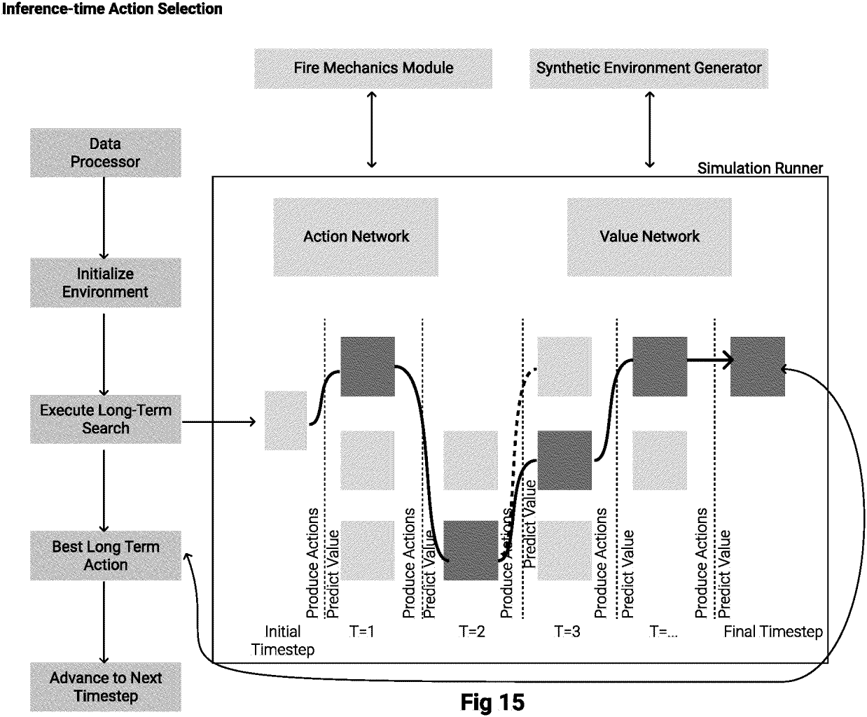

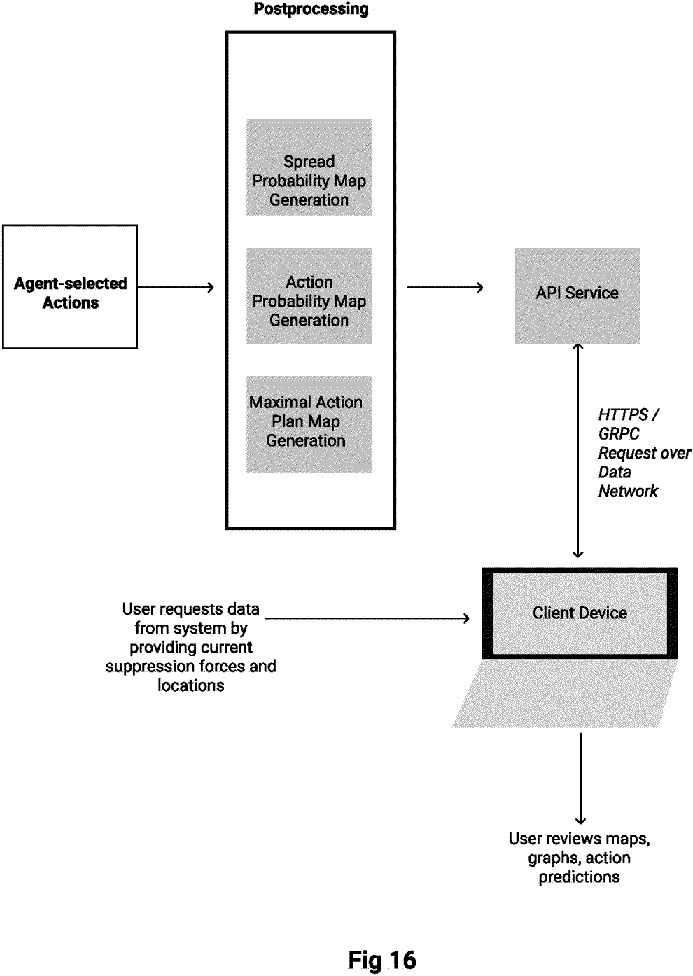

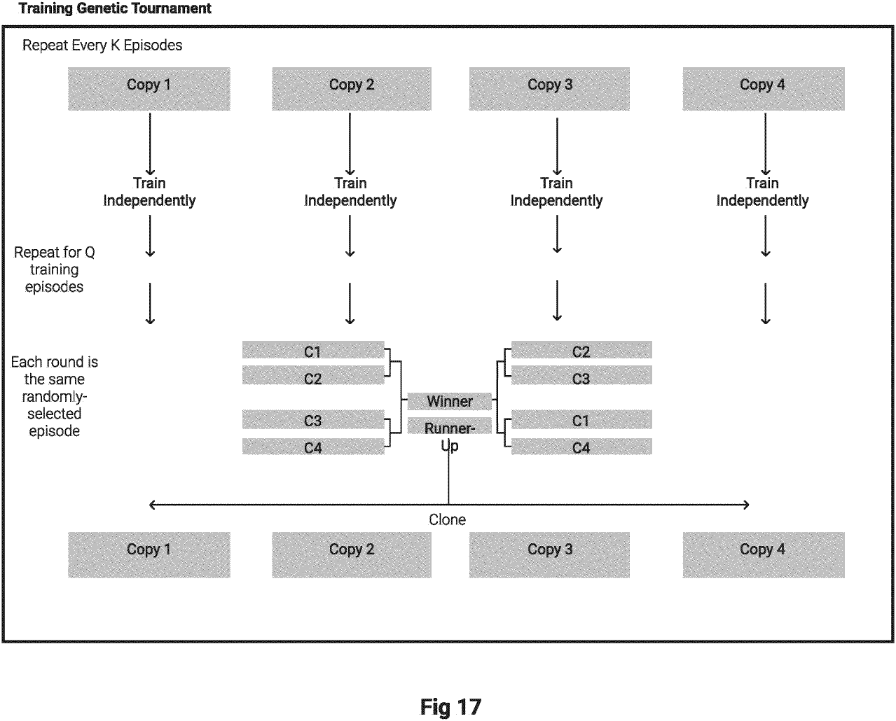

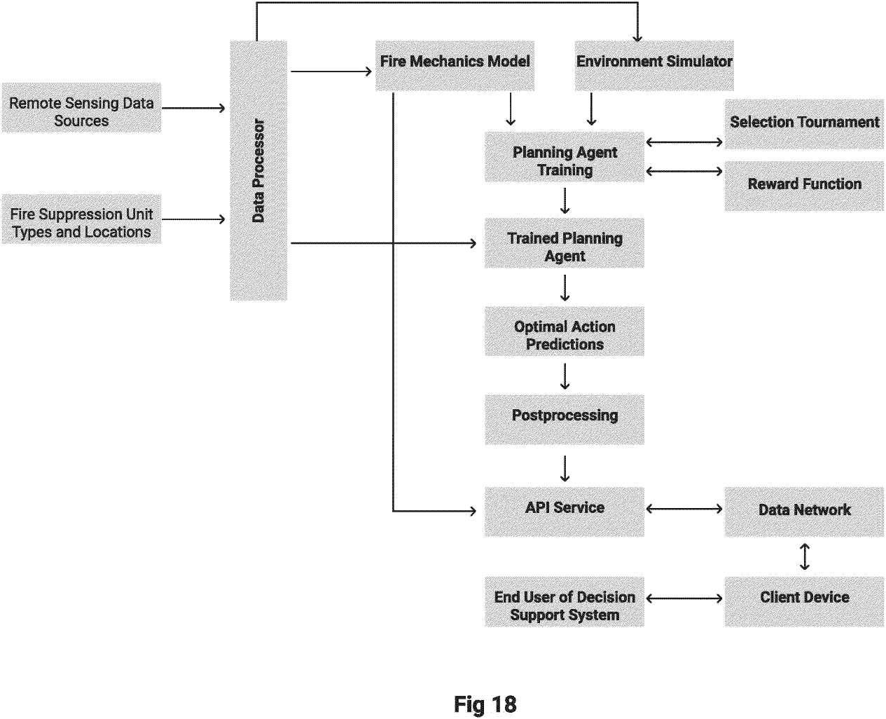

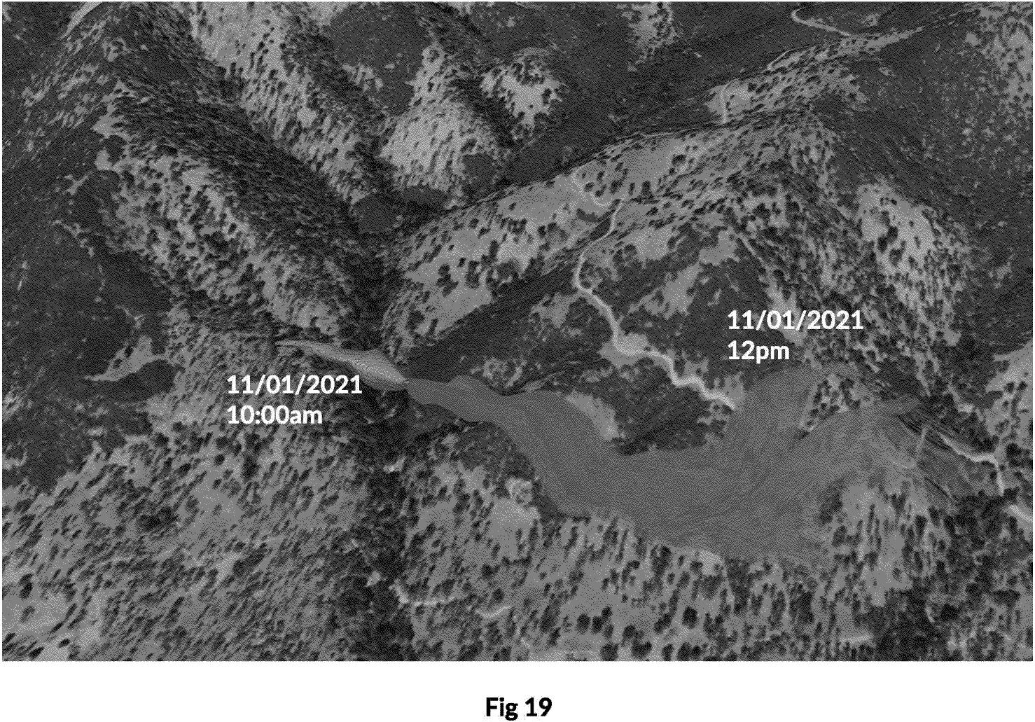

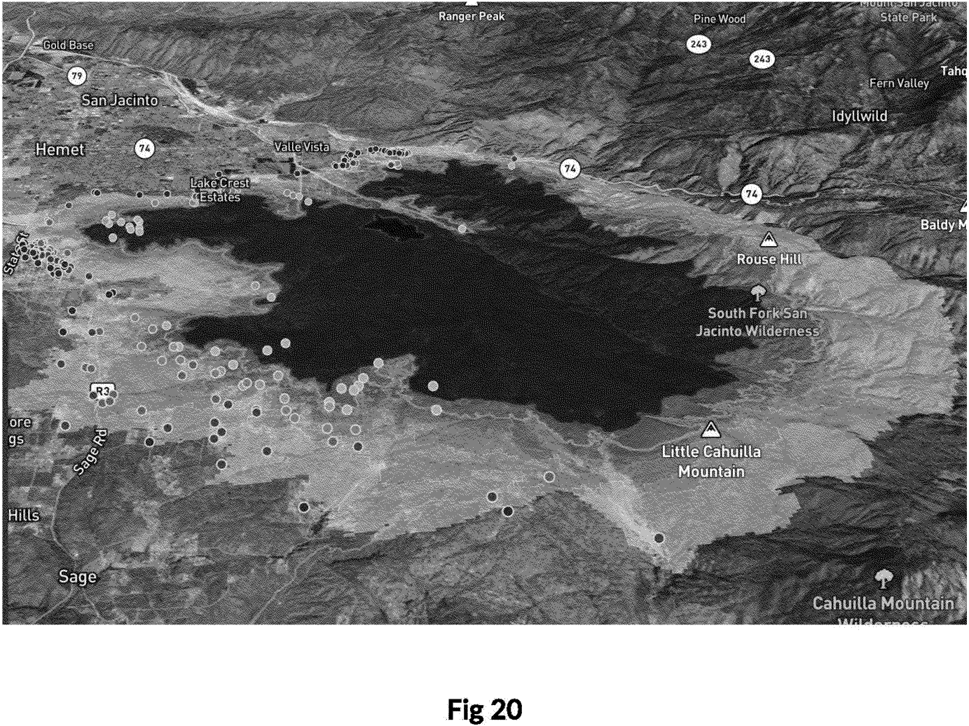

FIG. 3 illustrates an overview of an example embodiment of the wildfire mechanics module architecture. FIG. 4 illustrates an example embodiment of processing invoked on standardized forms for reporting suppression unit type and location to enrich and join that data source with satellite- and airborne sensor data. FIG. 5 illustrates the processing applied to time-varying data sources used in the wildfire mechanics module in an example embodiment, including data sources and preprocessing. FIG. 6 illustrates the processing applied to time-invariant data sources used in the wildfire mechanics module in an example embodiment, including data sources and preprocessing. FIG. 7 illustrates an example embodiment of the network architecture used by the wildfire mechanics module and the data outputs it produces. FIG. 8 illustrates an overview of the example embodiment architecture and the relationship between the processing of suppression resource location form data and remote sensing data obtained from air- and space-borne sensors. FIG. 9 illustrates an example embodiment of the simulated environment module architecture, including data sources, preprocessing, network architecture, and data outputs. FIG. 10 illustrates an overview of how the planning agent incorporates data from its environment and the pool of available suppression resources to produce the value-maximizing set of actions. FIG. 11 illustrates an overview of the optimizer module and the method in which action sets are computed in response to environmental conditions and reward signals. FIG. 12 illustrates a mechanism for computing reward function values. FIGS. 13 and 14 illustrate an example embodiment of the planning agent’s action/value model architecture and a method for training the planning agent. FIG. 15 illustrates an overview of how actions are computed at inference time. FIG. 16 illustrates an overview of the postprocessing done on the action sets produced by the planning agent and the user-initiated data flows over a network between a client device, an API service, and the planning agent. FIG. 17 illustrates an overview of the genetic selection tournament algorithm used in an example embodiment to select for promising algorithmic mutations in the planning agent. FIG. 18 illustrates an overview of the information flows between various system components in an example embodiment. FIG. 19 illustrates an example of a probabilistic spatiotemporal fire growth prediction made by the fire mechanics module. FIG. 20 illustrates an example of a probabilistic fire growth prediction and suppression resource locations produced made available on a client device through the API. Each of these modules and processes are described in more detail below.

### Data Processor Module

The construction of a data-driven wildfire mechanics model is a big data challenge that leverages the recent growth of machine-accessible earth observation data and associated computing investments. The data processor module forms connections with earth-observing instruments, remote sensing datasets, and suppression resource reports to provide the other modules with requisite data.

The data processor module ingests data from a variety of air- and space-borne sensors and from standardized forms indicating the type and location of suppression resources. In an example embodiment, satellite-based sensors are used to provide near-real-time data on environmental conditions such as temperature, wind speed, wind direction, fuel type, vegetation moisture, and vegetation height. Airborne sensors are used to provide data indicating vegetation type and health in the form of high resolution visible-spectrum imagery. Near-real time fire occurrence data is provided by thermal sensors onboard satellite observing platforms, producing twice-daily fire detections at approximately 375 m spatial resolution. Fire suppression resource data is derived from the centralized database for suppression resource ordering Integrated Reporting for Wildland-Fire Information (IRWIN) through standardized ICS 209 forms.

The data processor operates on 256×256 pixel patches, where each pixel represents approximately 250 m^2 on earth. For each patch-day in the input domain, the data processor module is used to harvest environmental data from public data distribution sites (e.g., topography from the USGS Elevation Program, satellite imagery from NASA imagery services, environmental variables from re-analyses such as GridMET), align these layers in time, slice them into patches, and chunk them into the four-dimensional matrix-sequences that are read as input by the wildfire mechanics module and the planning agent.

Incident management status updates describing suppression resource position are joined to the environment pixel patches by aligning the two datasets in space and time. Incident managers on large fires are federally required to file updates every operational period (8-24 hours) using a standard reporting procedure (ICS-209 forms). This data is publicly available for download through IRWIN and includes details on the fire’s activity, resource commitments and needs, and values at risk. Once joined, resource control activities (the count of suppression personnel and resources) are represented at each cell on the grid. ICS-209 reports quantify resources committed to the incident, but do not describe their exact spatial position; we assume that resources are homogeneously allocated across the incident’s heat perimeter.

In particular, the data processor module functions as follows:

1. Data is collected from remote sensing platforms, including air- and space-home instruments such as spectrometers, visible imagery cameras, and lidar sensors.

2. Data is processed with source-specific transforms to create spatially- and temporally-aligned data sets. For example, Lidar point clouds are filtered to obtain only pulses representing the ground and thermal signatures are processed into fire detections using an algorithm developed to minimize the influence of sun glint on false positive detections.

3. Data is made available on public distribution sites in machine-accessible formats, including NetCDF, Web Map Services (WMS), Web Coverage Services (WCS), JSON, XML, or other interchange formats.

4. For each patch of interest (defined by a bounding box and a calendar date), a script fetches the internet-accessible data over HTTPS, FTP, or other protocol over a data network and loads it into computer memory as a floating point matrix. In this matrix, each cell represents a discrete, homogeneous location on the earth’s surface. Layers are classified as time varying (data values change substantially on time scales < 7 days) and time invariant (data values are static or relatively so during a 7 day period). For time invariant layers, only one copy of the matrix is obtained per patch. For time-varying layers, one copy per day is obtained, to resolve daily fluctuations in data value.

5. The pixel matrices are concatenated along the depth dimension to form a 3D matrix of the shape n_layers x X_resolution x Y_resolution. These 3D matrices are stored in compressed, line-delimited JSON files on cloud storage servers for later retrieval.

6. Current and past ICS-209 forms are downloaded from publicly-available databases. Scripts are used to extract the structured- and free-form data on these forms into a machine-readable format. For a given day, resources for each wildfire incident are resolved by joining satellite-derived wildfire occurrence data. The number of suppression resources per pixel is assigned for each pixel by assuming homogenous distribution over the fire detections for that incident, on that day. In the example embodiment, suppression resources include helicopters, engines, and handcrews; the location of each resource type is handled separately. The resulting rasters datasets (one for each pixel patch) are saved to cloud storage servers for later retrieval.

### Wildfire Mechanics Module

The wildfire mechanics module accepts data from the data processor module. This data is in the form of spatiotemporal data matrices describing the wind, weather, topography, and suppression resource type and location. From this data, the mechanics module produces spatiotemporally-explicit predictions of expected fire trajectory over the following 24 hours. The wildfire mechanics module is built with a two-input-branch neural architecture whose outputs are combined to produce a spatially-explicit prediction of expected future fire behavior.

To our knowledge, no other large-scale fire simulator yet exists that produces fire growth and intensity predictions directly from observed weather, topographic, vegetation, suppression resource locations, and satellite-derived fire occurrence data. This is a highly effective means of forecasting fire activity and reliably captures complex fire behavior in heterogeneous landscapes that cannot be resolved in classical combustion models. Recent mega-fires, including the Caldor and Dixie fires in August 2021, both grew at rates as much as 100% faster than predicted by leading fire models. While several fire behavior simulators exist and are widely used in emergency and pre-season fire management, these software are not suitable for training our planning agent because they (a) are deterministic with respect to the environmental and topographic inputs, and do not account for stochastic variations in fire ignition and spread or the model’s epistemic uncertainty, (b) do not directly account for the ability of resources to control the fire’s spread, and/or (c) are relatively inefficient to use for computation over large landscapes. Further, these tools are based on mechanistic combustion physics that describe fire growth, spread, and behavior, which may fail to capture extreme fire behavior (e.g., spotting, explosive growth) or perform well in heterogeneous landscapes.

The wildfire mechanics module uses previous satellite-based thermal detections of wildfire occurrence and the current environment to predict fire occurrence at each location on a landscape at a future time. Since 2012, infrared imaging capabilities on the satellite-based Visible Infrared Imaging Radiometer Suite (VIIRS) and Moderate Resolution Imaging Spectroradiometer (MODIS) instruments have been used to detect the presence of wildfire on sub-kilometer scales. The current work uses VIIRS/MODIS fire detection dataset as a target variable on which to fit a logistic regression using a Convolutional Long Short Term Memory Network (ConvLSTM). Partially auto-regressive, this module accepts 7-day input sequences of environment, suppression resource location, and fire occurrence data as input and produces a prediction of fire occurrence and fire intensity on the following day. The ConvLSTM, an extension of the widely-used LSTM architecture, encodes both spatial and temporal dynamics, making it suitable for making predictions in complex systems, such as the fuel-topography-atmosphere interaction in wildland fire. The neural architecture can provide increased computational efficiency over other extant simulators by leveraging modern deep learning hardware accelerators (i.e., GPUs) and through parallelization.

In particular:

I. One input branch accepts the time-varying matrices. The popular ConvLSTM architecture combines the spatial comprehension of a convolutional neural network with the ability to extract temporal information of a Long Short Term Memory (LSTM) network. With this architecture, the mechanics module extracts features in the input data relevant to fire growth and intensity that vary in both space and time.

2. The second input branch accepts the time-invariant matrices. These layers do not have temporal information associated with them; they are efficiently processed with a sequence of convolutional neural network layers. With this architecture, the mechanics module extracts features in the input data relevant to fire growth and intensity that vary over space alone.

3. The feature maps produced by the two input branches are concatenated and fed through a number of upsampling blocks to produce an output pixel-matrix that aligns spatially with the input data matrices.

4. The mechanics module output is a 3-dimensional pixel grid representing (a) the probability of fire growth at each pixel in the input domain and (b) the conditional fire probability at each pixel in the input domain.

Training is completed on cloud computing servers that support modem machine learning hardware, including Graphics Processing Units (GPUs). Data augmentation, including random rotations, flips, and additive noise is applied to the input data to improve generalizability. Validation is performed by analyzing forecast performance on past wildfires using shape similarity metrics such as Intersection over Union (IoU), Dice Coefficient, and the area of underestimation.

### Synthetic Environment Module

Using a neural adversarial architecture, the synthetic environment generation module produces statistically-representative grids of dynamic environmental layer values (e.g., wind, temperature, relative humidity) that maintain the spatiotemporal structure of the underlying environmental processes. Training the planning agent requires many interactions with an environment; the synthetic environment generator facilitates exploration of realistic, yet synthetic environmental condition,

Further, synthetic environment grids may be input into the behavior dynamics model to facilitate stochastic simulation of many likely weather realizations. Monte Carlo simulation of fire growth under synthetic environments provides probabilistic estimates of future fire spread and conditional intensity.

The environment generation module has the following architecture:

1. An actor neural network uses a set of convolutional layers to produce a candidate set of time-varying environmental layers. This output is conditioned upon the input of (a) the day of year, (b) the latitude of the location represented, (c) the topography of the location (represented as a pixel matrix), and (d) the previous 3 days of environmental layers at that location.

2. A critic network uses a set of convolutional layers to predict whether the actor’s candidate layers are real (drawn from a true historical distribution) or fake (generated by the actor). The critic’s predictions are conditioned by the same inputs as the actor’s.

3. The critic network is trained to minimize the binary cross-entropy loss between the real and predicted labels.

4. During backpropagation, the weights of both the actor and critic networks are updated simultaneously.

Over the course of training, the actor module becomes more skillful at producing realistic, conditioned environmental conditions while the critic network becomes more skillful at determining the authenticity of the produced layers. This module is capable of producing environmental layers with temporal, spatial, and distributional patterns similar to those from real data.

### Wildfire Simulation Runner Module

The wildfire simulation runner module is responsible for generating simulated fire-seasons. Using the trained environment simulation module, time varying environmental layers are produced in an auto-regressive sequence using the past several days of data to produce a prediction for the next day. At each timestep, the synthetic environment conditions evaluated for fire spread and conditional intensity using the wildfire mechanics module. At each timestep, the planning agent may specify locations for zero or more suppression resources.

The simulation is initialized with true (observed) data from January and the model recursively makes predictions until the following December, or approximately 360 timesteps. In this way, an unlimited number of simulated fire seasons may be produced.

The simulation runner operates as follows:
1. Initialize a new simulated season for the region of analysis;
2. For each timestep:
   Call the environment simulator to obtain synthetic weather input data;
   Call the fire forecasting module to make fire growth predictions;
   Optionally, call the policy learning module to make firefighter action decisions;
   Store recently produced layers and other variables needed to produce new predictions in computer memory; and
   Monitor distributions of outputs to ensure stability (and, if necessary, terminating diverging sequences).
3. Store fire season statistics for later retrieval; and
4. Terminate and clean up old runs after successful completion.

This module is capable of running multiple seasons on different processes in parallel, allowing improved efficiency through multiprocessing and cloud-based processing.

### Planning Agent Module

The planning agent is developed by applying a reinforcement learning algorithm to maximize a value function that penalizes both resource movement and the loss of values at risk.

The environment consists of dynamic conditions (wind, weather, topography, vegetation, and fire detections) that vary across the environment and suppression resources (SR; specifically: engines, handcrews, and helicopters) located at particular locations. At each timestep, the model observes the current environmental conditions and locations of each SR. At each timestep, the agent emits structured action directives that indicate (a) the spatial location (in x, y coordinates) at which to move each available SR and (b) the number and type of resources required in the environment at the following timestep. After each timestep, the fire simulator is used to update the environment with new fire ignitions, resources are moved to their new locations, and the agent receives a reward corresponding to the outcome of the previous timestep.

When an SR is moved in the environment, the agent receives a slight negative reward proportional to the distance between the original and new positions, based on the movement ability of that SR type. The agent also receives negative rewards for illegal movements, such as positioning an SR in an ocean or body of water. In an example embodiment, the reward function reflects that all locations on the grid are equally valuable for protection and the agent receives a negative reward proportional to the total number of cells burned at each timestep (i.e., the agent is penalized according to total acres burned). An alternative embodiment includes a reward function that introduces a flexible framework that can be applied by the users of the decision support system to describe arbitrary valuation of assets (e.g., losses of structures can be weighed more than those in unpopulated areas, losses of one type of habitat can be preferred over others).

Planning agent training is completed using proximal policy optimization (PPO), a popular model-free reinforcement learning algorithm that has been used on high-dimensional control tasks with great success.

The architecture of the planning agent is as follows:
1. An action and a value network share an internal state;
2. The action network accepts the time varying and time invariant environmental layers for a given timestep and the location of each SR in the analysis area. For each SR, the actor network produces a prediction of the best location to move the resource to. Outputs are of the form of a length-three tuple, indicating the SR’s next position in the x direction (i.e., longitude), position in the y direction (i.e. latitude), and the number of resources required at the following time step;
3. A value network accepts the time varying and time invariant environmental layers for a given timestep and the location of each SR in the analysis area and makes a prediction of the value (i.e., long-term discounted reward) associated with the action produced by the actor; and
4. The action and the value networks are trained simultaneously using backpropagation where the two models’ shared weights are updated.

The planning agent’s training proceeds as follows:
1. For a simulated fire season (“episode”):
   Initialize the agent’s internal state using the environment generator to provide a set of initial conditions;
   Initialize an episode reward as 0;
   For each timestep:
      For each SR:
         Select the action that has the maximum long-term value as predicted by the value network;
         Update the agent’s internal state by using (a) the synthetic environment generator’s model to predict wind and weather evolutions and (b) the expected results of the selected action;
         Update the total reward with the reward from this timestep; and
         Save action, state, and reward to an experience buffer, saved on a computer storage device.
   Using proximal policy optimization (PPO), randomly sample (action, state, reward) data from the experience buffer;
   Provide random samples to the action/value network. On each example, estimate the difference between the critics expected reward signal and the reward signal obtained through experience. Quantify the difference using the Mean Squared Error between the two data values; and
   Using stochastic gradient descent or other neural network optimizer, update the weights of the actor and critic networks simultaneously using backpropagation to minimize Mean Squared Error.
2. Repeat until convergence or a fixed number of episodes as been reached.

At inference time, the model determines the optimal action on a given date using the following procedure to determine the long-term-value-maximizing action:
1. Initialize an action-value map (Actions);
2. Initialize agent state using near-real time data from the data processor;
3. For a set number of iterations (i.e., days in the future), possibly running multiple independent realizations in parallel, use a stochastic search tree to evaluate the long-term effect of each possible action:
   i. Use the action network to produce a set of possible actions;
   ii. Use the value network to produce the reward expected from each action. Rewards are discounted according to a discount factor that controls the tradeoff between near-term and long-term rewards;
   iii. With probability P, select the action the maximizes the expected reward;
   iv. With probability 1-P, select a random action to facilitate exploration of possibly valuable long-term states;
   v. Advance to the next timestep and repeat. Use the synthetic environment generator and fire mechanics module to produce relevant inputs for the action and value networks; and
   vi. When either (a) the iteration limit has been reached or (b) the tree reaches a terminal state (e.g., the end of fire season), return.
4. Select the action that has the maximum long-term value (e.g., argmax(Actions));
5. Update the agent’s state by using (a) the synthetic environment generator’s model to predict wind and weather evolutions and (b) the expected results of the selected action; and
6. Proceed to the next timestep.

### Genetic Selection

FIG. 17 illustrates an overview of the genetic selection process and the mechanism for selecting candidates after each episode. Self-play is a critical component of many recent RL advances, allowing agents to learn better and more complex strategies than if trained against an expert human opponent or without competition. To gain the advantages of self-play (i.e., the evolution of successful strategies and optimization of the explore/exploit tradeoff), we introduce a tournament-style selection algorithm that selects for promising policies while cutting off unsuccessful lineage after each episode. We train several independent versions of the algorithm concurrently during each episode and at the completion of each training episode, run a round robin tournament where each algorithm version is evaluated against its peers under a variety of input conditions, sampled from the synthetic environment generator. Each round in the tournament consists of one or more evaluation episodes. Each algorithm’s performance in the evaluation episode is scored based on the amount of reward it receives during the evaluation episodes. In each matchup, one algorithmic variant wins (higher reward) and one loses (lower reward). At the completion of the tournament, the algorithm versions with the fewest wins are terminated, while those with the most are cloned for further training. The cloned versions are used in the next training episodes. We observe and study the traits exhibited by the winning versions throughout the training process to understand the tactics most indicative of high performance.

### API Services

An example embodiment may be configured with an application programming interface (API) that allows clients to access planning agent actions and fire mechanics predictions over a data network. FIG. 18 illustrates the data flows between modules under this configuration. Human users interact with a client device (e.g., a mobile phone, tablet computer, laptop) which issues requests over HTTPs, gRPC, or other protocol across a data network. An API service deployed on a cloud service handles these requests and facilitates interaction with the other modules, including the wildfire mechanics module and the planning agent. The API service then returns relevant data to the client device over the same network. This deployment allows clients to easily obtain predictions for future states and action policies. Exposing the API service promotes rich user interactions with the decision support system running on the client device. Under this configuration, users can request action strategies, near-term predictions, and post-processed projections (maps, graphs) of strategy rewards that can be used by fire managers for deploying suppression units in the real world.

Further, the API configuration of the example embodiment enables extensibility, wherein third-party developers can integrate additional application-specific on top of the core information technology framework. In this case, diverse applications can make use of the planning agent and fire mechanics simulation, broadening its applicability to numerous other applications.

### B. Example Embodiments of a System and Method for Application of an On-Parcel Wildfire Risk Assessment Process

A structure’s risk profile - its initial probability of being exposed to a wildfire and its subsequent likelihood of destruction - is a function of risk factors operating on multiple spatial and temporal scales. Mesoscale climatic, topographic, and environmental patterns, and landscape-scale vegetation type, moisture, and continuity can influence the probability of wildfire occurrence in a given region. Parcel-scale factors, including the quantity and arrangement of fuels adjacent to the structure, its design and materials of construction, and the density and topology of other nearby structures, have a particularly significant influence on a structure’s resilience once exposed. During a fire, a structure can ignite through (a) radiant heat exposure, (b) direct flame contact, or (c) through exposure to wind-driven ember showers. While landscape- and community-scale fuel treatment projects are effective at inhibiting fire growth, lowering fire intensity, and increasing the effectiveness of suppression resources, the greatest factors in structure survival are the materials, conditions, and immediate surroundings of the structure.

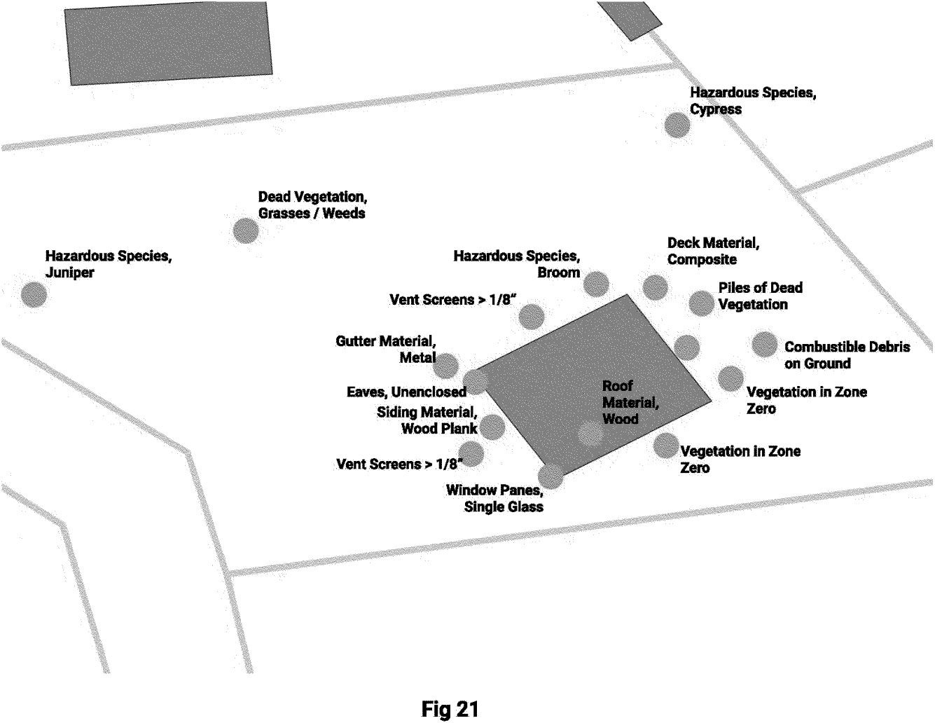

As the threat of wildfires continues to grow across the United States, defensible space inspections (DSI) are a common methodology for hazard mitigation and fire department outreach to at-risk properties. During a DSI inspection, a trained inspector (e.g., firefighter, fire prevention specalist, insurance loss control specialist, or other role) physically visits a parcel and performs a thorough site inspection, recording relevant potential wildfire hazards. Hazards identified during inspections include vegetation and combustibles, structure design, materials of construction, topological relationships between combustible elements, and other factors on the parcel that could contribute to structure ignition. During on-site inspections, inspectors may record data about the location and nature of different potential hazards. This data can be used to in determine the factors most likely to contribute to structure ignition, the parcels most likely to experience structure ignition as a result of home hardening, defensible space, other fire preparedness factors, the most efficient actions to mitigation, and the optimal prioritization for mitigation actions. FIG. 21 illustrates an example of the subset of the types of issues that may be found on an on-site defensible space inspection visit, located around a structure, located within a parcel.

An example embodiment of the present invention includes a quantitative framework that provides an objective, science-based risk assessment methodology that produces quantitative scoring metrics for common findings encountered during on-site defensible space parcel inspections. These scores are derived using several component models that independently track a risk’s contribution to parcel- and community safety. The scores are subsequently used to rank safety issues on a parcel or within an administrative unit and to determine the optimal sequence of mitigation activities.

In particular, the scoring framework:

1. Assigns a numeric value between 0 (lowest risk) and 100 (highest risk) to each geolocated risk. The scalar metric with normalized bounds provides (a) easy communication, (b) the ability to rank issues of various types, and (c) simple aggregation across multiple issues.

2. Enables scoring of both defensible space vegetation discoveries (e.g., dead vegetation, hazardous live vegetation) and home hardening (e.g., roof construction, siding materials) attributes in a single quantitative system.

3. Quantifies a discovery’s impact on the surrounding community as a whole, regardless of parcel or administrative boundaries.

4. Accounts for primary wildfire structure ignition pathways, including radiant and convective heat transfer, structure vulnerability, fuel continuity, and ember cast.

5. Draws on published science and rigorous statistical methods.

6. Accounts for the impact of local topography and other localized conditions, including wind speed, direction, and fuel moisture representative of high fire danger.

7. Facilitates quantitative analysis of tradeoffs between risk mitigation and mitigation cost, using local estimates of mitigation cost from a variety of relevant sources.

8. Facilitates regional-scale planning and assessment of the most efficient uses of limited risk mitigation resources by predicting the optimal sequence of mitigation actions.

9. Is made available over an application programming interface (API) such that fire prevention specialists, incident commands, and other fire management professionals can interact with the risk assessments and cost-benefit tradeoffs within a decision support system running on a client device (e.g., phone, tablet, or laptop).

### Methods of an Example Embodiment

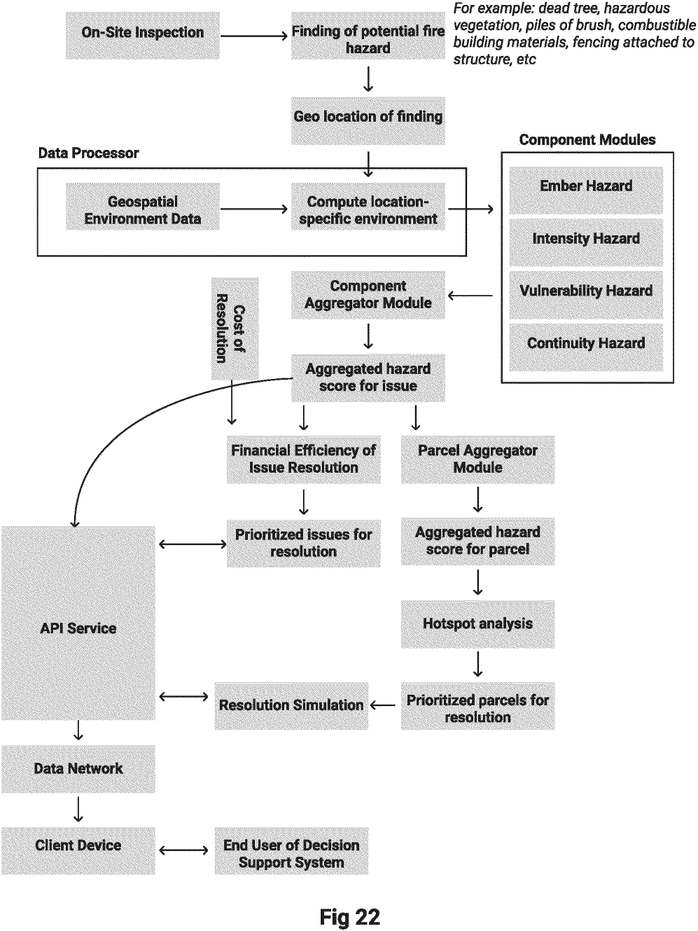

In the example embodiment score for each is a function of the type of issue, local topography, local weather, and topological relationships with nearby structures. Fine-scale variations in structure density, weather, wind, and topography produce a high resolution risk assessment dataset that can be used for numerous applications to wildfire prevention and preparedness. The score for each is computed using a suite of four component models, where each component model provides an independent measure of that risk’s contribution to structure ignition probability through a different potential fire pathway. For each discovery, component scores are aggregated together to create an aggregate score in the range of 0 to 100 that reflects its overall influence on community safety, regardless of parcel or other administrative boundaries. FIG. 22 illustrates an overview of an example embodiment of the risk framework and the flow of data between on-site inspection, component models, risk scores, efficiency calculation, prioritization analysis, and the API system that facilitates interaction by an end user. In the top portion of FIG. 22, an on-site inspection is performed, which generates findings of potential wildfire hazards. These findings are geolocated and augmented with a data processing module. In the right side of FIG. 22, component hazard models are used to provide measures of fire hazard according to different fire hazard pathways and create an overall risk score. In the middle portion of FIG. 22, additional data processing is done to provide efficiency and sequencing prioritization. On the bottom left portion of FIG. 22, data regarding the and its resolution prioritization are exposed over a data network through an API. Client devices enable end users to interact with the risk scores and resolution prioritization.

In the example embodiment, the four component hazard models include:

Vulnerability Component: The vulnerability component evaluates how the presence of a construction material or other hazardous structure design element increases the marginal probability of structure ignition, given other surveyed structure design elements. Using data from over 30,000 post-fire damage inspections (DINS) from over 145 California wildfires, as provided by CalFIRE, a non-linear regression model estimates the marginal increase in the probability of ignition given a particular structural attribute. While the DINS data is coarse, it provides a statistically significant, data-driven approach to evaluating the impact of the most common structural elements in the WUI.

Intensity Component: The intensity component characterizes the risk’s contribution to radiant heating and convective heating on adjacent structures. This component model approximates the heat flux produced during combustion under the specified wind and fuel moisture conditions local to the discovery. For live and dead vegetation types, standard and custom wildland fuel models are used to calculate flame lengths and fireline intensity using Rothermel’s fire behavior models. For other combustible findings (e.g., building materials, household debris), empirical studies of heat production and flame behavior during combustion of similar materials were identified in the literature and used to characterize fire behavior. The risk’s fireline intensity (heat flux per linear foot) indicates the potential heat output given the local wind and slope. An exponential decay based on empirical studies of radiant heating during wildfires is applied to the risk’s fireline intensity value to approximate heat dissipation as a function of distance and the increased potential for spread along the prevailing wind-slope vector. The final intensity component score is the sum of the effective intensities experienced at each structure within 40 m (131 ft).

Ember Component: The ember component evaluates the risk’s potential to deposit burning embers on downwind structures, given uplift from a buoyant plume, gravity, and the prevailing winds. Using a physical flight simulation model, the trajectories of simulated wind-borne embers from eligible types (trees, shrubs, and combustibles) are tracked as the particle is lifted into a buoyant plume above the flame, released into the prevailing wind, and is acted on by gravity and aerodynamic drag until deposited on the ground. As the flight progresses, the particle loses mass as it continues to burn. During the flight, the particle position is tracked in 3 dimensions against the locations of tree canopies, structures, and terrain obstacles using a fine-scale digital surface model. The ember score does not evaluate if the landing location is suitable for ember ignition; rather, it characterizes how likely the discovery is to produce embers that will land within the home ignition zone (e.g., within 3 m (10 feet)) of downwind structures.

Continuity Component: The continuity component quantifies the risk’s contribution to forward fire spread and structure ignition, either by providing a contiguous path of combustible materials suitable for fire spread, by serving as a fuelbed receptive to ember showers, or by increasing the likelihood that key vulnerable areas of the structure (such as the attic, crawl space, or living area) of the structure will be exposed to ember intrusion. The continuity score uses a rubric-based heuristic and draws on published experimental and observational evidence documenting the importance of various types. Because structures with less than 30 ft (10 m) of spacing to other nearby buildings are less vulnerable to structural weaknesses and on-parcel fuels than to structure-to-structure ignition, the continuity heuristic is adjusted to reflect the separation distance between structures in the vicinity of the discovery location.

The effort required to resolve each risk varies based on the type of mitigation required (e.g., landscaping vs. roofing). When characterized on a common scale that captures both the benefits of risk reduction and the relative costs of resolution, a metrics based system can aid in navigating the cost-benefit tradeoffs (Simon, Crowley, and Franco 2022; Chung 2015; Konoshima et al. 2010; US Office of Policy Analysis 2012). The benefit-to-cost ratio or efficiency of each discovery is computed as the composite risk divided by the average cost of resolving a risk of that category.

The component contributions for each issue category are determined a priori, using a rubric that assesses:
1. Likelihood of combustion and probable combustion characteristics;
2. Height and likelihood of casting embers a substantial distance;
3. Ability to be integrated into the statistical vulnerability model (which is based on the limited CalFIRE damage inspection schema); and
4. Likelihood of the issue to promote forward fire spread or serve as a fuelbed receptive to wind-borne embers.

In the example embodiment, the risk score for a given is computed as follows.
Using a data processor module, location-specific wind and fuel moisture conditions are computed for the risk’s location. Localized estimates for wind speed and direction are computed using the computer program WindNinja using historical wind observations. Localized fuel moisture is calculated using the computer program Flammap using a stream of historical temperature, solar radiation, and relative humidity observations.
Using a set of component hazard models, zero or more assessments are made for the risk’s contribution to community safety, through ember transport, intensity, structure vulnerability, or fuel continuity. For findings involving ember transport, the fire intensity is computed first to determine the buoyancy of the heat plume and the ember lofting height. The component models are discussed in more detail below.
Using a component aggregator module, each component model value is normalized into a score on the range 0-25 based on heuristic scaling rules. Normalized scores are aggregated together to provide an overall score for the ranging from 0 to 100.
Optionally, data from grants programs, local prevailing wages, and other sources may be combined with the risk score to analyze the cost-benefit “efficiency” between the benefit of removing the and the cost of performing that removal. Efficiency is calculated in units of risk reduction per dollar and is computed by dividing the risk score by the estimated cost of resolution.
Optionally, risk scores and efficiency metrics are made available over a data network through an API.

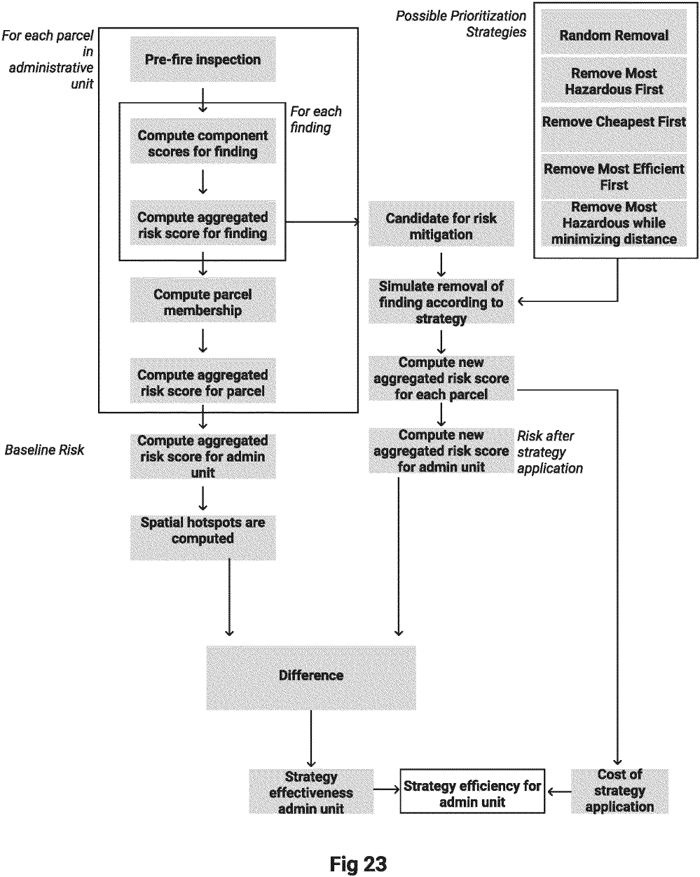

FIG. 23 illustrates how, in the example embodiment, site inspection findings may be used to determine the optimal resolution sequencing on a parcel or other administrative unit (e.g., fire district) through cost-benefit analysis. In the example embodiment, a risk score is calculated for a given parcel or other property boundary as follow:
1. Using a property boundary dataset, all findings located on a particular parcel are identified;
2. The risk scores for all findings on the parcel are computed as described above;
3. Using a parcel aggregator module, all risk scores are aggregated together to produce a parcel-level risk score;
4. Optionally, the optimal sequence of resolutions (e.g., the sequence that maximizes benefit while minimizing cost) is obtained through repeated simulation of various resolution strategies and comparing risk reduction to cost;
4. Spatial statistics (hotspots) are computed on parcel-level scores to identify statistically significant geographic hotspots and trends; and
5. Optionally, parcel-level scores and mitigation sequencing data are made available over a data network through an API.

### C. Additional Example Embodiments of the Disclosed Systems and Methods

Ignition occurs in a combustion reaction when heat energy is sufficient to raise the temperature of a receiving fuel to the temperature of pyrolysis, at which point solid fuel begins to degrade into vapors that can ignite to form an exothermic reaction. In the case of structures in a wildfire, heat is supplied by radiation from the combustion of vegetation or other combustible fuels, by direct contact with flames, or by the transfer of heat from one location to another via flaming or smoldering embers deposited on or around the structure. Although small, embers can accumulate and provide sufficient heat to quickly ignite combustible surfaces (Quarles and Standoher-Alfano 2018) (Suzuki et al. 2012). Once a portion of the structure is ignited, that reaction can provide sufficient heat to surrounding structural elements to facilitate fire spread (Quarles et al. 2010). Some building materials and designs can slow the combustion reaction (i.e., increase the temperature required for ignition), prevent fire spread once ignited (e.g., melt instead of burn), or restrict ember accumulation where ignition would be easiest or most costly.

When considering the structure ignition problem, it is useful to think in the context of heat transfer. Each on-parcel risk factor can act as one or more of (a) a heat source, producing radiative heat and/or flames, (b) a source of embers that can transfer heat to distant locations when carried by the wind, (c) a material that can raise the temperature required for structure ignition or otherwise inhibit the combustion reaction, or (d) an element that can reduce the likelihood of flame exposure or ember accumulations in areas that could ignite easily, thereby reducing the heat flux on nearby buildings. A single discovery may contribute to multiple of these pathways. For example, a stand of shrubs may create a fuelbed receptive to ember-driven ignition, it may expose nearby structures to radiant heat and flames during combustion, and it may produce embers that can ignite spot fires or structures downwind.

Not all risk factors are equally impactful in facilitating structure ignition (Syphard, Brennan, and Keeley 2017; Hakes et al. 2017). Results from numerous empirical, observational, and theoretical studies that use experimental burn chambers, computational fluid dynamics (CFD), post-fire surveys, and other approaches suggest that some types of on-parcel risk factors are more highly correlated with structure ignition than others (Caton et al. 2017; Manzello and Suzuki 2014; Syphard, Brennan, and Keeley 2017; Troy et al. 2022; Nguyen 2021). Moreover, the spatial context and unique physical setting of each discovery creates differences that can alter the impact of different instances of the same type of hazard, even when located on the same parcel or within the same neighborhood. For example, depending on slope, surrounding vegetation, moisture content, topological relationships with other structures, and other conditions, a patch of hazardous vegetation (e.g., juniper tree) may pose an outsized risk to surrounding structures when compared to the average patch of the same type of vegetation. It is therefore important to assess the risk of each on-parcel discovery in its spatial and environmental context to provide an accurate assessment, rather than attempting to create a score for each class of discovery in aggregate.

No single modeling system currently accounts for the heat production, ember transport and deposition, and structural ignitability from multiple types of on-parcel wildfire hazard, including vegetation, combustibles, structural materials, and structure design. In this analysis, four component submodels are employed to evaluate each discovery’s role within the pathways described above. Integrating standard wildfire science principles and characterizing multiple aspects of the structure ignition process, the framework offers a flexible system for assessing, comparing, and aggregating risk factors found on private parcels. In this work, we approximate marginal probabilities of ignition with a simplified scoring framework that utilizes score indexes to indicate relative wildfire hazard.

### Component Modules

### Advantages

The multilevel risk assessment framework has several advantages. First and foremost, it provides a flexible, modular way to integrate multiple aspects of WUI fire risk into a single, quantitative scoring framework, allowing a comprehensive assessment of multiple common fire pathways with compatible scoring. While a host of observational, theoretical, and experimental studies provide estimates of risk for individual classes of discovery or for different modes of structure ignition, these studies are heterogeneous and results are not directly comparable. At the loss of some specificity, the framework used here can integrate the impact of multiple fire hazards and many discovery classes.

Second, it enables seamless, multi-scale aggregation of on-parcel risks, from the discovery itself to higher level units including parcels, arbitrary grid cells, and JPA zones. While the hazards created by a discovery may span parcel or administrative boundaries, the framework assigns all those risks to the discovery where they originated. This aids planning and policymaking from this framework, because it assigns a geographic source to wildfire hazard, which can then be targeted and removed.

Third, the component scores and auxiliary data objects, such as flame lengths, ember deposition, and structural vulnerability, can be disaggregated and analyzed separately to gain a more complete contextualization of the risks inherent in on-parcel discoveries.

### Inputs

### Spatial Context and Environmental Position

The data processor module uses each discovery’s GPS coordinates to assign the following attributes to each:
Slope
Aspect
Canopy Height
Canopy Base Height
Local wind speed
Local wind direction
Local 1-hour fuel moisture
Local 10-hour fuel moisture

The GPS coordinates of each discovery are also used by the data processor module to compute the bearing (azimuthal direction) and distance to each structure within a 130 ft (40 m) radius, using structure footprint data from a Buildings Footprint dataset. To eliminate the influence of outbuildings on scoring, only buildings with footprints greater than 120 ft2 (11.1 m2) are considered.

### Wind, Weather, and Moisture

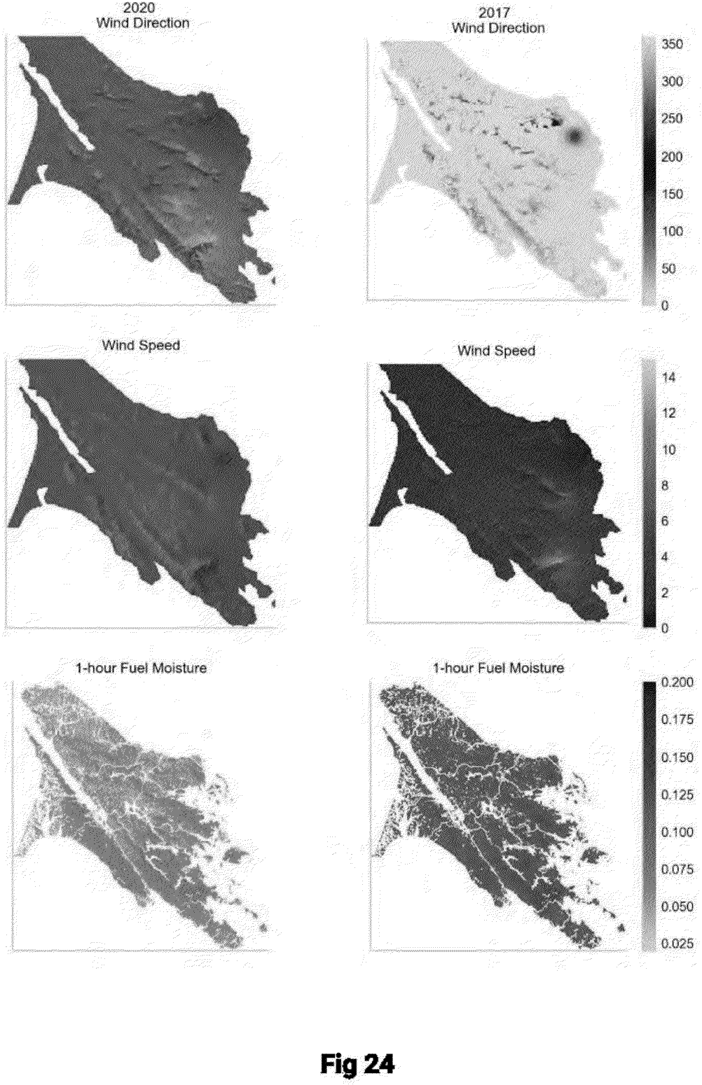

In an example embodiment, two fire weather scenarios are used to illustrate these common late-summer fire wind regimes. These scenarios use historical data to provide a concrete and realistic reference point under which to evaluate on-parcel risk. FIG. 24 illustrates two fire weather/wind scenarios for an example embodiment. FIG. 24 shows wind direction (top), wind speed (mph, middle), and 1-hour fuel moisture (bottom) for the 2020 scenario (left) and the 2017 scenario right. The color scale is the same for both scenarios.

Referring to FIG. 24, the 2020 Scenario illustrates an average set of conditions, as experienced on Oct. 8, 2020. This scenario is representative of sustained moderate winds from the west-to-northwest (250-350 degrees). Conditions are generally cool (55-65° F. in the night and reaching ~70° F. at mid-day) with very high relative humidity (100% at night and ~60% during the day).

Referring to FIG. 24, the 2017 Scenario reflects the conditions experienced on Oct. 8, 2017 and illustrates the severe conditions that supported the rapid growth of the destructive Tubbs fire in neighboring Napa and Sonoma counties. Moderate-to-high gusty winds out of the north and east (0-100 degrees) accompanied very low relative humidities (20%) and high daytime temperatures (>85° F.).

Historical data for these scenarios was obtained from Synoptic Data’s Mesonet API (Data n.d.). Freely available online, this data portal provides access to numerous hourly weather records from remote automated weather stations (RAWS).

Terrain can alter the prevailing wind flow by modifying or channeling the flow through complex topographic features. Diurnal effects, atmospheric instability, and cross winds can further alter the wind characteristics experienced at each point on the landscape (David Whiteman 2000). While the five RAWS stations offer observations of wind speed and direction during the chosen scenarios, these observations may differ from the actual conditions experienced at other locations on the landscape, particularly if those locations are located in complex terrain. The CFD wind solver WindNinj a was used to create spatially explicit estimates of wind speed and direction at 100 m resolution (J. Forthofer, Butler, and Wagenbrenner 2022). Using the RAWS station data as input, WindNinja computed the flow paths around topographic features to produce a spatially-resolved wind-field. The derived dataset resolves several key features, including channeling around Mount Tamalpais, higher velocities along ridgetops and mountain tops, and directional differences in flow on the lee side of ridges. Although the CDF solver has limitations, particularly in complex terrain, recent work has shown that wildfire behavior modeling using Wind Ninja can produce more accurate assessments of fire behavior than using a uniform wind speed and direction (J. M. Forthofer et al. 2014).

Fine-fuel moisture content, which influences combustion intensity and fuelbed receptivity, varies as a function of atmospheric humidity, temperature, and incident solar radiation (Catchpole et al. 2001; Viney 1991) (Nelson 2001; Slijepcevic, Anderson, and Matthews 2013). In addition to weather-induced changes in fuel moisture arising from the temporal evolution of cloud cover, temperature, and precipitation, fuel moisture varies with topography and vegetation due to shading effects from tree canopies and aspect and slope differences that change based on latitudinal position (Nelson 2000; National Wildfire Coordinating Group n.d.; Harrington 1982; Estes et al. 2012). The Flammap modeling system (Finney and Charles 2022) was used to estimate the equilibrium moisture content at 5 m resolution.

### Component Modules

### Intensity Component Module

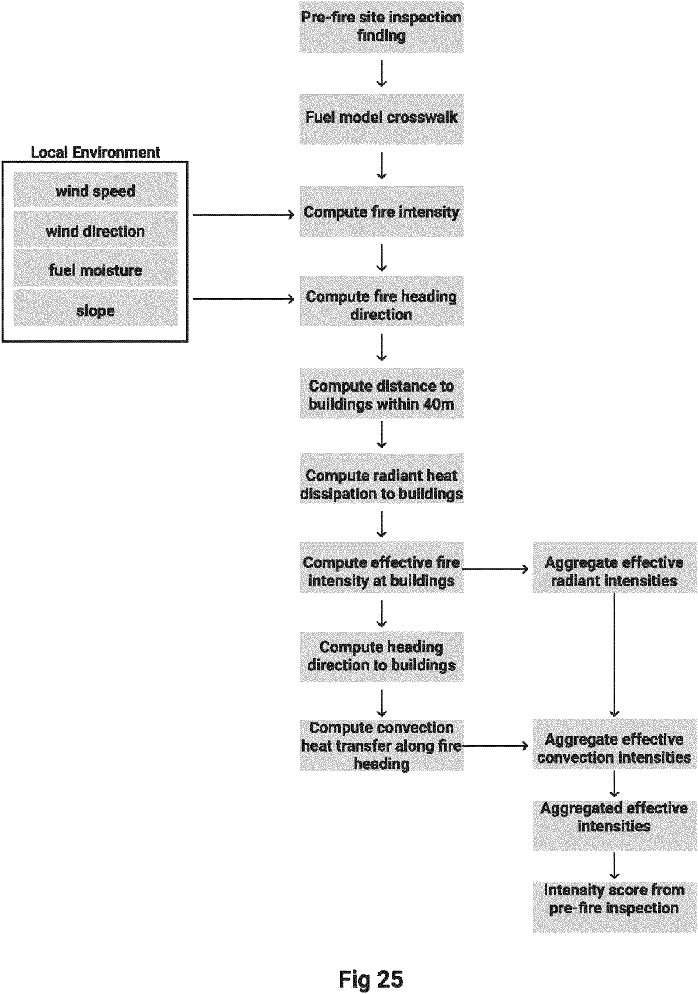

The intensity component assesses a discovery’s contribution to radiant and convective heat transfer to adjacent structures in the WUI environment. This index is calculated by estimating the fireline intensity produced during the combustion of the flaming front under the local wind, moisture, and topography, calculating the effective fireline intensity (EFI) experienced at each nearby structure using a decay curve that approximates the dissipation in radiant heating with increasing distance and effect of convective preheating, and normalizing the resulting value onto a scale of 0 to 25. FIG. 25 illustrates an overview of the intensity component architecture in the example embodiment.

In the example embodiment, the intensity component is computed as follows:
1. findings are mapped to wildland fuel models or experimental estimates of heat production;
2. Fire intensity is computed using local estimates of environmental variables, such as wind speed, wind direction, fuel moisture, and slope;
3. The primary fire direction is calculated from local estimates of wind direction, wind speed, slope, and fire intensity;
4. A database is used to identify buildings within 40 m;
5. The radiant heat reception at nearby buildings is estimated as a function fire intensity and distance;
6. The convective heat reception is estimated as a function of fire intensity, fire direction, and building direction;
7. Heat reception at each building is aggregated; and
8. Heat reception at all buildings is aggregated and normalized onto a 0-25 point scale using heuristic scaling rules.

### Vegetation Discoveries

### Fuel Models

In the case of live and dead vegetation discoveries (e.g., shrubs, trees, grasses, litter and debris), a wildland fuel model is used to represent the surface fuelbed. Where possible, standard fuel models from the set of 40 standard fuel models are used (Scott 2005). For example, standard fuel model SH5 (High Load Dry Climate Shrub) is used to represent Broom plants and standard fuel model GR1 is used to represent poorly maintained ground cover. Fuel model assignment was performed using assumptions about the structure of the discovery (e.g., relative volumes of fine dead and live fuel, arrangement, depth, etc.) and using the descriptions of how standard fuel models carry fire.

In some cases, no standard fuel model was available to accurately describe a class of discoveries. Because standard fuel models are designed to represent wildland fuelbeds, they do not cover some vegetation conditions common on private parcels. For example, accumulation of 100-hour fuels (>3″ diameter) is not as likely to occur on residential properties as in natural fuelbeds, since even infrequent maintenance is likely to remove heavy fuels, particularly under porches, in gutters, or on roofs. In these cases, a custom fuel model was designed to represent on-parcel fuels. These custom fuel models adapted standard fuel model parameters using expert judgment to produce more realistic representations of fuels encountered adjacent to structures in the WUI.

### Fireline Intensity Calculation for Vegetative Fuels

For each discovery, the fireline intensity, heat per unit area, flame length, and effective direction (i.e., the azimuthal direction of the wind-slope axis) were calculated using the standard BEHAVE formulas as described in (Andrews 2018). The reader is referred to (Andrews 2018) for complete derivation and explanation of each quantity.

First, reaction intensity (BTU/ft²-min) is calculated from the geometric and physical properties of each size class present in the fuel bed and the potential reaction velocity for that fuel bed, which is a function of fuel arrangement.

$${I}_{r} = \overline{Γ} {\sum }_{i = 0}^{n} {w}_{i} {h}_{i} {η}_{i} {m}_{i}$$

Where Γ is the optimal reaction velocity for a fuelbed with the given arrangement (min-1), wᵢ is net fuel loading of size class i, hᵢ is the heat content from size class iηᵢ is the mineral damping coefficient for size class i, and mᵢ is the moisture damping coefficient for size class i.

Following (Anderson 1969), the residence time of the flaming front (in minutes) is estimated as tᵣ = 8 ∗ d, where d is the diameter of the fuel (in inches). Using dimensional analysis and the fuelbed’s characteristic surface area to volume ratio σ, the flame residence time for a given fuelbed can be calculated as tᵣ = 384/σ.

The total energy release per unit area Hₐ (BTU/ft²) is then calculated as the product of the reaction intensity and the flame residence time: Hₐ = Iᵣ_{*} tᵣ.

Subsequently, rate of spread is computed using the Rothermel’s standard formula:

$$R = \frac{{I}_{R} ζ \left(1 + {ϕ}_{w} + {ϕ}_{s}\right)}{{ρ}_{b} ε {Q}_{i g}}$$

Where:
I_{R} is the total energy production rate per unit area in the flaming zone, measured in BTU/ ft²/s
ζ is the no-slope, no-wind propagating flux ratio which describes the fraction of energy that heats adjacent fuel particles.

ϕ_{w}and ϕₛare dimensionless multipliers that represent the increased propagating flux from wind and slope, respectively.

ρ_{b} is the characteristic bulk density of the fuel bed, measured in lbs/ft³

∈ is the effective heating number which represents the fraction of a fuel particle that is heated to ignition temperature at the time flaming combustion starts.

Q_{ig}is the heat of pre ignition, which represents the heat required to ignite the fuel, measured in BTU/lb.

Finally, fireline intensity (BTU/ft/min) is calculated as the product of rate of spread and heat release rate to produce an estimate of the heat released during the combustion of available fuel at the flaming front (Andrews 2018): I_{b} = Hₐ_{*} R.

While not used directly, flame length (ft) is a valuable property to model, since it is readily apparent during fire suppression activities and gives a relatable property by which to measure fire intensity. While it is not directly used in the intensity component model, it is calculated and used for additional contextual analysis.

$${F}_{l} = 0.45 {I}_{b} {}^{0.46}$$

### Non-Vegetation Combustible Discoveries

Non-vegetation combustible discoveries, such as household garbage, gasoline cans, play structures, and fences, cannot be easily translated into the wildland fuel model framework. In these cases, experimental studies of combustion were used to derive characteristic fireline intensity, flame lengths, and heat output for the discovery. While environmental conditions, particularly wind speed and moisture, are likely to alter the true fire behavior from those observed in controlled studies, these studies provide a set of benchmark values for fire intensity of similar objects. Further, non-vegetation combustibles are often located in areas of the home that are not subject to topographic influences (e.g., garbage cans are located on flat hardscaping) and may be in areas sheltered from the wind, such as under a deck or in the lee of a structure, making direct estimation more appropriate than computing using the Rothermel-based semi-empirical formulas.

Most commonly, combustion studies report heat release rate (HRR) as a primary output, measured in kW (kJ/s). kW is converted into BTU/min by multiplying the HRR by the unit conversion factor of 56.87. For a given volume of fuel g (lbs), the energy release per unit mass (δ, BTU/lb/min) is computed a

$${I}_{m} = \frac{H R R}{g} .$$

Using the mass (m, lb) and area (a, ft²) assumed for a particular discovery type, the characteristic density of the discovery (lb./ft) is computed as

$${ρ}_{d} = \frac{m}{a} .$$

Thus, the heat per unit area (BTU/ft²/min) for a particular class of discovery is calculated as Hₐ = Iₘ ∗ P_{d} .

Using an empirical measurement for rate of spread R (commonly 0.7 ft/min), fireline intensity (BTU/ft/min) is calculated as for vegetative fuels I_{b} = Hₐ ∗ R.

### Fire Spread Direction

The fire’s total rate of spread R can be expressed as its wind and slope components. For non-vegetation fuels, wind and slope coefficients are assumed to be zero.

$$R = \frac{{I}_{R} ζ \left(1 + {ϕ}_{w} + {ϕ}_{s}\right)}{{ρ}_{b} ε {Q}_{i g}} = {R}_{0} \left(1 + {ϕ}_{w} + {ϕ}_{s}\right) = {R}_{0} + {R}_{0} {ϕ}_{w} + {R}_{0} {ϕ}_{s}$$

The respective wind and slope vectors are expressed relative to the upslope (ω) as S = (R₀ϕₛ, 0) and W = (R₀ϕ_{w}cosω, R₀ϕ_{w}sinω). Vector addition is used to compute the direction (α) and magnitude (D_{H}) of the primary wind-slope axis. As shown in (Andrews 2018), given the wind direction ω, specified in radians relative to the upslope direction, these components can be calculated as:

$$X = {R}_{0} {ϕ}_{s} + {R}_{0} {ϕ}_{w} c o s ω$$

$$Y = {R}_{0} {ϕ}_{w} s i n ω$$

$${D}_{H} = \sqrt{{X}^{2} + {Y}^{2}}$$

$$α = s i {n}^{- 1} \left(\frac{\left|Y\right|}{{D}_{H}}\right)$$

### Effective Fireline Intensity and Radiant Heat Dissipation

The radiant heating received at a location (e.g., a structure’s wall) can be related to the amount of heat emitted by a flame of given dimensions if the geometrical relationships between the flame, incident surface, and obstacles between the two are known (Cohen and Butler 1998; Cohen 2000, 2003) (J. E. Hilton et al. 2020; J. Hilton et al. 2017). Experimental studies have shown that incident heat flux can be compared to the critical value needed for piloted combustion of wood (~7 kW/m2) to predict structure ignition (Cohen 2000). These calculations, however, are generally too complex to apply in real-world applications, because they require both careful specification of the flame dimensions and the calculation of the “view factor” between the receiving surface and the flame. The view factor is a geometric term that represents the proportion of radiation leaving the flame that strikes a receiving object (J. Hilton et al. 2017) that varies with topography, vegetation, and other barriers that shield the structure from the emitted radiation (Cohen and Butler 1998; Cohen 2000, 2003). To fully calculate the view factor requires evaluation of all possible lines of sight from the flame surface to the receiving point accounting for possible obstructions and attenuation through smoke and vegetation (J. Hilton et al. 2017).

Because of the complexity in calculating the view factor, limited information on potential obstacles between the flame and the structure, and variations in ignition temperature of different structural materials, the intensity component does not estimate the probability that a structure will receive a heat flux that exceeds the critical threshold for ignition. Instead, it provides a holistic characterization of the intensity of the fire front during combustion of the discovery. Fireline intensity (the product of the heat content of the burning fuel, the quantity of fuel consumed in the flaming front, and the front’s rate of spread) provides a useful indication of the fire behavior and is widely used in comparing different fires and their behaviors under different fuel, weather, and topography conditions (Andrews 1982; Alexander 2000; Roussopoulos and Johnson 1975). Unlike heat per unit area, which measures the integral of heat emission over time, fireline intensity accounts for the residence time of the flaming front and the wind and slope effects that can modify the intensity as the front passes (Manzello 2020). Although not directly observable, fireline intensity is readily experienced when working near the fireline and it can be used to choose appropriate suppression techniques (Andrews 1982).

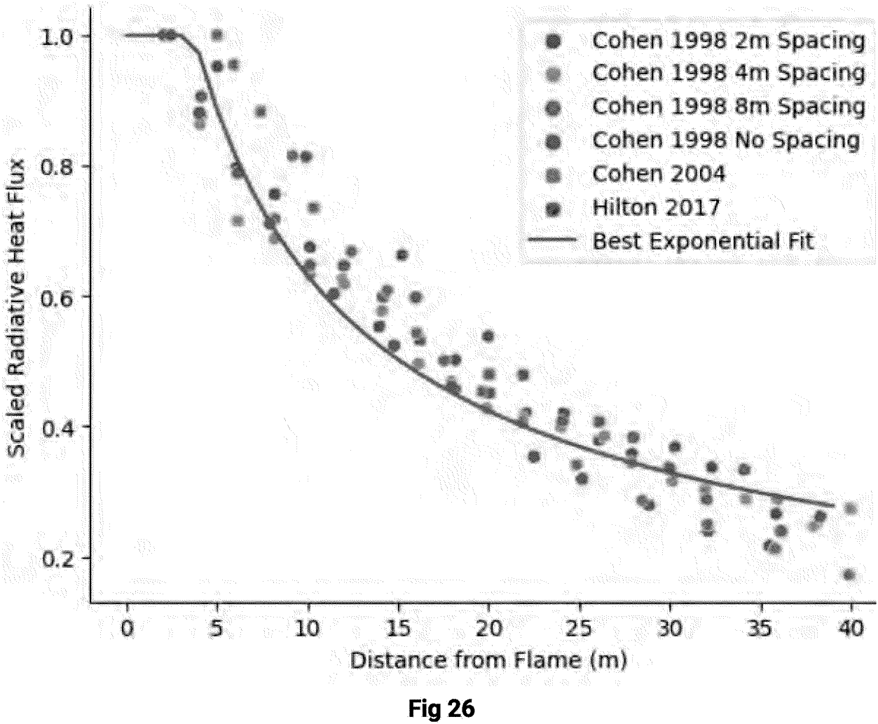

Although the view factor, and thus, the exact heat flux from a discovery incident at a structure, cannot be calculated directly, a worst-case (i.e., unshielded) estimate of heat dissipation is derived from studies of incident heat flux that show that radiation decays exponentially with distance (Cohen 2003, 2000; J. Hilton et al. 2017; J. E. Hilton et al. 2020). FIG. 26 illustrates radiative heating studies and a line of best fit between the measured datapoints. Studies included are (Cohen and Butler 1998; Cohen 2003; J. Hilton et al. 2017). As shown in FIG. 26, receptors within 32 ft. (10 m ft.) of the emitting location will receive 75% or more of the original radiation; however, as distance increases to more than 30 m (98 ft.), recipient radiation decreases rapidly to less than 30%.

If the role of radiative shielding is negated, the radiative heat dissipation factor (γ_{Hᵢ} ) can be estimated a function of the distance between the discovery and the receiving structure (dᵢ, meters):

$${γ}_{{h}_{i}} = \frac{a}{{\left({d}_{i} + b\right)}^{k}}$$

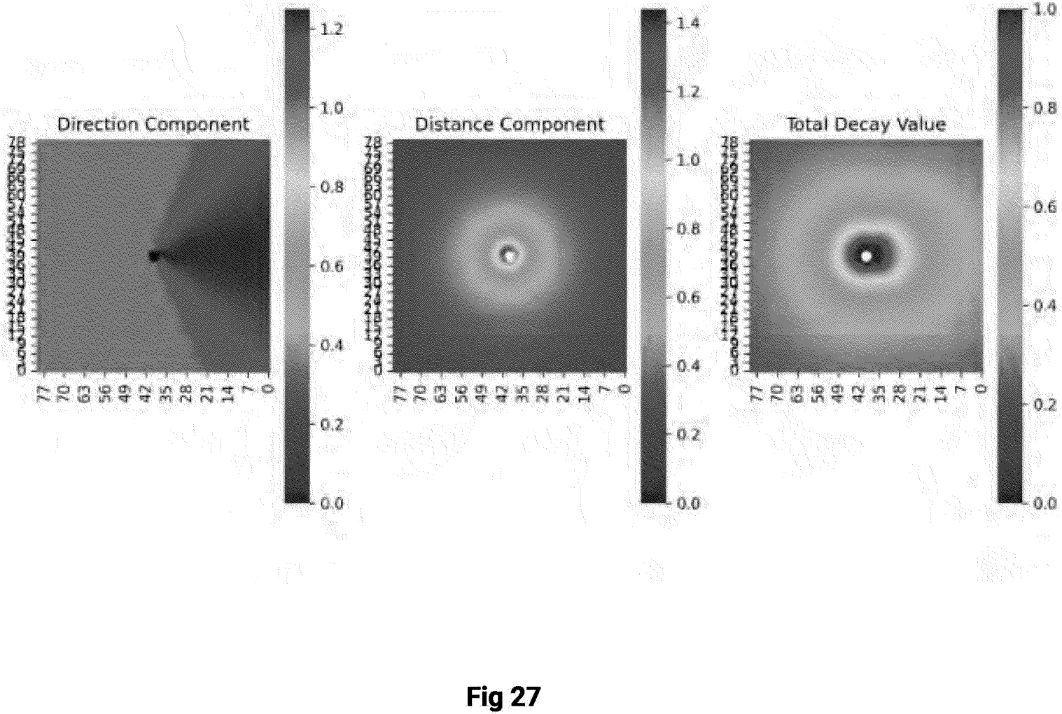

Using numerical optimization and the values from several studies of radiative heat dissipation in the context of wildland fires (FIG. 27), coefficient values (red curve) are set to a=3.8, b=3, and k=0.7.

Because convective heat preheats fuels upslope and down wind of the flame, fuels along the wind-slope axis contain less moisture and ignite at lower temperatures than fuels counter to the wind-slope axis that experience convective cooling and slower fire growth (Andrews 2018). Structural elements located along the wind-slope axis can also trap hot vapors rising from the fire plume under eaves, decks, and other attachments, causing higher likelihood of ignition (Quarles et al. 2010; Slack 1999). FIG. 27 illustrates the direction component (left), distance component (middle) and total decay value for a hypothetical location marked as the center circle. In this example, the wind-slope axis aligns from left to right. As shown in FIG. 27 (left), this convective heating effect is modeled with a separate decay function that modulates the intensity scores according to the wind-slope axis specific to the topographic and environmental settings of the particular discovery. Given the azimuthal direction of fire spread α and the bearing between the discovery and a given building (θᵢ), the relative bearing between the two vectors is δᵢ = θᵢ - α. A heuristic decay function is then applied on δ to capture the effect of convective heating along the wind slope axis for the ith structureγ_{cᵢ} = max(-0.00005δ₁ + 1, 1).

The EFI for a particular building is calculated as the product of the initial fireline intensity, the fraction of heat dissipation due to distance between the discovery and the building, and the role of convective heating along the axis between the discovery and structure:

$$E F {I}_{i} = {I}_{b} {γ}_{{H}_{i}} {γ}_{{C}_{i}}$$

### Score Calculation

EFI values for all structures within 40 m are normalized and added together to produce a final intensity score for each discovery. Because experimental studies of structure ignition show that it is unlikely for structures more than 40 m away from a flame to receive radiation greater than the critical 7 kW/m2 required for piloted ignition of wood - even when exposed to very large crown fires (Cohen and Butler 1998; Cohen 2000) - only structures within 40 m of the discovery are considered when computing the intensity component score. Structure-specific EFI values are normalized onto a scale of 0-25, such that discoveries with a sum of EFIs greater than 100 BTU/ft/s are assigned the maximum value of 25; lower EFIs are linearly mapped onto the 25-point scale. The 100 BTU/ft/s maximum was chosen to reflect an intensity threshold where fires begin to exceed the capacity of firefighters with hand crews and start to pose control problems (Andrews 1982). While chosen arbitrarily, normalizing by this critical value aids in communicating the effects of a high intensity component score and facilitates combination with other component scores.

Mathematically, given the critical value fireline intensity (I_{b} ★), set a priori to 100 BTU/ft/min, the structure-specific intensity component index for structure i is calculated as:

$${S}_{{i}_{i}} = \frac{{I}_{b} {γ}_{{C}_{i}} {γ}_{{H}_{i}}}{{I}_{b} ⋆}$$

A discovery’s total intensity index is the sum over all buildings within a 40 m radius search. If the total score exceeds the maximum possible score of 25, the values are capped at 25.

$${S}_{i} = m a x \left({\sum }_{i = 0}^{n} \frac{{I}_{b} {γ}_{i} {α}_{i}}{{I}_{b} ⋆} , 25\right)$$

### Ember Component Module

Wind-driven embers are a primary mechanism of structure ignition during a wildfire (Ager et al. 2019). Depending on the wind speed and direction, local topography, and receiving location, embers (smoldering or flaming pieces of wood or other debris) can ignite structures and vegetation far ahead of the main front of the fire (Caton et al. 2017; Zhou, Quarles, and Weise 2015). Numerous post-fire surveys have indicated that embers landing on or near combustible materials on and around a structure are responsible for structure loss, even when the surrounding vegetation is unburned (Murphy, Rich, and Sexton 2007; A. Maranghides, McNamara, and Mell 2013; Stratton 2012; Caton et al. 2017). While many embers in WUI fires will be supplied by wildland (off-parcel) fuels, embers from on-parcel discoveries can increase the risk to downwind structures by exposing them to elevated ember fluxes. The ember component index characterizes a discovery’s ability to distribute burning embers through the air and deposit them adjacent to downwind structures. Weighted towards long-distance ember dispersal, this score captures the potential for discoveries to produce embers that travel significant distances and land within the ember-resistant zone of downwind structures.

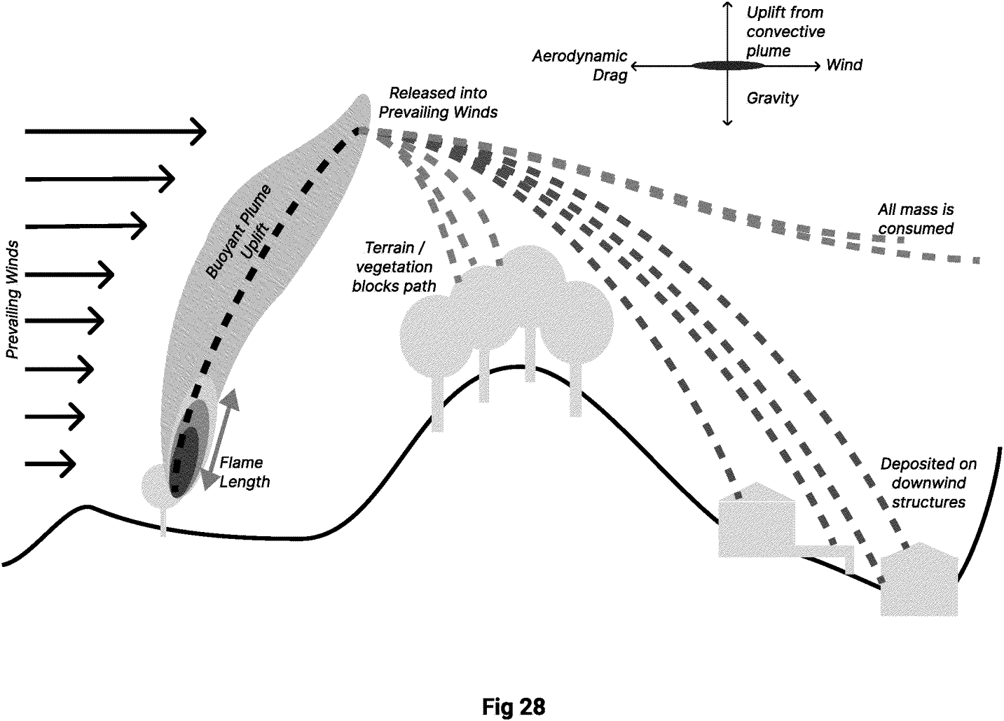

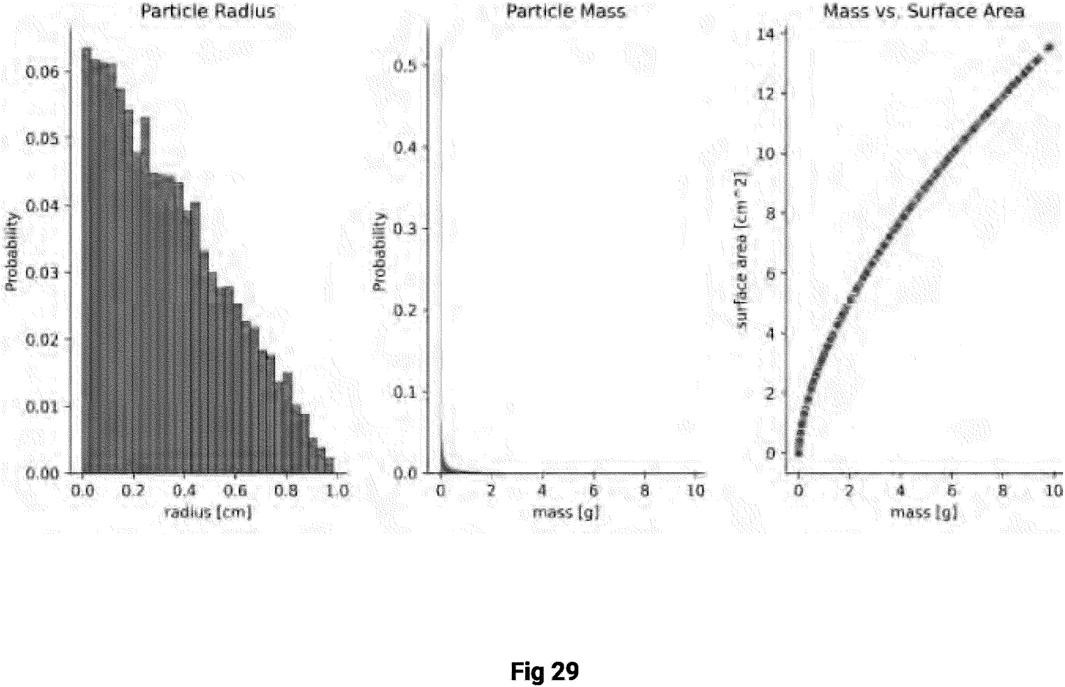

Ember generation, transport, and deposition is highly stochastic, and flight trajectory is dependent on the specific physical, chemical, and thermal characteristics of the wind, fire plume, and individual burning pieces (Tohidi, Kaye, and Bridges 2015). In this work, a physics-based model of ember dispersal is used to simulate particle trajectories with different physical and geometric characteristics to develop Monte Carlo probability distributions of ember travel, allowing probabilistic insight into ember sources and sinks (Gannon, Thompson, and Wei 2020) and identification of discoveries with significant ember hazard. FIG. 28 illustrates a schematic of the ember lofting, transport, and deposition. Embers are lofted through a convective plume whose height and uplift velocity depend on the flame length of the fire below. Burning cylindrical embers are released into the prevailing winds where they are subjected to the forces of gravity, wind, aerodynamic drag, and convective uplift, until they are deposited on the surface or are completely consumed. Embers that are deposited near structures count towards the ember transport component score. As illustrated in FIG. 28, simulated embers are launched from each discovery’s location at a height dependent on the discovery’s combustion intensity and tracked as they are carried upwards through the fire plume’s convective column and horizontally through the prevailing winds until they are (a) completely consumed (no mass remaining) or (b) land with sufficient mass to start a new fire. Forces operating on the parcel, including gravity, wind drag, and the buoyancy of the fire plume, cause the particle’s velocity to change as it progresses through its simulated flight. A high resolution lidar-derived digital surface model (DSM) is used to evaluate particle height and surface intersections. The simulated trajectory accounts for the presence of varying amounts of surface friction, the changing mass of the particle, and the assumed vertical profile of the prevailing winds. Because long-distance spot fires pose difficulty to control (National Wildfire Coordinating Group 2021a; Fernandez-Pello 2017) (Sullivan 2009), discoveries where embers are likely to both travel long distances and be deposited close to structures receive the highest ember scores. FIG. 29 shows the ember characteristics used in an example embodiment.

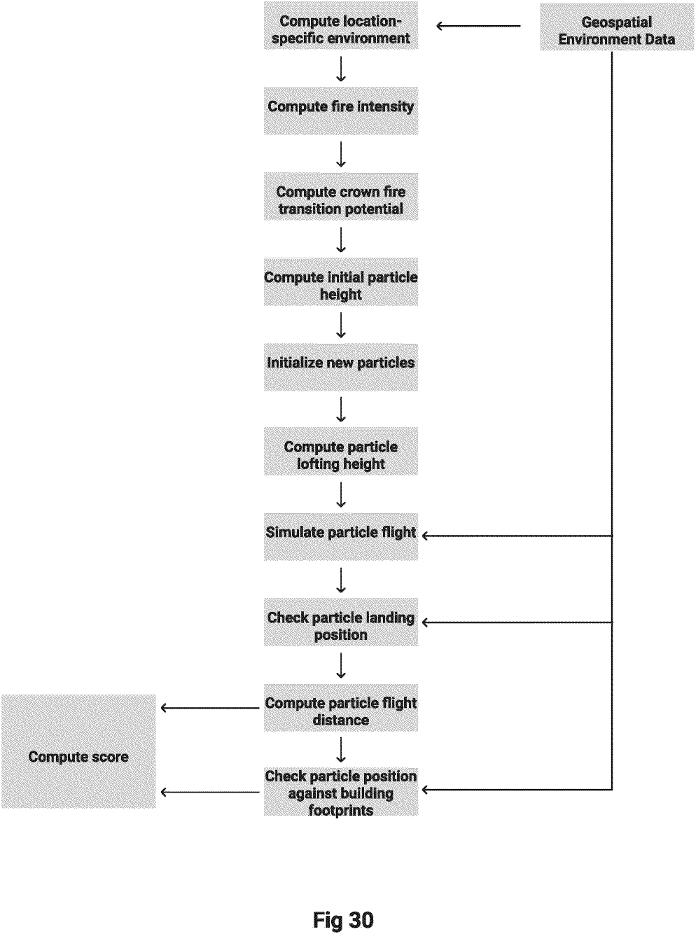

FIG. 30 illustrates an overview of the ember component module in the example embodiment. This module computes an ember hazard score for a as follows:
1. Location-specific environment data is fetched for using geospatial environment databases;
2. Fire intensity is computed for the specific type in its particular location;
3. Crown fire transition probability is calculated by comparing fire intensity to the transition intensity;
4. Initial launch height is calculated based on a surface-level launch or a crown launch;
5. A set of simulated particles are initialized;
6. Particle lofting height is calculated as a function of the risk’s combustion intensity;
7. Particle flight is simulated until a termination condition has been met;
8. The landing location is compared against the location of buildings in a buildings’ footprint dataset;
9. The particle flight distance between source and landing location is computed;
10. The fraction of particles intersecting with a geographic buffer around buildings is calculated; and
11. The final ember component score for that is calculated.

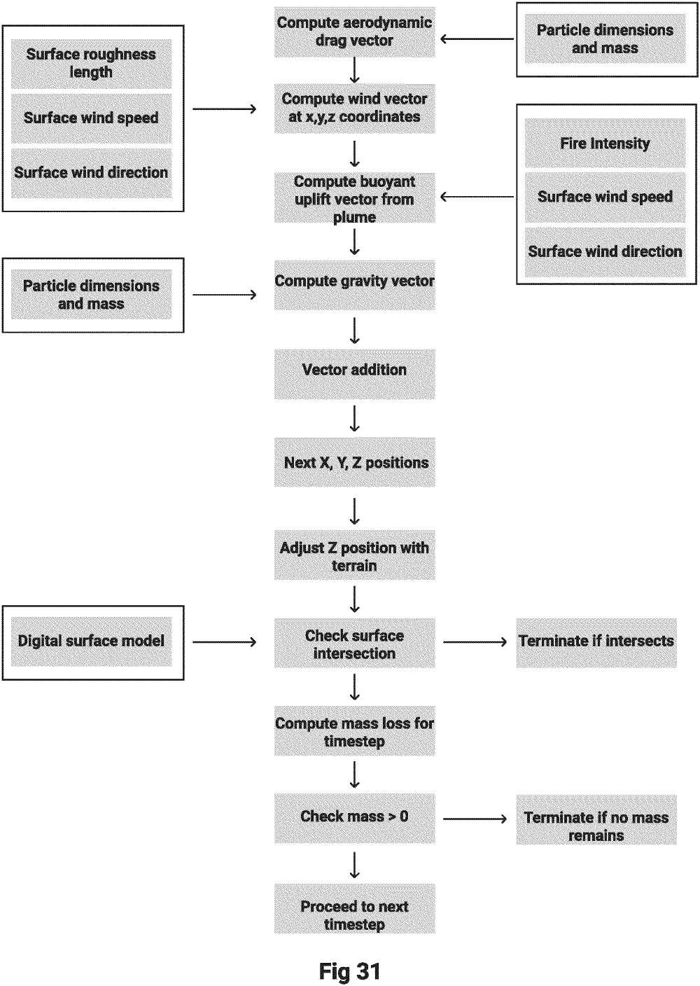

FIG. 31 illustrates an overview of the ember flight simulation process in the example embodiment. For each simulated timestep, a simulated particle’s position is updated as follows:
1. The particle’s aerodynamic drag is computed using its mass, surface area and surface area;
2. The aerodynamic roughness length is determined from remotely sensed geospatial data indicating vegetation height, type, or fuel model;
3. The location-specific vertical wind speed profile is calculated using surface estimates of wind speed and direction and estimates of friction between wind, land surface, and vegetation;
4. The location-specific uplift vector is calculated as a function of the buoyant plume at that location. Fire intensity, wind speed, and wind direction are used to calculate plume dynamics at a given distance and direction from the ember and combustion source;
5. The gravity vector is calculated using particle mass, surface area, and volume;
6. Buoyant uplift vector, gravity vector, aerodynamic drag vector, and wind vector are added together to produce travel distances in the x, y, and z directions;
7. The particle’s position is updated in the x, y, and z planes;
8. The particle’s z position is updated according to slope changes in the terrain beneath it;
9. The particle’s x, y, z position is used to check for intersections with the land surface or other obstacles, using a LIDAR derived digital surface model;
10. The simulation is terminated if an intersection occurs;
11. Assuming consistent combustion, the particle’s mass is reduced according to the rate of combustion;
12. The particle’s mass is checked to determine whether it is greater than zero;
13. The simulation is terminated if no mass remains; and
14. Continue to the next timestep.

These processes are described in more detail below.

### Simulated Ember Generation

Simulated embers are launched from vegetation and other combustible materials (e.g., shrubs, trees, fences, and play structures) that are capable of producing embers large enough to be carried in the prevailing winds. While grass, litter, and other small-diameter, near-surface combustibles may also produce embers, these discoveries are excluded from the ember component score because their embers are likely to be very small and unlikely to be carried more than a few meters. In general, taller vegetation produces larger embers (Manzello et al. 2009; Manzello, Maranghides, and Mell 2007; Tohidi, Kaye, and Bridges 2015) and exposes the embers to winds that are less restricted by vegetation friction (Massman, Forthofer, and Finney 2017).

The process in which pieces of burning materials (commonly twigs, leaves, and other vegetative debris) break off from their source is a highly complex process that depends on fire intensity, the speed and direction of the prevailing wind, and the size and geometry of the vegetation source from which the ember originates (Chakerian and Mandelbrot 1984; Barr and Ezekoye 2013; Tohidi, Kaye, and Bridges 2015) (Hudson et al. 2020; Hudson and Blunck 2019; Barr and Ezekoye 2013). Here, this process is parameterized: all eligible discoveries launch a constant number of simulated embers with physical properties drawn from a global distribution describing their size and shape. While ember shape can vary based on source material and the conditions responsible for ember production, all embers in this study are modeled as idealized cylinders. To simulate the effect of variations in ember size, aerodynamics, and weight, the key geometrical properties for each simulated ember are drawn from a distribution centered on empirical distributions available in the literature (Manzello et al. 2009; Suzuki, Manzello, and Hayashi 2013; Manzello et al. 2008, 2007; Manzello, Maranghides, and Mell 2007).

This work assumes that the particle’s initial radius (in cm) at formation is drawn from a beta distribution parameterized by α = 1 and β = 2 (FIG. 29, left). Further, all embers are assumed to be composed of oak wood with a constant density of 0.545 g/cc (34 lb./ft³) (Anthenien, Tse, and Carlos Fernandez-Pello 2006). FIG. 29 illustrates a particle radius (left), mass (middle), and surface-area-to-volume (center) distributions of the simulated embers used in an example embodiment. Given the initial radius r, dimensional relationships can be used to compute the particle’s surface area and mass (FIG. 29, center and right). In this work, the aspect ratio (K) of each simulated particle is held constant at 4 (length is four times the width). Given that D = r² and L = Kr, the volume V of the particle is found by V = πD²L. The surface area, S, is similarly found to be

$$S = π D L + \frac{π {D}^{2}}{2} .$$

As shown in FIG. 29, these assumptions produce a set of simulated embers biased towards small, light particles. This aligns with empirical studies of ember characteristics that show distributions heavily skewed towards low-mass firebrands (Tohidi, Kaye, and Bridges 2015; Manzello et al. 2009). In this work, the median ember mass is 0.02 g, the average mass is 0.49 g, and the median radius 0.29 cm.

The drag coefficient is a dimensionless value that describes the ember’s resistance as it travels through the air. Particles with higher levels of resistance experience higher friction and thus lose velocity more quickly. In this work, we capture the influence of slight variations in particle geometry, and thus, drag coefficient, by parameterizing this value by drawing from a normal distribution with a mean of 0.7 and a standard deviation of 0.2. Physically, this approximates the differences in drag encountered among cylinders of slightly different length-to-width relationships.

### Launch Height

The vertical height from which the simulated ember is released from the source fuel is a function of the source fuel height and the ignition status of the tree canopy. Some discoveries (e.g., trees and certain shrubs) are assigned explicit canopy height and base height values to reflect conditions common to that discovery type; if the discovery has canopy characteristics associated, the specified canopy base height and canopy height values are used to determine the likelihood of canopy ignition (i.e., torching). Otherwise, the GIS layers for base height and canopy height are used to determine values corresponding to the discovery’s location. In both cases, if a canopy is present, the fireline intensity needed to achieve crown fire transition is calculated and compared to the surface fire intensity at that location (see Intensity Component) to determine if a canopy fire is possible. The minimum intensity needed to ignite canopy fuels is a function of canopy base height (B) and foliar moisture content (M, held at 80% in this analysis) (Scott 1998; Alexander 1988; Van Wagner 1977):

$${I}^{′} = {\left[\frac{C \left(460 + 25.9 M\right)}{100}\right]}^{\frac{3}{2}}$$

If the discovery’s surface fireline intensity exceeds I′ simulated embers from that discovery are launched from a height randomly chosen to be between the canopy’s base height and the canopy height. If no canopy is present or the fire’s intensity is insufficient to ignite the canopy vegetation, simulated embers are initially positioned at the top of the surface fuel bed. Embers that are launched from the canopy are more likely to travel long distances because winds above the vegetation are subject to less friction with the surface and thus move faster. Further, additional obstacles, including vegetation, structures, and topography, frequently block the trajectory of low-launch-height particles. Some discovery types, such as ladder fuels, are always launched from the canopy, since their primary hazard is to transition fire into the canopy, even if surface fire intensity is low.

### Fire Plume

Embers are lifted above their initial vertical position by the buoyant fire plume. After they are broken off from their source, embers are entrained in the convective column of hot gasses rising from the burning material. The height that they are lifted to depends on the size and intensity of the fire (Anthenien, Tse, and Carlos Fernandez-Pello 2006) and the mass and aerodynamic properties of the ember. With some assumptions, physical relationships are available to relate fire behavior characteristics to heat release rate and velocity of the updraft within the plume (Anthenien, Tse, and Carlos Fernandez-Pello 2006; Baum and Mccaffrey 1989). In the absence of wind, the convective column rises straight up; however, in the presence of cross winds, which are typical during large wildfires, the plume bends over as the winds interfere with the upward convection (Liu et al. 2022). Assuming that the plume is buoyancy dominated and that the horizontal velocity of the plume is equal to the crosswind velocity, the buoyant force of the plume operating on a particle as it is entrained can be calculated at a given distance away from the source fire.

The vertical velocity of the simulated ember is the net force of the upwards convective velocity of the plume minus the downward force of gravity acting on the ember. Following (Anthenien, Tse, and Carlos Fernandez-Pello 2006), the upward plume velocity at a given horizontal distance (d) from the source location is calculated following the “two-thirds rule”:

$${{z}^{′}}_{p l u m e} = {\left(\frac{2}{3}\right)}^{2 / 3} {\left(\frac{{I}_{b}}{{χ}^{2} d}\right)}^{2 / 3}$$

Using assumptions about the force of gravity (g, 9.8 m/s2), the specific heat of the air surrounding the plume (Cpa, 1.0), and the ambient temperature (Ta, 300 K) and a fitted entrainment parameter (χ, 0.6, (Anthenien, Tse, and Carlos Fernandez-Pello 2006)), the heat release rate (H, in MW) and diameter of the fire driving the plume (Df) can be used to calculate the buoyancy length scale, Ib, of the plume. The fire intensity is again calculated, as in the Intensity Component section, as a function of the surface fuel properties, wind, slope, and moisture content. Assuming a constant fire diameter of 5 m, fireline intensity is converted to its equivalent heat release rate (MW).

The convective heat release rate is proportional to the total heat release rate of the fire such that Q_{c}′ ≈ 0.6H (Baum and Mccaffrey 1989). The flame velocity at the vertical height z can be then calculated as

$${w}_{f} = 3.4 {\left(\frac{g}{{C}_{p a} {T}_{a}}\right)}^{1 / 3} {Q}_{c} {}^{′} {}^{1 / 3} {\left(z - {Z}_{0}\right)}^{- 1 / 3} ,$$

where z is the flame height and Z0 is the assumed height of the source of the plume and is assumed to be 2 m below the flame tip.

Subsequently, the buoyancy flux Fb is calculated from fire diameter and flame velocity:

$${F}_{b} = {w}_{f} ∗ g ∗ \frac{{D}_{f} {}^{2}}{4}$$

Finally, given the horizontal wind speed, w, the buoyancy length scale I_{b} is calculated as:

$${I}_{b} = \frac{{F}_{b}}{{w}^{3}}$$

This formulation accounts for the fact that high winds reduce the amount of upward convection in the plume as the plume is blown over and the hot gasses are blown in the direction of the prevailing winds. Once the ember travels more than 25 m from the fire that launched it, it is assumed that the plume has no more vertical influence on the particle’s velocity and force of gravity alone is acting on the particle in the vertical direction. For very large fires (e.g., with heat release rates >= 40 MW), this may underestimate the influence of the plume in launching long-distance embers (Anthenien, Tse, and Carlos Fernandez-Pello 2006); however, this is a useful simplifying assumption for computing the behavior of on-parcel ember sources. The lofting height calculation also assumes that the discovery is the only material combusting and thus is the only source of buoyant uplift. This assumption is unlikely to hold true in large WUI fires, in which there is likely to be a large plume generated by a fire with a footprint hundreds or thousands of meters in diameter. However, attributing the uplift to the discovery enables differences in surface fire intensity to translate into increased ember transport distances.

### Flight Trajectory

Throughout the flight, the position and velocity of the particle in three dimensions is evaluated every 0.25 seconds. At each timestep, the position of the particle is updated based on its velocity at the last timestep. Assuming a timestep duration of t=0.25 s,

$${x}_{t} = {x}_{t - 1} + {{x}^{′}}_{t} t$$

$${y}_{t} = {y}_{t - 1} + {{y}^{′}}_{t} t$$

$${z}_{t} = {z}_{t - 1} + {{z}^{′}}_{t} t$$

Initial x and y (east-west) and (north-south) coordinates are set to the UTM Zone 10N coordinates of the discovery. The z (up-down) coordinate is initialized based on surface fire and fuel properties as discussed in Simulated Ember Generation. These coordinates are adjusted (in meters) in each timestep according to the simulated movement.

As illustrated in FIG. 28, the primary forces operating on the particles over the course of their flights are the buoyant force of the fire plume, the downward force of gravity, and the force of the prevailing wind and associated aerodynamic drag. As embers continue to burn during flight, they lose mass, which in turn reduces their terminal velocity. In this study, we assume that continued combustion does not produce a buoyancy effect that would alter the aerodynamic properties of the particle during its trajectory (Koo et al. 2010; Thomas, Sharples, and Evans 2020) but do account for the fact that mass reduction changes the aerodynamic profile of the ember through its flight.

Wind speed increases logarithmically with height above the surface (Ro K. S. and Hunt P. G. 2007). Using the location-specific wind velocity (w), derived from the spatial wind field computed as in the Wind, Weather, and Moisture section, the altitude-specific wind speed for that location is calculated using the standard equation for boundary-layer flow velocity w′ =

$$\frac{w}{k} ∗ l o g \left(\frac{z}{{z}_{l}}\right) ,$$

where k is the Von Kármán constant (0.4), z₁ is the roughness length at that location, and z is the altitude of the particle relative to the reference velocity (10 m, the height of the surface wind observations). The roughness length is a parameter that specifies the friction encountered by the wind flow along the surface. Large obstacles, such as trees and buildings, have longer roughness lengths than grasses and bare earth (Stull and Ahrens 2000).

TABLE C1

Roughness lengths corresponding to each fuel model group.

| Fuel Model | Roughness Length |
|---|---|
| Urban/Suburban (NB1) | 1.25 |
| Grass Group | 0.1 |
| Shrub Group and Grass/Shrub Group | 0.75 |
| Timber Group and Timber/Understory Group | 1 |
| All Others | 1 |

The altitude of the particle is re-evaluated at each timestep. At each timestep, the particle may gain altitude (due to plume uplift) or lose altitude (due to gravity). Further, because the particle is traveling over heterogeneous terrain, it may gain or lose additional altitude as it moves horizontally in the direction of the prevailing wind due to changes in the terrain below it. These topography-induced altitude changes are important in the overall flight trajectory, because terrain features can cause increases in altitude that correspond with rapid increases in wind speed. These sorts of terrain features are important in estimating the spotting hazard and are often responsible for very long distance ember travel (Albini 1979). Therefore, at each time step in the simulation, the particle’s altitude is adjusted according to the slope of the land beneath it. Because a digital surface model is used to represent the terrain, changes in vegetation height, land surface topography, or building height are all counted when adjusting particle height. Concretely, the topography-driven change in the particle is modeled as z′ₜₒₚₒ = Sₜ(wₜ′t), where St is the slope of the land in vertical change over horizontal change evaluated in the direction of the prevailing wind evaluated at the location of the particle at time t.

Without upward velocity from the buoyant plume, the ember is acted upon by gravity alone in the vertical direction and is assumed to travel at its terminal velocity towards the ground (Koo et al. 2010). The instantaneous force of gravity on the ember, and thus its instantaneous velocity, is recomputed at each timestamp to reflect changes in ember mass. Assuming a constant air density, the particle’s downward velocity is calculated as:

$${{z}^{′}}_{g r a v i t y} = \sqrt{\frac{2 m g}{ρ A {C}_{d}}}$$

where m is the particle mass at time t, g is the force of gravity, ρ = 1.225 is the density of air, A is the particle area at time t, and C_{d} is the particle drag coefficient at time t (Albini 1979). Through its flight, the burning particle loses mass as it continues to combust, which alters its terminal velocity. Following (Anthenien, Tse, and Carlos Fernandez-Pello 2006), the mass loss rate (kg/s) is a function of the altitude-specific effective wind speed encountered by the particle, such that

$${{m}^{′}}_{t} = - \left(1.3 \sqrt{{{w}^{′}}_{t}} + 0.4\right) ∗ {10}^{- 7} .$$

The particle mass is then updated at each timestep, mₜ = mₜ₋₁ + m′ₜt.

The location-specific wind direction (θ) is derived from the high-resolution spatial wind field (described in the Wind, Weather, and Moisture section). Wind direction is assumed to be constant in the vertical profile. Observational and wind-tunnel studies, however, suggest that initial particle orientation, surface friction, and turbulence can create a “V″-shaped pattern in downwind deposition (Martin and Hillen 2016) (Wadhwani, Sutherland, and Moinuddin 2019). To parameterize this observed off-centerline effect, a small amount (2.5 degrees) of random noise is added to the location-specific prevailing wind direction at each timestep.

Using vector addition, particle heading (azimuthal direction) and velocity are transformed into vector components representing velocities in all three directions:

$${x}^{′} = {{w}^{′}}_{t} ∗ s i n \left({θ}_{t}\right)$$

$${{y}^{′}}_{t} = {{w}^{′}}_{t} ∗ c o s \left({θ}_{t}\right)$$

$${{z}^{′}}_{t} = {{z}^{′}}_{p l u m e} - {{z}^{′}}_{g r a v i t y} + {{z}^{′}}_{t o p o}$$

### Termination Conditions

Ember flights are terminated in one of two ways. First, simulated embers may consume all their initial mass through continued combustion. Second, embers with a nonzero mass may intersect the ground surface or other obstacles. Because a LIDAR-based digital surface module is used to check surface intersections, obstacles such as buildings, vegetation, or the earth’s surface are accounted for and can be used to determine ember accumulation zones. In both termination cases, once a condition is met, the simulation is over and the result is used in the calculation of the ember score.

### Ember Component Scoring

For each discovery, 20 simulated ember flights are run for each weather scenario. The ember component index is calculated by multiplying the fraction of simulated embers landing with the ember-resistant zone of a building footprint (here, within a 10 ft buffer) and by a factor proportional to the distance traveled by the set of simulated embers.

Specifically, if an ember lands with a non-zero mass, it is checked against the building footprint dataset to evaluate if it falls within 10 ft of a structure. The proportion of embers falling within this zone (Fe) is then multiplied by the square root of the average Euclidean distance between source and landing location (dₑ). A minimum intersection fraction of 0.15 is enforced to reflect the importance of long distance ember transport, even if it falls outside of a downwind home ignition zone. In total, the final weighted index is computed as:

$${S}_{e} = 2 {F}_{e} \sqrt{{\overline{d}}_{e}}$$

### Vulnerability Component

Structure vulnerability, here defined as the likelihood that the structure will resist ignition given a wildfire exposure, is dependent on its specific design elements and materials of construction (Hakes et al. 2017). Numerous studies have shown that architectural elements, such as the presence of a Class A fire-resistant roof, ignition resistant siding, and double-pane or tempered windows, can greatly improve the chance of a structure surviving a wildfire exposure (Troy et al. 2022; Syphard, Brennan, and Keeley 2017, 2014; Caton et al. 2017; Hakes et al. 2017). Conversely, post-fire damage surveys indicate that combustible roofs, wooden decks, and unscreened vents can adversely affect the structure’s chance of survival by facilitating ember intrusion into vulnerable areas of the building and enabling ignition upon exposure to radiant heat (Murphy, Rich, and Sexton 2007; A. Maranghides, McNamara, and Mell 2013; Stratton 2012). The likelihood of a structure’s survival is a function of all of its attributes. When encountered together, some risk factors, such as the presence of both combustible siding and combustible roofing) can magnify each other’s influence and non-additively affect the structure’s chance of survival. The vulnerability component model captures these dynamics by using a statistical model that evaluates a structure’s probability of ignition by comparing it to similar structures involved in recent California wildfires. This model produces a contribution index that indicates the marginal increase in probability of ignition derived from the presence of a particular structural element, given other structural elements present on the structure.

Post-fire inspection reports made available through the CalFIRE Damage Inspection (DINS) program are used to fit a non-linear regression model to estimate the probability of ignition as a function of the presence or absence of a suite of ten structure-related attributes. The contribution index of a particular element is computed by comparing the structure’s probability of ignition in the presence of that element with the probability of ignition without that element. The difference between these two probabilities is taken to be the influence that variable has on the structure’s loss probability.

This data-driven approach allows the scoring to take advantage of vast amounts of post-fire observational data that is challenging to integrate into pre-fire predictive models. Note, however, that due to the adverse circumstances under which it is collected, the resolution of the post-fire survey data is coarse and can be inconsistent. To account for this, specific elements are grouped into broad categories (e.g., “non-combustible roof”) prior to integration into the component scoring model, which limits this component’s ability to make inferences about specific material properties (e.g., tile roof vs. metal roof). Further, the DINS dataset contains only a subset of the 63 structural discoveries available in the parcel inspection dataset, limiting its power to assess vulnerability risks of many structural attributes. Despite these limitations, this component makes a valuable contribution to the overall discovery risk analysis by providing a direct indication of structure ignition potential.

### DINS Data Processing

The CalFIRE DINS dataset is collected by trained specialists in the immediate aftermath of a fire. The dataset includes a set of approximately 2 dozen attributes about each structure and its immediate surroundings. In total, the DINS data includes over 70,000 inspection records in the period 2013 to 2020. Because these records are collected quickly in the aftermath of a fire, many records are missing attributes or contained attributes that were not determinable by the inspector. Accordingly, there are variations and inconsistencies across the dataset and within particular attribute classifications (for example, Wood Siding vs. Combustible Siding).

To use the DINS data, the dataset was first cleaned by removing records with clerical errors and records with exclusively “Unknown” values. In total, 29,382 records were retained from 145 different fire incidents in California. Attributes were simplified into categories with higher statistical power (e.g., “combustible” instead of “wood” roof).

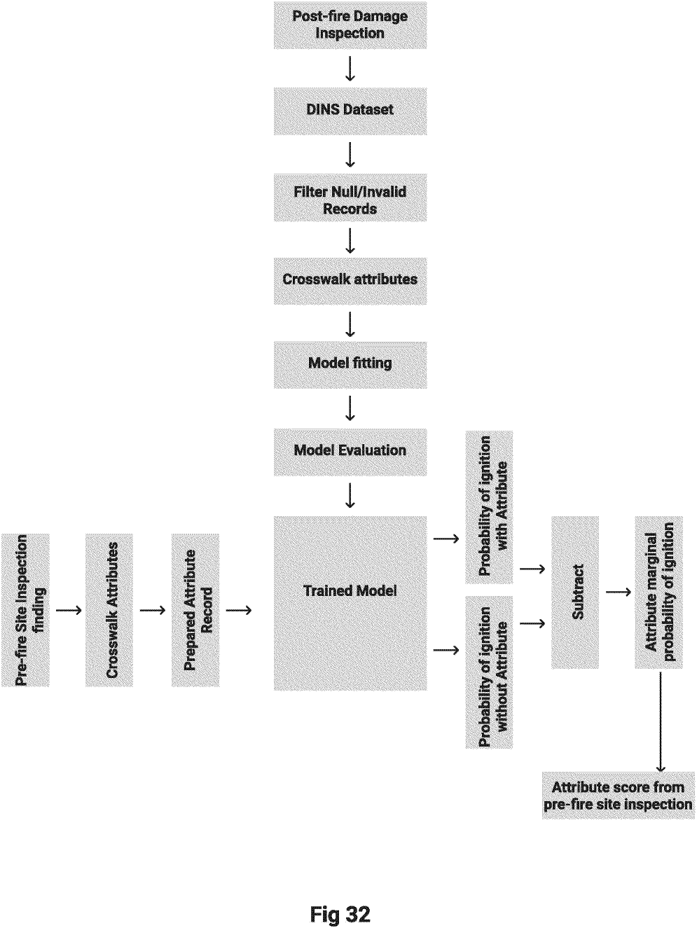

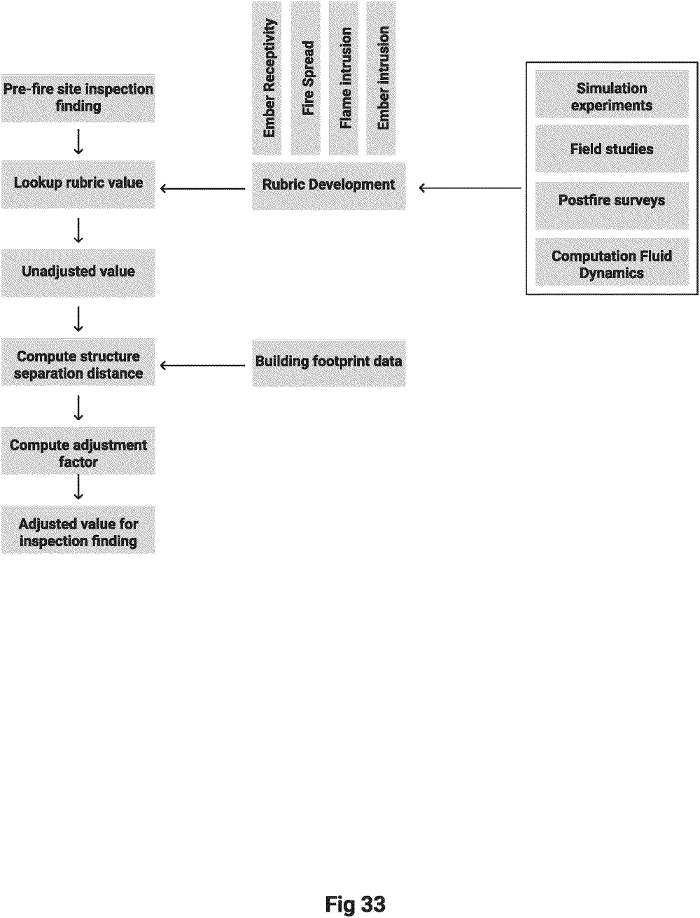

FIG. 32 shows an overview of the process in the example embodiment where a statistical model is trained on post-fire damage inspection data and used to describe the relative hazard of pre-fire inspection s. In the top portion of FIG. 33, post-fire attribute data for burned structures is collected by trained investigators after a wildfire exposure and assembled into a cohesive dataset. Records are cleaned according to filtering rules and attributes are generalized using a crosswalk. A statistical model is fit to the data to predict structure ignition given the surveyed attributes. The model is evaluated using a holdout set. On the left portion of FIG. 32, pre-fire data is generalized using an attribute crosswalk and prepared for input into the trained model. On the right portion of FIG. 32, the trained model makes two predictions for the structure ignition probability of the given pre-fire site inspection : one where the attribute is present, the other where it is absent. The difference between the two outputs is interpreted as the marginal contribution to structure ignition derived from the . On the bottom left of FIG. 32, the marginal contribution is scaled according to heuristic scaling rules to serve as a component in the risk assessment process.

### Model Specification

The vulnerability component model estimates the difference in conditional probability of ignition with and without a given structural attribute. Partial or minor damage is not included in the model; however, partial damage is relatively infrequent, most structures in the DINS dataset are either destroyed or sustained no damage.

The regression model produces a probability between 0 and 1 indicating the likelihood of ignition given the set of all structural factors, including roof type, siding type, vent screens, and windowpanes.

$$\begin{matrix}{P}_{i g n i t i o n} = f \left(r o o f , d e c {k}_{e l e v a t e d} , d e c {k}_{s u r f a c e} , v e n t s ,\right) \\ \left(s i d i n g , w i n d o w s , p r o p a n e , f e n c e , s l o p e , e a v e s , c a r p o r t\right)\end{matrix}$$

This modeling approach assumes that (a) a structure’s ignition probability is a function of all of its attributes when evaluated together and (b) the relationship between attribute presence/absence and structure loss probability may be nonlinear. In practice, this means that the risk of an attribute varies from structure to structure and parcel to parcel, given the presence of different structural attributes. For example, the relative importance of combustible siding may be greater on a structure with a non-combustible roof than on a structure with combustible roofing.

The probabilistic model is fit using gradient boosted decision trees (BDT) (Hastie, Tibshirani, and Friedman 2009). A decision tree is a predictive model that recursively partitions an underlying dataset into groups based on an outcome (i.e., ignition vs. no ignition) to estimate the probability of occurrence of each outcome, given a set of covariate attributes. Decision trees can be of arbitrary depth and can provide an explainable structure that can be easily interpreted to understand the model’s internal logic. BDT is a class of flexible statistical classifiers that combine many small decision trees into a highly predictive ensemble classification model. Using the gradient boosting algorithm, many shallow decision trees are assembled stage-wise to minimize an overall objective function by iteratively reducing residual error (i.e., it is trained iteratively to reduce classification error).

Uniquely among machine learning models, decision trees can accept domain knowledge in the form of monotonic constraints between the covariate attributes and the outcome. These constraints force the model to match a priori specifications of the relationship between an attribute and the outcome. There is abundant observational evidence regarding the causal relationship between certain structural risk factors and probability of ignition (e.g., combustible roofing can cause structure ignition). Empirical relationships are imposed on the BDT estimator to ensure that the final model outputs incorporate this prior knowledge. For example, a positive constraint is imposed on the coefficient for the presence of a combustible roof, ensuring that the model’s prediction of loss probability always increases with the presence of a combustible roof, even when coarse data, small sample sizes, or other inconsistencies would cause statistical estimation to the contrary. The monotonic constraints only enforce the direction of the relationship (positive or negative); the magnitude of the relationship is learned by the estimator.

A discovery’s vulnerability component index is calculated as the difference in structure ignition probability computed with and without the attribute. First, all structural discoveries on a parcel are grouped together to describe the structure’s context: the set of structural attributes noted to be present by the DSI inspectors. If an attribute was not recorded, the context assumes that the attribute is the more risky of present or absent. For example, if no roof discovery is available, it is assumed that the structure has a combustible roof. The parcel’s mean slope, computed from CWPP GIS layer, is used to provide slope attribute information to the model.

The model is provided with two sets of structure contexts. Holding all other surveyed variables constant, the first context set reflects a structure where the discovery variable is constant and the second indicates a structure where it is absent. The difference between the outcome probabilities for the two sets of inputs is the discovery’s vulnerability contribution. The discovery’s final vulnerability component index is derived by normalizing the contribution score onto the 25 point scale by multiplying the raw contribution values by 25.

Some structural discoveries are resilient: they indicate that the structure has design elements that lower the risk of ignition. For example, vents screened with < ⅛” mesh lower the risk of structure ignition (Hakes et al. 2017) and Class A roofs are designed and tested to resist ignition from flames and embers. The contribution score of resilient scores is calculated in the same way as for non-resilient discoveries; however, the outcome vulnerability contribution value is negative (the structure is less likely to ignite when the variable is present) . When aggregated to the parcel negative vulnerability component scores offset the other hazards found on a parcel.

### Continuity Component

The continuity component model captures factors that increase the potential for fire to spread towards or into vulnerable areas of the structure. These mechanisms may be absent from the DINS data or may reflect physical properties that are too small and/or insufficiently characterized in the literature to incorporate as a separate component model applicable to all discovery types. The continuity component index expresses the potential for the discovery to (a) spread fire across the parcel, (b) serve as a receptive fuelbed for wind-driven embers, and (c) permit entry of embers or flame into vulnerable areas of the house (such as the attic or crawl space).

FIG. 33 shows an overview of the architecture of the continuity component in the example embodiment. On the right portion of FIG. 33, various sources in the scientific literature are used to inform a rubric that describes a type’s contribution to ember intrusion, flame intrusion, forward fire spread, and ember receptivity. On the left side of FIG. 33, a pre-fire inspection is evaluated against the developed rubric and then adjusted according to the prevailing structure separation distance in the area surrounding the . This process is described in more detail below.

For each class of discovery, a heuristic continuity coefficient is set based on the rubric presented in Table C2. Using available literature and expert judgment, the rubric is used to develop a coefficient of between -25 and 25 that reflects the characteristics of the discovery type along each of the three axes. Each discovery is assigned a point value for each rubric category (high = 10, moderate = 5, low = 2, none = 0). If the sum of all point values exceeds 25, the total value is capped at 25 to match the maximum value of other components. As in the vulnerability component, resilient discoveries prevent fire spread and ember intrusion are assigned negative continuity coefficients.

TABLE C2

Rubric used to specify continuity coefficient values.

| | | |
|---|---|---|
| Contributes to Fire Spread | Constitutes a Receptive Fuelbed | Permits Ember or Flame Intrusion |
| High: Discovery creates a fuel hazard that is likely to connect the other combustible fuels with the structure itself or its attachments. Examples: Attached fences, vegetation in zone zero. | High: Embers are highly likely to accumulate and ignite the fuel surrounding a structure. Examples: grass clippings, combustible materials beneath a deck, litter in gutters. | High: Discovery creates the potential for embers to be exposed directly to the interior of the structure, such as in the crawl spaces, attic, or living area. Examples: unscreened vents, unenclosed eaves, wood roof. |
| Moderate: Discovery creates an uninterrupted fuel pathway that can carry fire around a parcel. Examples: Non-attached fences, mulch beds. | Moderate: Discovery is likely to accumulate embers but accumulated embers may not ignite into flaming combustion. Example: piles of firewood, attached decks, scattered debris. | Moderate: Embers or flame may enter the structure after a critical threshold is reached. Examples: single-pane windows, vinyl gutters. |
| Low: Discovery creates a non-contiguous fuelbed that may contribute to fire spread if barriers and separation are not present. Examples: Scattered debris, grass clippings | Low: High loads of ember accumulation may contribute to ember-drive ignition, but fuels are unlikely to be receptive except in rare cases. Examples: piles of building materials. | Low: Discovery contributes to the exposure of potentially weak elements of the structure, such as the siding, but does not directly allow penetration. Examples: decks, attached fences. |
| None: Discovery is unlikely to change how fire is carried across the parcel. | None: Discovery is unlikely to serve as a receptive fuel for wind-driven embers. | None: Discovery is unlikely to contribute to ember intrusion. |
| Resilient: The discovery interrupts fuel continuity and reduces the chance for fire to spread across the parcel. | Resilient: The discovery resists ember-driven ignition. Examples: ignition-resistant siding, non-combustible roof. | Resilient: The discovery actively prevents ember-intrusion. Examples: engineered vents, metal flashing against decks and gutters. |

### Role of Structure Separation Distance

Recent post-fire analyses have shown that the density of structures in an area reduces the importance of on-parcel fuels and home hardening measures in structure ignition, because structures in high-density areas are more likely to ignite through structure-to-structure heating (Alexander Maranghides et al. 2022). Correspondingly, the resiliency gained by removing on-parcel fuels or performing structural hardening is also reduced because these factors are less likely to prevent structure ignition when nearby structures are emitting heat loads capable of directly igniting the structure. To incorporate these dynamics, the continuity index is adjusted downwards in areas with low structure separation distance (SSD) as shown in Table C3.

Note that separation distance varies significantly even on small spatial scales. SSD is calculated by calculating the pairwise distance matrix between the centroids of all features in the building dataset using QGIS. Only buildings larger than 120 ft² were used in the calculation, to minimize the influence of sheds and utility structures in the adjustment. The distance matrix is an NxN dimension matrix with each row representing a building feature and each column representing the distance to another feature. The SSD is selected as the minimum distance between the structure’s centroid and another structure’s centroid. SSD can vary substantially even on the neighborhood scale. Each parcel is assigned the minimum SSD of all buildings found on that parcel. Finally, the continuity index for a particular discovery is adjusted according to the parcel on which the discovery was found. Note that this calculation is different from the distance calculations performed to calculate Effective Fireline Intensity values in the Intensity Component section, where the distance statistic reflects the distance between the discovery and the structure. Here the distance measure reflects the distance between structures and the relative location of the discovery is not considered.

TABLE C3

Continuity component adjustment to reflect the decreased influence of on-parcel fuels and structural hardening measures in high-density areas.

| SSD (ft) | Adjustment Fraction |
|---|---|
| <=10 | 0.30 |
| 15 | 0.48 |
| 20 | 0.65 |
| 25 | 0.81 |
| >=30 | 1.0 |

### Discovery Score Index

For each discovery, all component index scores are added together to produce the discovery’s overall hazard score. It is important to remember that this scoring framework produces a different score for each discovery instance, rather than a score for each class of discovery. In other words, some instances of the same discovery type can be more hazardous than others based on specific geographic and topographic positions, spatial relationships with neighboring structures, and on local wind and moisture conditions.

Theoretically, the discovery score index ranges between -50 (most resilient) to 100 (most hazardous). Defensible space discoveries (combustible materials and vegetation) are typically lower bounded by zero because they are not resilient findings and typically contribute to ember transport, intensity, and/or continuity. Structural discoveries (materials and design), which can be either hazardous (positive score) or resilient (negative score), are primarily modeled with the continuity and vulnerability components, causing scores to range from -50 to 50.

When computing the total score for each instance, the maximum value for each component under the two weather scenarios is used, ensuring that the discovery is representative of the worst-case conditions.

### Parcel-Level Normalization

The total hazard load on a parcel (or other higher-level administrative unit) is a function of the discoveries found on that parcel and is therefore theoretically unbounded because the number of discoveries on a parcel is unlimited. While it may be useful to have unbounded parcel risk scores under some circumstances, it is usually preferable to use a bounded score for spatial analysis and for combination with other parcel-level risk metrics.

In this example embodiment, a parcel-aggregator module is used to compute a parcel-level score index by dividing the sum of all discovery scores by four and then enforcing the maximum of 100:

$${S}_{p a r c e l} = m i n \left(\frac{{\sum }_{k = 0}^{n} {S}_{k}}{4} , 100\right)$$

This is purely a scaling step that allows the index values to range between 0 and 100. We find that only a very small percentage of parcels exceed the maximum of 100.

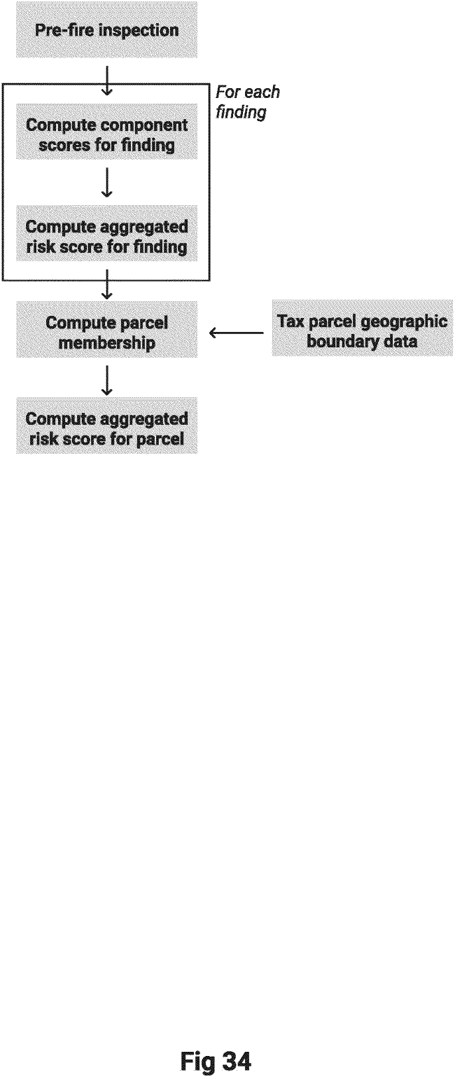

FIG. 34 shows an overview of the parcel aggregator module used in the example embodiment.

Note that resilient discoveries, having negative scores, can offset positive-scoring hazards on a parcel and can cause the aggregate score for a parcel to be below zero. This indicates that the resilient attributes discovered on that parcel effectively outweigh the hazards on that parcel. Allowing parcels to take negative scores to reflect their heightened levels of resilience is useful when performing spatial analysis of on-parcel hazards.

### Efficiency

Mitigation efficiency is defined as the amount of risk reduced per dollar of mitigation spending. This measure captures both the benefits achieved by moving, removing, replacing, or otherwise mitigating a discovery and the cost required to perform this work.

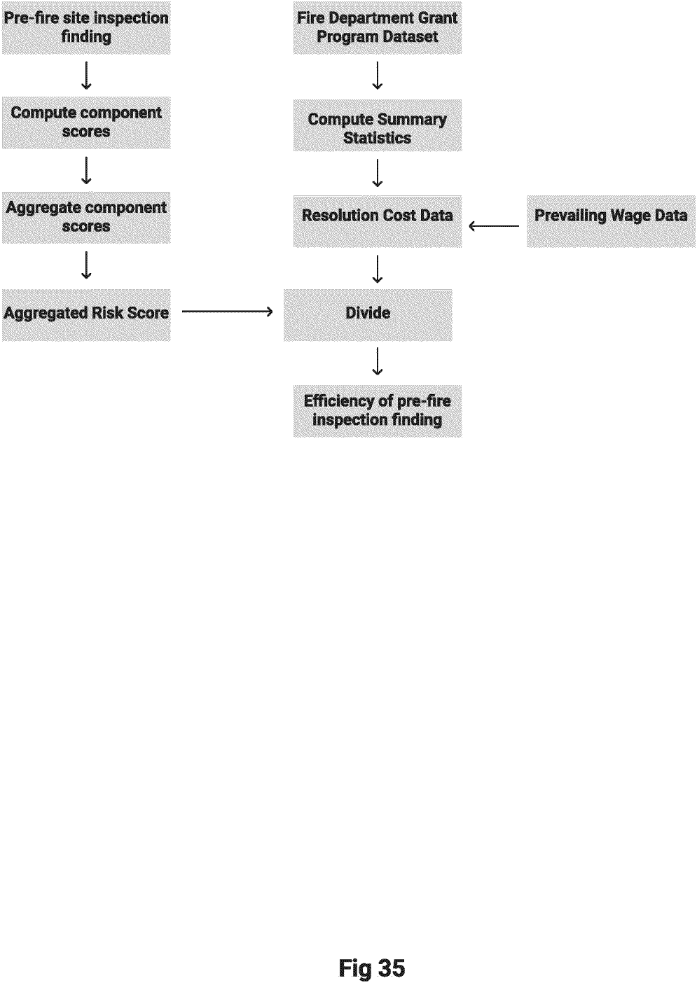

FIG. 35 shows an overview of the efficiency module used in the example embodiment. On the left side of FIG. 35 risk scores are calculated for a pre-fire site inspection . In the center and right of FIG. 35 data describing the cost for performing mitigation of that is derived from various sources. In the center of FIG. 35, the two measures are divided to produce an efficiency metric describing the resolution risk change per dollar.

For many discovery types, multiple forms of mitigation are possible and the way in which a discovery is mitigated influences residual hazard remaining after mitigation. For example, an attached combustible fence can be mitigated by (a) replacing the entire fence with a non-combustible alternative, (b) replacing only the attaching sections with a non-combustible material, or (c) removing the fence completely. The residual risk of replacing only the attachment points with a non-combustible material is higher than that of the other two choices, because the combustible fencing material that remains continues to pose a continuity risk to the surrounding parcels. For any given discovery type, the choice of mitigation method is largely dependent on parcel-specific conditions and the wants, needs, and financial state of the parcel resident.

In most cases, vegetation and combustible discoveries are assumed to be mitigated by removal, which results in zero residual risk. For some types, such as outdoor furniture cushions and firewood, moving combustible objects may be a low-cost method to reduce their risk. However, moving combustible objects to other locations on the parcel may cause an unintended increase in the risk they pose to structures on other parcels, so that form of mitigation is not considered here. For discoveries involving structural hardening, some actions may result in a negative residual risk if that mitigation involves the installation of an attribute that provides additional resiliency. For example, the replacement of a wood roof with a Class A asphalt roof will not only eliminate the hazard posed by the wood roof but also include some additional resiliency gained by the fire-and-ember resistant properties of the new roof. The additional resiliency is calculated by taking the average of the discovery scores for the post-mitigation discovery type.

With an assumed mitigation, efficiency for a type is calculated by dividing the post-mitigation residual risk by the average mitigation cost for a of that type.

$$ε = \frac{{S}_{k} + {S}_{R}}{\overline{C}}$$

In this formulation, Sₖ represents the discovery’s risk score, S_{R} represents the additional resilience gained during mitigation, and C⁻ represents the average cost of mitigation.

### Mitigation Cost Sources

In the example embodiment, the cost data is provided by a variety of sources. The Headwaters Economics / Institute for Business and Home Safety (IBHS) study Construction Costs for a Wildfire-Resistant Home: California Edition provides California-specific estimates of construction costs for some fire resistant structural hardening measures (Barrett, Quarles, and Gorham 2022). When possible, the construction cost of a corresponding wildfire-resilient attribute was used as an estimate of mitigation cost. This study includes Northern-California estimates for some construction types; preference towards these local estimates is given when available. An example embodiment focuses on the cost of home construction to wildfire resistant standards, and may not capture additional costs related to permitting, labor, and debris removal for replacement or other modifications from a previous state. Nonetheless, it provides a California-specific view on the costs of structural modifications.

Finally, in the absence of other sources, prevailing wage data is used to estimate the cost of mitigation from an estimated number of work hours. This heuristic is primarily used for defensible space and vegetation discoveries, where costs can range significantly based on issue size and severity. In these cases, the mitigation cost for each discovery type is estimated by estimating the number of hours required to mitigate the issue multiplied by the prevailing wage for a specified type of labor (e.g., laborer, landscaper, roofer, arborist). Prevailing wage information is obtained from the California State Department of Industrial Relations for different trades (California Employment Development Department Occupational Employment and Wage Statistics Program 2022). Online research was performed with various vendors to validate whether the estimated cost falls within typical ranges of similar projects; however, the exact cost of work can vary based on numerous factors, such as slope, parcel-specific conditions, materials used, experience, and quality of work.

### Hotspot Statistics

While maps and visual analysis can reveal locations with high or low risk score values, analysis of local spatial autocorrelation can reveal statistically significant clusters of contiguous groups of parcels with high (hotspots) or low (coldspots) values. This form of statistical analysis provides both an additional level of robustness in defining regions of similar hazard scores and enables the clear delineation of cluster boundaries. Intuitively, a hotspot is not just a single high-hazard parcel on its own but one that is also surrounded by other high-hazard parcels. Hotspot areas would be ideal targets for re-inspection, abatement, or other programming because the concentration of on-parcel risk is high, the potential for risk reduction is significant, and the residual benefits around community engagement could be multiplicative. Conversely, cold spots would be ideal for case studies and success stories highlighting effective mitigation strategies. Reinspection in these areas is less critical because parcels already tend to have lower overall parcel-level hazard indexes. Hot and cold spots can reflect neighborhood-scale dynamics and block-by-block differences in community engagement in mitigation activities.

Several tools provide statistical criteria for identifying these high-scoring clusters. In this analysis, Local Moran’s I is used to analyze spatial autocorrelation among the 100 m grid cells and statistically test whether they fall within a hotspot or coldspot. Each cell’s six neighboring cells are used to compute the average score of the neighboring cells. Moran’s I is then calculated for each cell to quantify correlation between the cell and its neighbors. For a given grid cell xᵢ, the I statistic is calculated as

$${I}_{i} = \frac{{x}_{i} - \overline{x}}{{σ}^{2}} {\sum }_{j = 0}^{n} \left({x}_{j} - \overline{x}\right) , \text{where} {σ}^{2}$$

is the standard deviation of the scores of all grid cells, xᵢ-x̅ is the difference between the grid cell xᵢ’s score and the global average grid cell score (x̅), and xⱼ-x̅ is the difference between each neighboring cell xⱼ and the global average grid cell score. The data is then repeatedly permuted to estimate the probability that the observed spatial pattern in the grid cell is statistically different from random and generate a p-value. Because each cell is determined to be a hotspot by comparison with its neighbors, cells determined to be significant are in fact the center of a cluster of cells with similar values.

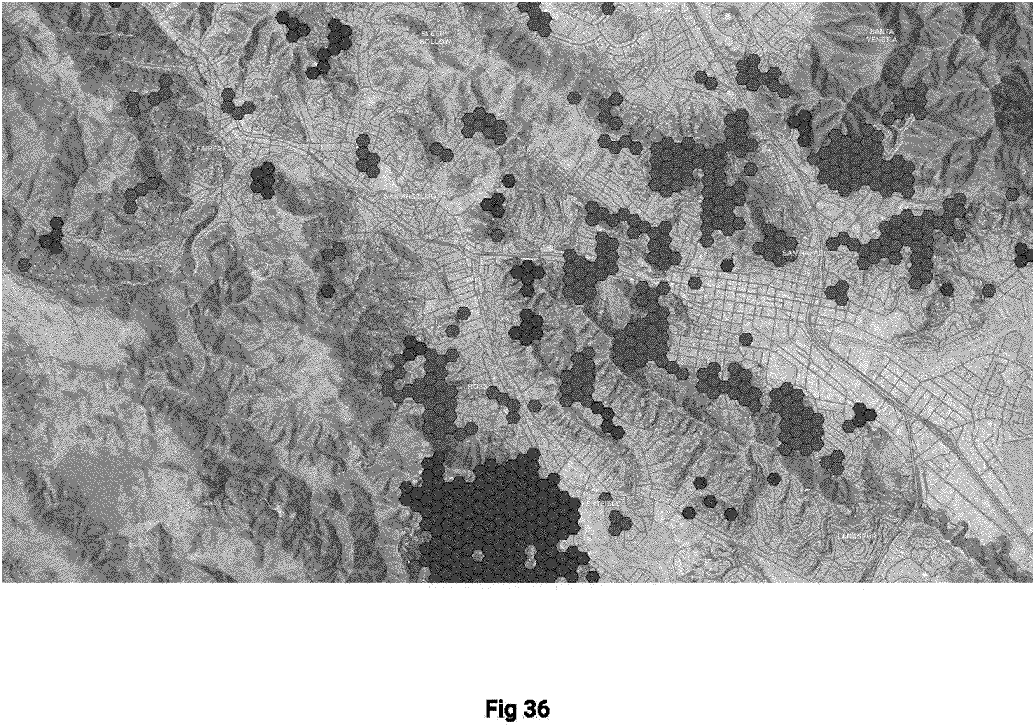

FIG. 36 illustrates an example of hotspots and coldspots calculated in the example embodiment.

### Issue Resolution Simulation Analysis

It is useful to understand the sensitivity of the on-parcel hazard scores to issue mitigation: an operationally useful scoring framework should show a reduction in hazard scores when issues are resolved. In an example embodiment, simulations may be performed on an existing score dataset to aid in optimizing the prioritization of resolution of specific issues. This form of analysis provides specific insights into how sensitive the score is to hazard mitigation by community members and provides guidance on the optimal prioritization strategies.

In an example embodiment, the following resolution strategies are considered:
Random Resolution: Issues are resolved at random.
Hazard-load based prioritization: Discovery types are prioritized by their total hazard load. Issues are resolved at random within each included discovery type; the top 5 and 10 highest hazard load types are considered. This strategy provides a balanced mitigation prioritization for issues that are both common and individually hazardous.
Mean-hazard based prioritization: Discovery types are prioritized by their average hazard. Issues are resolved at random within each included discovery type. The top 5 and 10 most hazardous types are considered. This strategy prioritizes mitigation of issues that are the most individually hazardous.
Other potential prioritization strategies include (a) on parcels within the top Nth percentile of hazard scores, (b) for high-efficiency types, (c) within particular fire districts or administrative units.

Hazard hotspots provide a level of geographic proximity that can be used to identify specific neighborhoods. In addition to unconstrained application (e.g., mitigation anywhere in the JPA), the three scenarios were also applied only to hotspots to illustrate the effectiveness of resolving issues within the hotspots alone. Hotspot-based prioritization optimizes for the geographic proximity of resolved issues, and is suitable for planning abatement and other mitigation strategies where minimizing travel time between mitigations is a priority.

### API Services

The score computation module, hotspot statistics module, and resolution simulators are deployed as application programming interfaces accessible over HTTPS and/or gRPC. Their deployment allows clients to easily obtain predictions of parcel-level wildfire hazards, community-level hotspots, and resolution simulations. By exposing the functionality as APIs, we enable (a) a rich expressive decision support system where fire preparedness officials can obtain deep insights into the impacts of their chosen policies and (b) extensibility, where developers can integrate additional application-specific logic on top of our modeling frameworks.

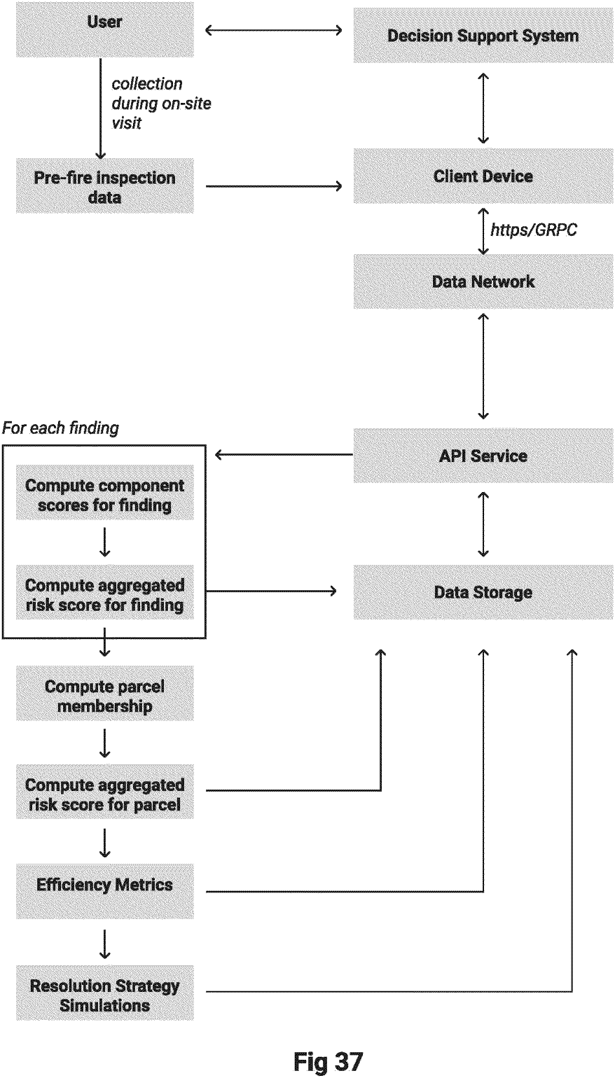

FIG. 37 illustrates an overview of the information flows of the example embodiment configured with an API module. In the top of FIG. 37, a user interacts with a decision support system through a client device. On the right side of FIG. 37, data is transferred over a data network to an API service. On the left portion of FIG. 37, the risk score modules, the parcel aggregator modules, the efficiency module, and the resolution strategy module are invoked and results saved into data storage. Results are returned to the client device over the same data network and displayed on the device’s visual outputs as maps and graphs.

### Parcel-Level Example

This section offers an in-depth example embodiment that illustrates the computation of the finding- and parcel-level risk scores on a single parcel. In this example, the hazard assessment methodology is applied to hypothetical discoveries found on a real parcel, to highlight the calculation of commonly-found discoveries.

Discoveries are shown in yellow circles, structures are shown as gray polygons. 20′ elevation contours illustrate the topography on the parcel. As shown in FIG. 21, the parcel contains a number of different fire-hazardous species, including Juniper, Cypress, and Broom, as well as other defensible space discovery types, such as piles of dead vegetation, vegetation in zone zero, and litter on the ground. In addition, the primary dwelling unit on the structure has a Class A asphalt roof, vents with mesh exceeding ⅛”, unenclosed eaves, metal gutters, and an on-grade deck made of a plastic composite material.

First, the parcel’s prevailing environmental and topographic conditions are identified for each of the two weather scenarios. As shown in Table C4, the mean slope of the parcel is 20.4° and the mean aspect is southwest-facing (223°). Topographically, this parcel is located on the top of a north-south running ridge, yielding higher wind speeds than that for adjacent parcels. Fine-scale variations for slope, aspect, and fuel moisture are possible given the 5 m-resolution topographic and vegetation data, allowing each discovery to take its own unique value for these fields. Standard deviations in each attribute is shown in parentheses for these fields in Table C4. Wind speed and direction vary at 100 m resolution, and small-scale perturbations and flow eddies around the structure and topography are not included, so the single parcel-level average wind speed and direction is used for all discoveries.

TABLE C4

Mean discovery-level environmental conditions for the parcel explored in this section.

| | | |
|---|---|---|
| | 2020 Scenario | 2017 Scenario |
| Slope | 20.4° (± 2.5°) | |
| Aspect | 229.4° (± 11.8°) | |
| 1-Hour | 10.9% (± 0.02%) | 5.7% (± 0.43%) |
| 10-Hour | 8.7% (± 0.12%) | 9.6% (± 0.33%) |
| 100-Hour | 9.0% (± 0.26%) | 9.0% (± 0.39%) |
| Wind Speed | 6.5 mph | 4.8 mph |
| Wind From Direction | West | North |

Sub-parcel variation in environmental conditions are illustrated with the standard deviation of each attribute in parentheses.

### Intensity Component Calculation

Ten of the 19 discoveries on the parcel represent vegetation or combustible materials and are given an intensity component score. A summary of the predicted fire behavior and scaling for each scenario is provided in Table C5. As shown in Table C5, the fireline intensity of these discoveries varies widely. The maximum fireline intensity varies from less than 1 BTU/s/ft (flame lengths of approximately 3 inches) for grasses and weeds to more than 1,040 BTU/s/ft (flame lengths exceeding 10 ft) for the instances of juniper, cypress and broom.

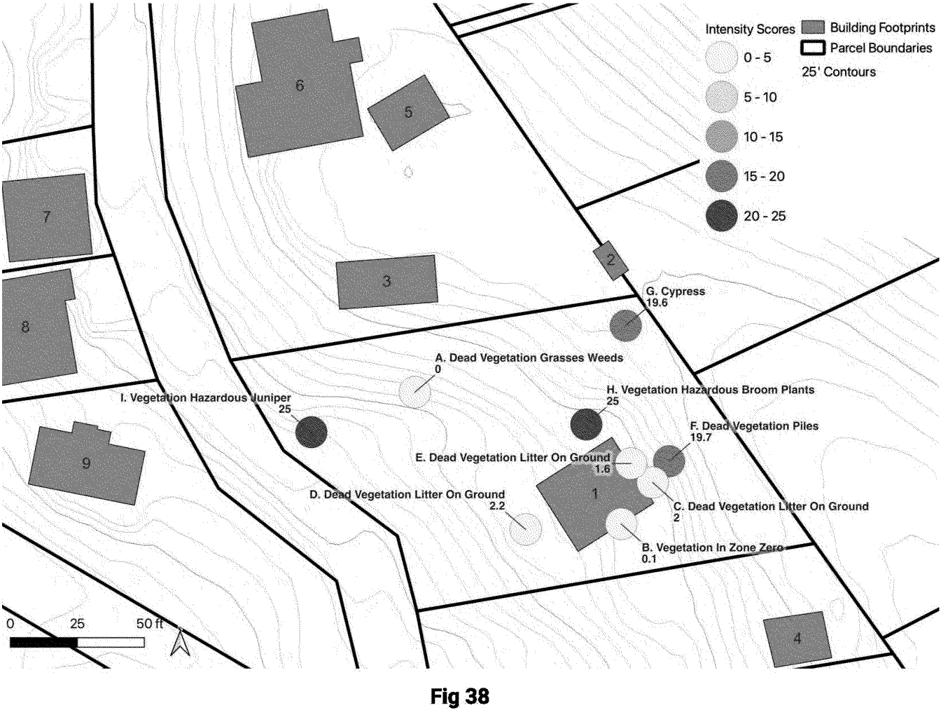

FIG. 38 illustrates intensity scores and affected buildings for each combustible discovery. Effective fireline intensity values are then computed for all adjacent structures as numbered in FIG. 38. The distance between the discovery and each structure and the relative bearing between the direction of the local wind-slope axis and the bearing between the discovery and structure are used to generate the intensity values for each structure.

TABLE C5

Fire behavior characteristics and scaling values used to produce the intensity component score for combustible discoveries on the example parcel.

| | Max Flame Length (ft) | Max Fireline Intensity (BTUs/ft) | Distance and Direction Scale 2017 | 2017 Intensity Value | Distance and Direction Scale 2020 | 2020 Intensity Value | Intensity Score |
|---|---|---|---|---|---|---|---|
| A. Grasses & Weeds | 0.2 | 0.2 | 2.46 | 0.0 | 2.3 | 0.0 | 0.0 |
| B. Vegetation in Zone Zero | 0.6 | 2 | 6.3 | 0.13 | 6.1 | 0.14 | 0.1 |
| C. Litter on Ground | 3.1 | 68.5 | 2.8 | 1.9 | 2.6 | 2.0 | 2.0 |
| D. Litter on Ground | 3.1 | 68.6 | 2.6 | 1.9 | 2.8 | 2.2 | 2.2 |
| E. Litter on Ground | 3.2 | 72.5 | 2.0 | 1.4 | 2.0 | 1.6 | 1.6 |
| F. Dead Vegetation Piles | 9.7 | 793.1 | 2.17 | 17.2 | 5.8 | 19.7 | 19.7 |
| G. Cypress | 10.5 | 936 | 2.0 | 19.6 | 1.9 | 18.7 | 18.7 |
| H. Broom Plants | 10.7 | 988.6 | 2.5 | 24.5 | 2.7 | 27.7 | 25.0 |
| I. Juniper | 10.9 | 1017 | 2.5 | 27.6 | 2.7 | 25.8 | 25.0 |

As shown in FIG. 38 and Table C5, the resulting intensity component index captures both the intensity of the fire for a given discovery and the distance and direction to the surrounding structures. Discovery B (Vegetation in Zone Zero), is located very close to Building 1, yielding a distance and direction scaling value for both weather scenarios. However, because the fire produced by this discovery is likely to be small, the overall intensity component index is low. On the other hand, because they are located farther away from nearby structures lower the Juniper and Broom plants have lower distance and direction scale values, but support much more intense fires, yielding a higher index value overall.

### Ember Component Calculation

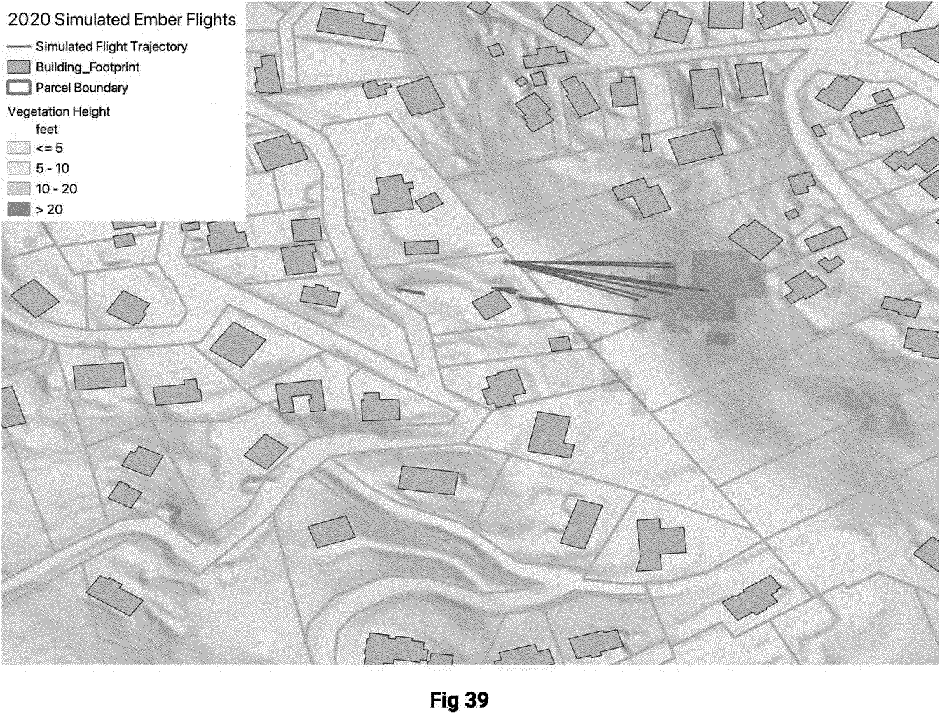

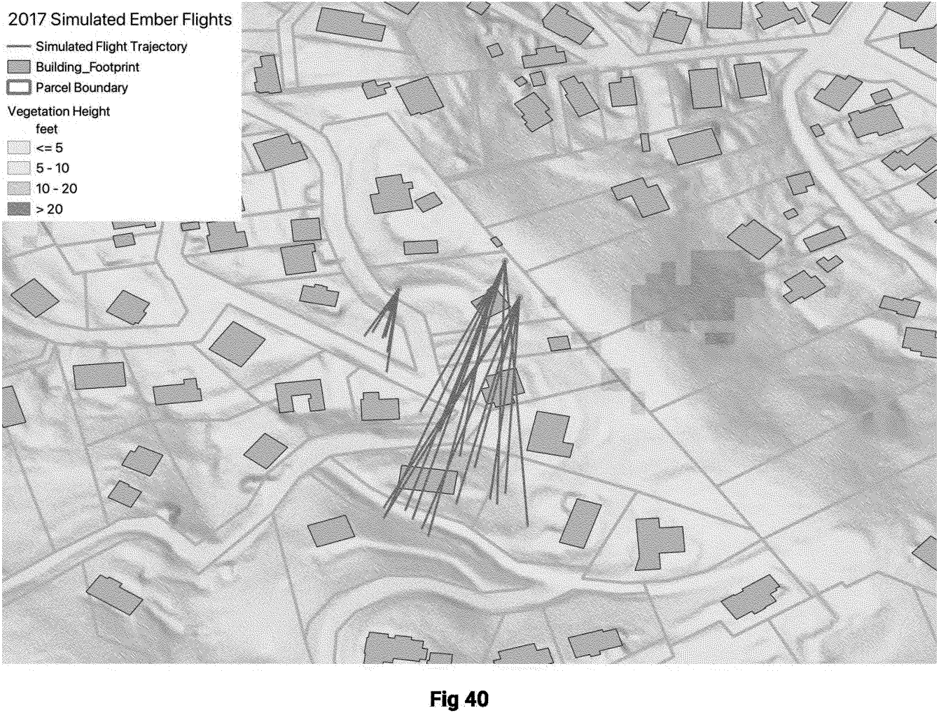

The ember component is calculated for four of the discoveries found on this parcel: Dead Vegetation Piles (F), Cypress (G), Broom Plants (H), and Juniper (I). FIGS. 39 and 40 illustrate simulated ember trajectories for the 2020 scenario (FIG. 39) and the 2017 scenario (FIG. 30). Vegetation height is illustrated. Notice that in 2020 (FIG. 39), embers generated by the cypress tree (Discovery G) are blocked from traveling into the community below by the tall vegetation (>30′) on the west-facing slope (shaded green area). If this vegetation was not as tall or was absent entirely, several structures to the east (right of FIGS. 39 and 40) may have been impacted by the cypress tree’s embers. Depending on conditions, intersection with the vegetation may cause ignition of the vegetation; however, if this were to happen, the nature of the hazard would change. Instead of being threatened by ember-based ignition from the cypress tree, the primary hazard would be from radiant heat produced by the now-ignited trees and other vegetation. Embers under the 2017 scenario, where the wind blows from the north, are not impacted by this patch of vegetation and are deposited on and near downwind structures to the south.

Table C6 provides a summary of the ember flights for each discovery under each weather scenario. From an ember deposition perspective, the broom plants are the most hazardous, because this plant’s embers are very likely to be deposited on downwind structures.

TABLE C6

Ember component scoring calculations for the four discoveries capable of producing embers on the parcel.

| | 2017 Intersection Fraction | 2017 Max Distance (meters) | 2017 Score | 2020 Intersection Fraction | 2020 Max Distance | 2020 Score | Ember Score |
|---|---|---|---|---|---|---|---|
| F. Dead Vegetation Piles | 29% | 104 | 5.8 | 0% | 44.2 | 2 | 5.8 |
| G. Cypress | 14% | 119.3 | 3.3 | 0% | 69.4 | 2.5 | 3.3 |
| H. Broom Plants | 100% | 72.1 | 17.0 | 100% | 8.6 | 5.9 | 17.0 |
| I. Juniper | 0% | 35.1 | 1.8 | 0% | 8.5 | 0.9 | 1.8 |

### Vulnerability Component Calculation

Eight of the discoveries are integrated into the structure vulnerability assessment model. As shown in Table C7, the >⅛” mesh is the highest hazard discovery, followed by single pane windows and wood plank siding.

TABLE C7

Vulnerability component score values as encountered on the example parcel.

| | Vulnerability Component Value |
|---|---|
| S. Asphalt Roof | -14.6 |
| M. Tempered/Multi-Pane Windows | -4.1 |
| L. Deck on Grade | 1.5 |
| P. Eaves Unenclosed | 2.4 |
| Q. Wood Plank Siding | 2.4 |
| N. Single Pane Windows | 3.7 |
| J. Vents > ⅛” Mesh | 7.1 |

The Class A Asphalt roof and multi-pane windows are both resilient s, lowering the overall risk of structure ignition on the parcel and offsetting the hazards created by other discoveries (denoted with a negative component value).

To illustrate how the vulnerability component assesses a discovery’s marginal contribution to structure ignition as a function of all surveyed attributes, two additional scenarios are shown in Table C8. The first shows the value of the vulnerability index if all model inputs are unhardened. This scenario illustrates a structure at very high risk of ignition during a wildfire, with a combustible roof, single pane windows, combustible siding, and attached combustible fencing and carport. The second example shows the attribute value if all attributes are constructed to fire resilient standards, reflecting a structure that is highly resistant to ignition. Note the differences between the scenarios, and the component values from Table C8, which highlight the holistic and non-linear relationships between structural hardening and ignition probability. For example, while the replacement of a combustible roof with an asphalt roof is beneficial in both scenarios, this modification is much more important on the structure with no other fire resistant attributes. Similarly, the wood plank siding is far more hazardous on a structure that also has a combustible roof and attachments than one where these attributes are fire resistant. Additionally, both vents and windows are greater contributors to structure ignition when encountered on a fully hardened structure than when found structures with fire hazardous construction. This illustrates that these attributes may play a smaller role in structure ignition in unhardened structures because these structures are more likely to be ignited from other factors, such as combustible roofing and siding.

TABLE C8

Vulnerability component score values for the discovery types found on the example parcel for two scenarios representing other configurations of structural hardening.

| | Unhardened Scenario | Fully Hardened Scenario |
|---|---|---|
| S. Asphalt Roof | -15.8 | -4.3 |
| M. Tempered/Multi-Pane Windows | -4.1 | -3.8 |
| L. Deck on Grade | 9.9 | 1.5 |
| P. Eaves Unenclosed | 5.6 | 2.1 |
| Q. Wood Plank Siding | 17.2 | 2.4 |
| N. Single Pane Windows | 3.3 | 3.8 |
| J. Vents > ⅛” Mesh | 6.7 | 7.8 |

### Continuity Component Calculation

All of the discoveries include a continuity component value. The primary structure on the parcel is located 26 ft (8.6 m) from the next nearest structure, categorizing it as being within a high density interface area according to the rubric in (Alexander Maranghides et al. 2022). In this area, structure-to-structure ignition through radiant heating and embercast is likely. Accordingly, the impact of home and parcel hardening is low. Therefore, the continuity values for discoveries on this parcel are adjusted to reflect their decreased effectiveness in preventing structure ignition in these areas. As shown in Table C9, the initial continuity values are adjusted by a factor of approximately 0.86 to produce the final continuity component score value. It is important to remember that while the continuity values are decreased, the model is not indicating that the parcel itself is at less risk, only that the source of the risk is not derived from a source captured in the DSI dataset.

TABLE C9

Continuity component values adjusted for structure separation distance on the example parcel.

| | Continuity Type Value | Adjusted Continuity Value |
|---|---|---|
| A. Grasses & Weeds | 15 | 12.8 |
| B. Vegetation in Zone Zero | 21 | 18.0 |
| C. Litter on Ground | 10 | 8.6 |
| D. Litter on Ground | 10 | 8.6 |
| E. Litter on Ground | 10 | 8.6 |
| F. Dead Vegetation Piles | 4 | 3.4 |
| G. Juniper | 14 | 12.0 |
| H. Broom Plants | 20 | 17.2 |
| I. Cypress | 14 | 12.0 |
| J. Vents > ⅛” mesh | 14 | 12.0 |
| L. Composite Deck | -12 | -10.3 |
| M. Multi-Pane Windows | -5 | -4.3 |
| N. Single-Pane Windows | 12 | 10.3 |
| P. Unenclosed Eaves | 14 | 12.0 |
| Q. Wood Plank Siding | 19 | 16.3 |
| R. Metal Gutters | 7 | 6.0 |
| S. Asphalt Roof | -15 | -12.9 |

### Discovery Score Calculation

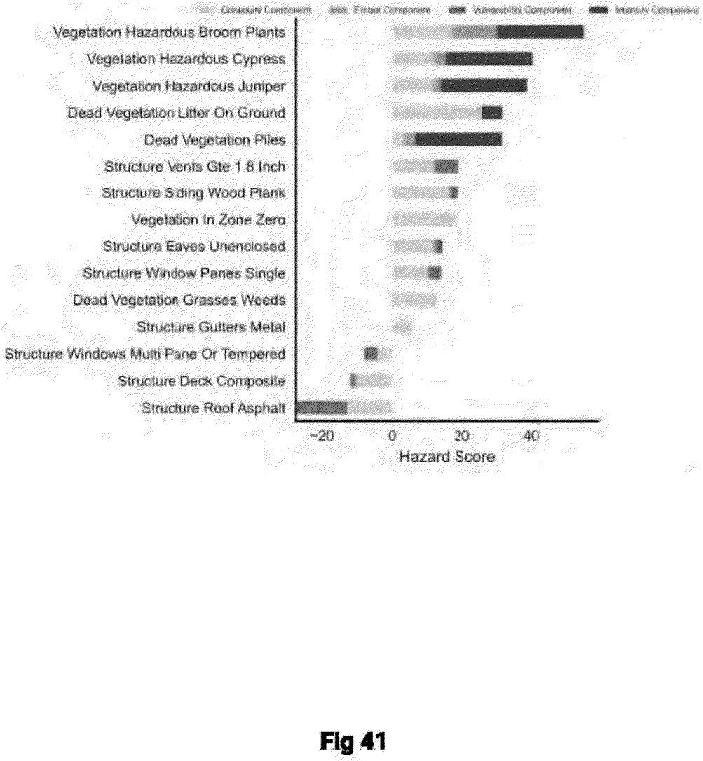

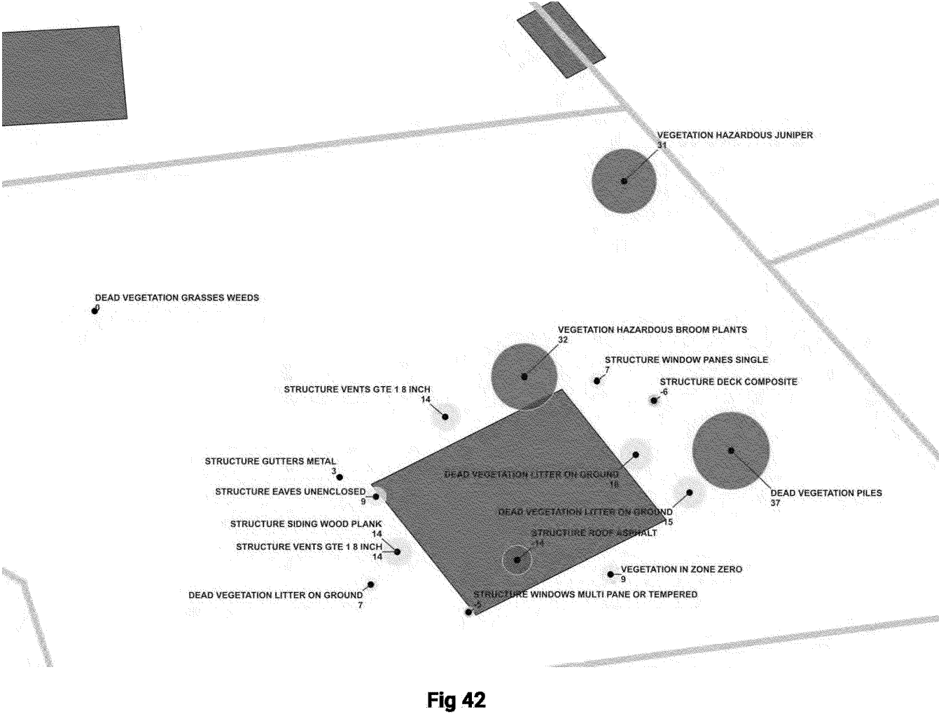

After each of the component scores has been calculated, the final discovery score is produced by adding the component values together to reflect the overall fire hazard of the discovery. FIG. 41 illustrates discovery hazard index scores on the example parcel, broken out by component index score. FIG. 42 illustrates discovery hazard index scores on the example parcel shown spatially. As shown in FIGS. 41 and 42, the scores produce a hazard index value that can be used to rank and prioritize mitigation of the different on-parcel discoveries.

Further, the component scores enable a framework for communicating how each discovery affects parcel and community safety. For example, the broom plants (Discovery H) are the most hazardous issue on the parcel because they produce a high ember load, are located close to the parcel’s primary structure such that their combustion will expose that structure to high intensity fire, and produce a litterbed that is highly receptive to ember ignition. The Vegetation in Zone Zero (Discovery B), primarily threatens the parcel by facilitating ember ignition adjacent to the structure and exposing the structure to direct flame contact, due to its location against the structure. While the fire intensity of this vegetation is likely to be moderate, its location makes it an important risk factor on this parcel. An assessment of each discovery type’s average contribution to on-parcel risk is described herein.

It is also important to note that the framework assesses fire hazard without regard to parcel boundaries. While the instances of juniper and cypress are located relatively far from the parcel’s primary structure, they are located in positions to expose other neighboring structures to radiant heating, raising their index scores. The full value of this cross-boundary hazard is associated with the parcel on which the discovery is found.

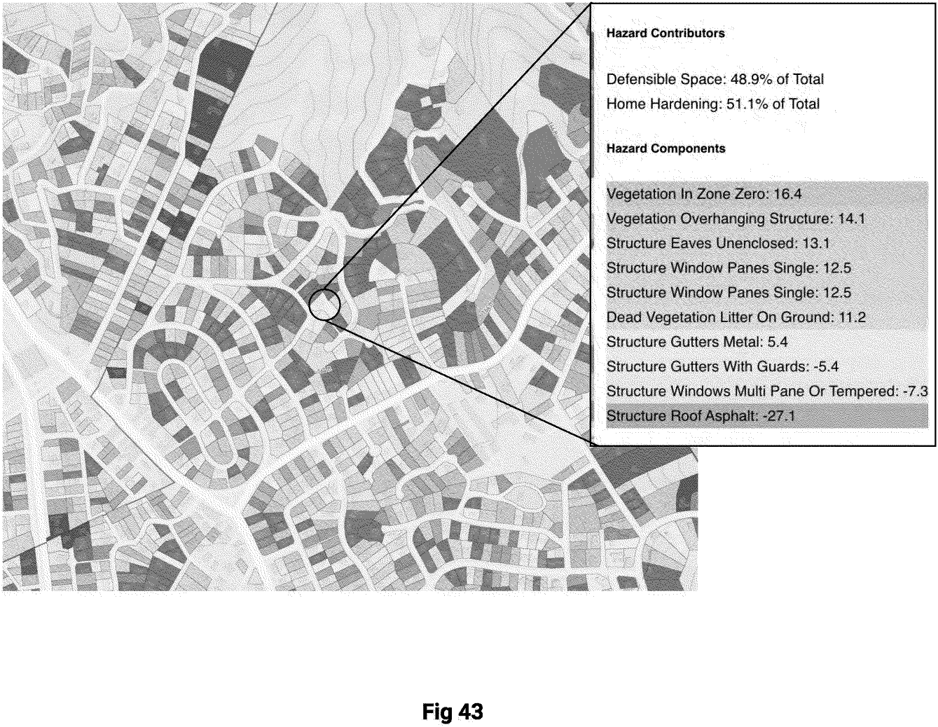

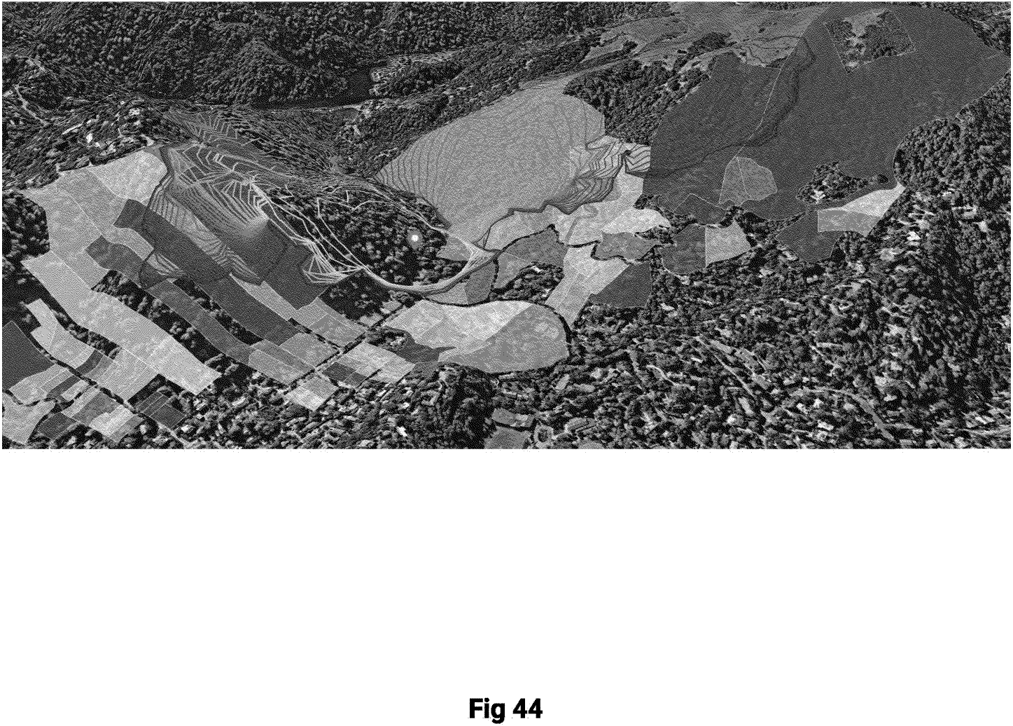

FIGS. 43 and 44 illustrate the example embodiment when used in a decision support system. In FIG. 43, parcel-level scores and shown to the end user, via the API module, and shown to be a function of the component hazard scores on each parcel.

FIG. 44 illustrates the example embodiment where parcel-level risk assessment scores are used in conjunction with the fire mechanics module and planning agent to determine the optimal locations for fire suppression resources given environmental conditions and on-parcel conditions. In this case, the planning agent’s is exposed to an additional environment variable (parcel scores), which it uses to further refine its planning in the presence of additional information regarding the particular structures most likely to ignite upon fire exposure.

As described herein for various example embodiments, system and method for wildfire spread behavior forecasting and on-parcel wildfire risk evaluation is disclosed. In the various example embodiments described herein, a computer-implemented tool or software application (app) as part of a wildfire risk evaluation system is described to automate and improve the collection, processing, verification, scoring, and analysis of wildfire spread behavior and risk evaluation information. As such, the various embodiments as described herein are necessarily rooted in computer and network technology and serve to improve these technologies when applied in the manner as presently claimed. In particular, the various embodiments described herein improve wildfire risk evaluation technology and data network technology in the context of wildfire spread behavior forecasting and on-parcel wildfire risk evaluation via electronic means.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

What is claimed is:

1. An information technology system comprising:
a data processor; and
a wildfire risk evaluation module, executable by the data processor, the wildfire risk evaluation module including:
a preprocessing module for processing a plurality of data sources into spatially-aligned and temporally-aligned data matrices; and
a fire mechanics software module that produces a likelihood of future wildfire growth trajectories and conditional predictions of fire intensity from a plurality of remotely-sensed data sources, including at least one satellite-derived wildfire occurrence data source or one visible imagery data source, and ground-based data sources, including at least one spatiotemporally-explicit record of firefighter location and assignment.

2. The information technology system of claim 1, wherein the fire mechanics module uses a neural network to produce predictions of future fire growth and fire intensity.

3. The information technology system of claim 1, including a fire behavior estimator module that performs spatial and temporal comprehension of system dynamics through the use of one or more convolutional neural network layers.

4. An information technology system comprising:
a data processor; and
a wildfire risk evaluation module, executable by the data processor, the wildfire risk evaluation module including:
a fire mechanics software model that produces probabilistic estimates of future wildfire growth trajectories from a plurality of data sources;
an environment simulator module for producing simulated spatio-temporally explicit realizations of environmental conditions;
a simulation module that produces simulated fire environments and mechanics; and
a planning agent software module that produces the highest-value locations to which to dispatch fire suppression resources in response to a configurable value function.

5. The information technology system of claim 4, wherein the environment simulator module uses a neural network to produce predictions of future environmental conditions.

6. The information technology system of claim 4, wherein the fire mechanics module uses a neural network to produce predictions of fire growth in response to the environment.

7. The information technology system of claim 4, wherein the planning agent module uses a neural network to produce the actions that maximize a configurable value function.

8. The information technology system of claim 4, wherein the planning agent module uses a stochastic search process to identify a set of actions that maximize an expected long-term value of a configurable value function, measured over a finite set of simulated time periods.

9. The information technology system of claim 4, wherein the planning agent module is further configured to account for varying effectiveness and varying movement patterns of a plurality of fire suppression resource types.

10. The information technology system of claim 4, wherein the planning agent module utilizes a genetic selection tournament to select for promising algorithmic mutations.

11. The information technology system of claim 4, further configured to include an application programming interface (API) module, wherein the API module accepts requests over a data network and returns data in a machine-readable format to a calling client.

12. An information technology system comprising:
a data processor that processes findings of potential fire hazard obtained during on-site parcel inspections;
a plurality of component evaluation modules that produce independent measures of structure ignition potential through a different combustion pathways and under a plurality of different weather high-fire danger weather scenarios for an individual finding; and
a component-aggregation module that produces a scalar metric describing the fire hazard profile of an individual finding.

13. The information technology system of claim 12, further configured to include a parcel-aggregation module that produces a scalar metric describing the fire hazard profile of a tax parcel or other property delineation boundary from a plurality of findings located within that boundary.

14. The information technology system of claim 12, where the plurality of component evaluation modules are configured to quantify a wildfire issue’s hazard impact on a plurality of surrounding structures, regardless of parcel or administrative boundaries.

15. The information technology system of claim 12, where the plurality of component evaluation modules are configured to account for the structure ignition risks created by the potential radiant heat produced by combustion on an inspection finding.

16. The information technology system of claim 12, where the plurality of component evaluation modules are configured to account for structure ignition risks created by potential deposition of embers on or adjacent to downwind structures.

17. The information technology system of claim 12, where the plurality of component evaluation modules are configured to account for structure ignition risks created by different building design features and materials of construction.

18. The information technology system of claim 12, further configured to facilitate financial tradeoff evaluation and location-specific risk-mitigation prioritization.

19. The information technology system of claim 12, further configured to include an application programming interface (API), wherein the API accepts requests over a data network and returns data in a machine readable format to a calling client.

20. The information technology system of claim 12, further configured to use a neural network to generate high-value fire suppression strategies that account for both forecast wildfire spread behavior and the results of an on-parcel wildfire risk evaluation.
